(19) United States
(12) Patent Application Publication
(10) Pub. No.: US 2022/0187871 A1
(43) Pub. Date: Jun. 16, 2022

(54) DISPLAY APPARATUS AND OPERATION METHOD THEREOF

(71) Applicant: Semiconductor Energy Laboratory Co., Ltd., Atsugi-shi, Kanagawa-ken (JP)

(72) Inventors: Shunpei YAMAZAKI, Setagaya (JP); Naoto KUSUMOTO, Isehara (JP); Kensuke YOSHIZUMI, Atsugi (JP)

(21) Appl. No.: 17/439,437

(22) PCT Filed: Mar. 13, 2020
(86) PCT No.: PCT/IB2020/052265

§ 371 Date: Sep. 15, 2021

(30) Foreign Application Priority Data
Mar. 26, 2019 (JP) 2019-058794
Apr. 5, 2019 (JP) 2019-072577

(51) Int. Cl. G06F 1/16

(52) U.S. Cl. CPC G06F 1/1641; G06F 1/1652; H02J 50/10; G06F 2200/1637; G06F 1/1681

(57) ABSTRACT

A foldable display apparatus with excellent portability is provided. The display apparatus includes a flexible display panel, which can be folded in a small size. The display apparatus has a tri-fold mechanism, in which a region folded with a first surface itself of the display apparatus facing each other and a region folded with a second surface opposite to the first surface itself facing each other can be formed. Thus, even a display panel which has a relatively high aspect ratio can be folded in a small size by provision of a folding crease in the short-axis direction, so that portability can be improved.

### TECHNICAL FIELD

The present invention relates to an object, a method, or a manufacturing method. The present invention relates to a process, a machine, manufacture, or a composition of matter. In particular, one embodiment of the present invention relates to a semiconductor device, a light-emitting device, a display apparatus, an electronic device, a lighting device, a driving method thereof, or a fabrication method thereof. In particular, one embodiment of the present invention relates to a display apparatus whose display surface has flexibility, an operation method thereof, or a fabrication method thereof.

Note that in this specification and the like, a semiconductor device generally means a device that can function by utilizing semiconductor characteristics. A transistor, a semiconductor circuit, an arithmetic device, a memory device, and the like are each an embodiment of the semiconductor device. Moreover, a light-emitting device, a display apparatus, a lighting device, and an electronic device include a semiconductor device in some cases.

### BACKGROUND ART

Electronic devices such as mobile phones, smartphones, tablet computers, and laptop computers are each formed in an adequate size in accordance with its function, usability, and portability. However, it is inconvenient to carry a plurality of electronic devices. Accordingly, a form in which functions of a plurality of electronic devices are integrated is desired. For example, Patent Document 1 discloses a tri-fold type light-emitting panel. With the use of the light-emitting panel, an electronic device in which functions of a plurality of electronic devices are integrated and whose size is variable can be fabricated.

### REFERENCE

### Patent Document

[Patent Document 1] Japanese Published Patent Application No. 2015-130320

### SUMMARY OF THE INVENTION

### Problems to be Solved by the Invention

An object of one embodiment of the present invention is to provide a foldable display apparatus with excellent portability. Another object is to provide a foldable display apparatus with excellent display visibility. Another object is to provide a foldable display apparatus having a power-saving function. Another object is to provide a foldable display apparatus which is very easy to hold. Another object is to provide a novel display apparatus. Another object is to provide an operation method of the novel display apparatus.

Note that the description of these objects does not preclude the existence of other objects. One embodiment of the present invention does not need to achieve all these objects. Objects other than the above will be apparent from the description of the specification and the like, and objects other than the above can be derived from the description of the specification and the like.

### Means for Solving the Problems

One embodiment of the present invention relates to a tri-fold type display apparatus with excellent portability.

One embodiment of the present invention is a display apparatus including a display panel having flexibility. The display panel includes a first region, a second region, and a third region. The first region, the second region, and the third region are positioned parallel to one another to form a plane when the display apparatus is opened flat. The second region is provided between the first region and the third region. The display apparatus has a function of forming a first curved surface with a convex shape on a display surface side across the first region and the second region and a function of forming a second curved surface with a concave shape on the display surface side across the second region and the third region. When the display apparatus is folded, a radius of curvature R1 of the first curved surface is larger than a radius of curvature R2 of the second curved surface.

Another embodiment of the present invention is a display apparatus including a display panel having flexibility. The display panel includes a first region, a second region, and a third region. The first region, the second region, and the third region are positioned parallel to one another to form a plane when the display apparatus is opened flat. The second region is provided between the first region and the third region. The display apparatus has a function of successively forming a first curved surface with a convex shape on a display surface side, a plane surface, and a third curved surface with a convex shape on the display surface side in this order across the first region and the second region. The display apparatus has a function of forming a second curved surface with a concave shape on the display surface side across the second region and the third region. When the display apparatus is folded, a radius of curvature R1 of the first curved surface is larger than a radius of curvature R2 of the second curved surface, a radius of curvature R3 of the third curved surface is larger than the radius of curvature R2, and the radius of curvature R1 is substantially equal to the radius of curvature R3.

In either of the above embodiments, the display apparatus further includes a first housing, a second housing, a third housing, a first hinge, and a second hinge. At least part of the first region is fixed to the first housing. At least part of the second region is fixed to the second housing. At least part of the third region is fixed to the third housing. The first hinge is provided between the first housing and the second housing. The second hinge is provided between the second housing and the third housing. The first hinge has a function of forming the first curved surface. The second hinge has a function of forming the second curved surface. When the display apparatus is opened flat, the gravity center of the whole is in the first housing or the third housing.

A battery may be provided in the first housing or the third housing.

A power receiving coil for wireless charging may be provided in the third housing.

The display panel preferably includes a light-emitting device.

Another embodiment of the present invention is an operation method of a display apparatus, in which only a part of a region performs display when the display apparatus is folded. Furthermore, when the display panel is opened flat, operation may be performed such that orientation of an image is changed in accordance with inclination of the display panel.

### Effect of the Invention

According to one embodiment of the present invention, a foldable display apparatus with excellent portability can be provided. Alternatively, a foldable display apparatus with excellent display visibility can be provided. Alternatively, a foldable display apparatus having a power-saving function can be provided. Alternatively, a foldable display apparatus which is very easy to hold can be provided. Alternatively, a novel display apparatus can be provided. Alternatively, an operation method of the novel display apparatus can be provided.

Note that the description of these effects does not preclude the existence of other effects. One embodiment of the present invention does not have to have all of these effects. Note that effects other than these will be apparent from the description of the specification, the drawings, the claims, and the like and effects other than these can be derived from the description of the specification, the drawings, the claims, and the like.

### BRIEF DESCRIPTION OF THE DRAWINGS

FIG. 1A and FIG. 1B are diagrams illustrating a display apparatus.

FIG. 2A to FIG. 2C are diagrams illustrating a display apparatus.

FIG. 3A and FIG. 3B are diagrams illustrating a display apparatus.

FIG. 4A to FIG. 4C are diagrams illustrating a hinge.

FIG. 5A to FIG. 5C are diagrams illustrating a hinge.

FIG. 6A to FIG. 6C are diagrams illustrating a hinge.

FIG. 7A to FIG. 7C are diagrams illustrating a hinge.

FIG. 8A to FIG. 8D are diagrams illustrating display apparatuses.

FIG. 9A and FIG. 9B are diagrams each illustrating operation of a display apparatus.

FIG. 10 is a flow chart showing operation of the display apparatus.

FIG. 11A is a circuit diagram of a protection circuit. FIG. 11B is a block diagram illustrating the connection mode of the protection circuit.

FIG. 12A is a diagram illustrating a display apparatus. FIG. 12B is a diagram illustrating wireless charging of the display apparatus.

FIG. 13A to FIG. 13C are diagrams each illustrating operation of a display apparatus.

FIG. 14A to FIG. 14C are diagrams each illustrating operation of a display apparatus.

FIG. 15A to FIG. 15C are diagrams each illustrating operation of a display apparatus.

FIG. 16A and FIG. 16B are diagrams illustrating application examples of a display apparatus.

FIG. 17A to FIG. 17D are diagrams illustrating application examples of a display apparatus.

FIG. 18A and FIG. 18B are diagrams illustrating application examples of a display apparatus.

FIG. 19 is a block diagram illustrating an example of a television device.

FIG. 20 is a diagram illustrating a structure example of a display panel.

FIG. 21 is a diagram illustrating a structure example of a display panel.

FIG. 22 is a diagram illustrating a structure example of a display panel.

FIG. 23A is a block diagram of a display apparatus. FIG. 23B and FIG. 23C are circuit diagrams of pixels.

FIG. 24A, FIG. 24C, and FIG. 24D are circuit diagrams of pixels. FIG. 24B is a timing chart showing operation of the pixel.

FIG. 25A to FIG. 25E are diagrams illustrating structure examples of pixels.

FIG. 26A illustrates classification of IGZO crystal structures. FIG. 26B illustrates an XRD spectrum of quartz glass. FIG. 26C illustrates an XRD spectrum of crystalline IGZO. FIG. 26D illustrate a nanobeam electron diffraction pattern of the crystalline IGZO.

FIG. 27A to FIG. 27D are cross-sectional views of light-emitting devices.

FIG. 28A to FIG. 28C are conceptual diagrams illustrating light-emission models of a light-emitting device. FIG. 28D is a diagram illustrating normalized luminance of the light-emitting device over time.

FIG. 29A to FIG. 29D are diagrams each showing the concentration of an organometallic complex in an electron-transport layer.

### MODE FOR CARRYING OUT THE INVENTION

Embodiments are described in detail with reference to the drawings. Note that the present invention is not limited to the following description, and it will be readily understood by those skilled in the art that modes and details of the present invention can be modified in various ways without departing from the spirit and scope. Therefore, the present invention should not be interpreted as being limited to the description of embodiments below. Note that in structures of the invention described below, the same portions or portions having similar functions are denoted by the same reference numerals in different drawings, and the description thereof is not repeated in some cases. The same components are denoted by different hatching patterns in different drawings, or the hatching patterns are omitted in some cases.

Even in the case where a single component is illustrated in a circuit diagram, the component may be composed of a plurality of parts as long as there is no functional inconvenience. For example, in some cases, a plurality of transistors that operate as a switch are connected in series or in parallel. In some cases, capacitors are divided and arranged in a plurality of positions.

One conductor has a plurality of functions such as a wiring, an electrode, and a terminal in some cases. In this specification, a plurality of names are used for the same component in some cases. Even in the case where elements are illustrated in a circuit diagram as if they were directly connected to each other, the elements may actually be connected to each other through one conductor or a plurality of conductors. In this specification, even such a configuration is included in direct connection.

### Embodiment 1

In this embodiment, a display apparatus of one embodiment of the present invention is described with reference to drawings. In this specification, a display apparatus means all devices having a display function. That is, an electronic device including a display portion is included in the display apparatus. For example, electronic devices including a display portion such as a mobile phone, a smartphone, a tablet computer, and a television devices are included in the display apparatus.

One embodiment of the present invention is a display apparatus that includes a display panel having flexibility and that can be folded in a small size. The display apparatus has a tri-fold mechanism, in which a region folded with a first surface itself facing each other and a region folded with a second surface opposite to the first surface itself facing each other can be formed. Thus, even a display panel which has a relatively high aspect ratio such as 16:9, 18:9, or 21:9 can be folded in a small size by provision of a folding crease in the short-axis direction, so that portability can be improved. A display region that can not be seen when the display panel is folded in a small size, is put in a non-display state, whereby power consumption can be significantly reduced.

### <Display Apparatus>

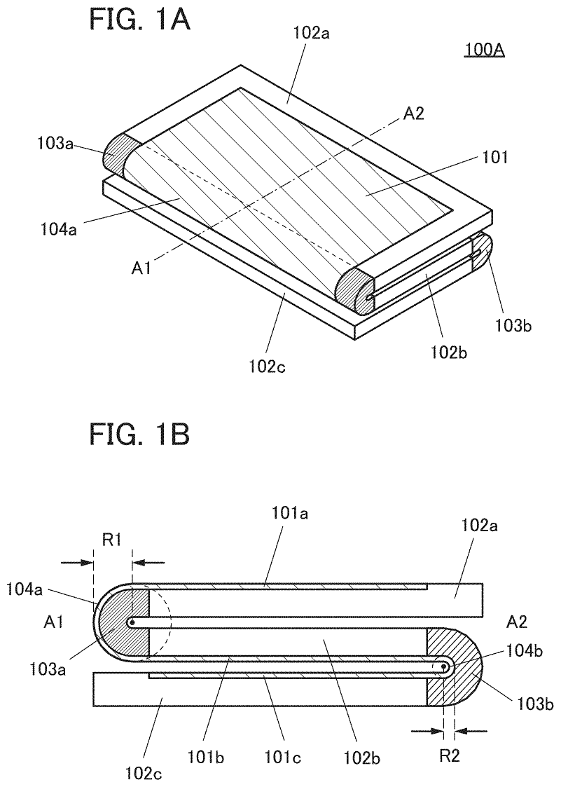

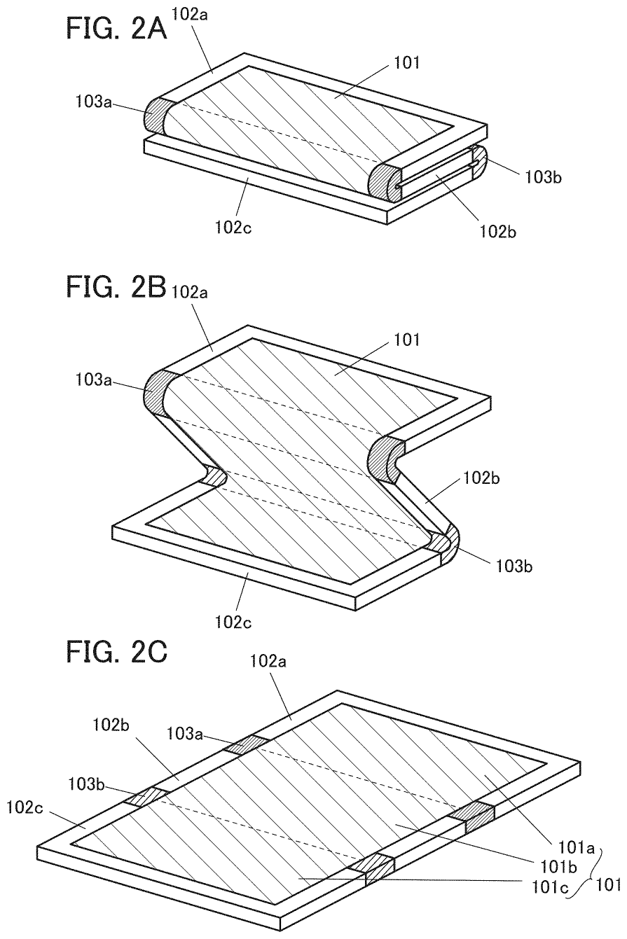

FIG. 1A is a diagram illustrating a state where a display apparatus 100A of one embodiment of the present invention is folded in a minimum size. The display apparatus 100A can be changed in shape as illustrated in FIG. 2A to FIG. 2C. When the initial state is a folded state (see FIG. 2A), it can be changed to an flat opened state (see FIG. 2C) through a state of change in shape (see FIG. 2B). When being changed in shape in the reverse order, the display apparatus 100A can be folded. The display apparatus 100A can be changed in shape manually; however, electrical power or mechanical power such as a spring may be used.

The display apparatus 100A includes a display panel 101 having flexibility, a housing 102a, a housing 102b, a housing 102c, a hinge 103a, and a hinge 103b. Note that in this embodiment, the display panel 101 is divided into three regions of a region 101a, a region 101b, and a region 101c (see FIG. 2C). The region 101a, the region 101b, and the region 101c are regions which are positioned parallel to one another in the horizontal direction (the direction in which a plane of the display panel 101 extends) to form a plane when the display panel 101 is opened flat, and are regions where the positions of hinges or the vicinity thereof serve as boundaries. In practice, there is no structural difference among the regions 101a to 101c and among their boundaries. For the display panel 101, a flexible display panel with no joint can be used.

FIG. 1B corresponds to a cross section taken along A1-A2 of FIG. 1A. The housing 102a is connected to the housing 102b through the hinge 103a. The housing 102b is connected to the housing 102c through the hinge 103b.

The display panel 101 is provided on a first surface side of the housings 102a to 102c. At least part of the region 101a can be fixed to the housing 102a. At least part of the region 101b can be fixed to the housing 102b. At least part of the region 101c can be fixed to the housing 102c.

In the case where a plane fixed to the housing of the display panel 101 is a non-display surface and a plane opposite to the plane fixed to the housing of the display panel 101 is a display surface, as illustrated in FIG. 1A and FIG. 1B, the non-display surfaces of the region 101a and the region 101b face each other, and a curved surface 104a with a convex shape on the display surface is formed across the region 101a and the region 101b. The curved surface 104a is a region including part of the region 101a and part of the region 101b. Furthermore, the display surfaces of the region 101b and the region 101c face each other, and a curved surface 104b with a concave shape on the display surface is formed across the region 101b and the region 101c. The curved surface 104b is a region including part of the region 101b and part of the region 101c.

A distance to the center of curvature with reference to the surface (display surface) of the curved surface is defined as a radius of curvature, and a radius of curvature of the curved surface 104a is represented by R1 and a radius of curvature of the curved surface 104b is represented by R2 when the display panel 101 is folded in a minimum size. At this time, R1>R2 is preferably satisfied.

R1 is a radius of curvature when the display surface is bent outward, which has a relatively large value even in the case where the thickness of the housings 102a and 102a is reduced in an appropriate range, and stress to be applied to a portion of the curved surface 104a of the display panel 101 is small. In contrast, R2 is a radius of curvature when the display surface is bent inward, which has a relatively small value regardless of the thickness of the housings 102b and 102c, and stress to be applied to a portion of the curved surface 104b of the display panel 101 is likely to be large.

Therefore, R2 is set to equal to R1 or larger than R1 so that stress to be applied to the portion of the curved surface 104b can be reduced, whereby the reliability can be improved. On the other hand, when R2 is large, the entire thickness is increased when the display apparatus 100A is folded, leading to poor portability.

In one embodiment of the present invention, a display panel that is highly resistant to bending stress is used, so that R1>R2 can be achieved without reducing the reliability. A display panel that is highly resistant to bending stress can be obtained by using a transistor including a metal oxide (hereinafter referred to as an oxide semiconductor) in a channel formation region (hereinafter referred to as an OS transistor) for a pixel circuit.

A metal oxide can be formed by a deposition method such as a sputtering method, and can be formed in a process with a relatively low temperature. Thus, a device such as a transistor and a peripheral member such as a protective film have less residual stress, and thus are highly resistant to the bending stress to be added later.

On the other hand, as a transistor having electrical characteristics at an equivalent level to those of a OS transistor, a transistor including silicon (such as low-temperature polysilicon or single crystal silicon) in a channel formation region (such a transistor is hereinafter referred to as a Si transistor) is given. For a fabrication step of a low-temperature polysilicon transistor, a laser crystallization step of a silicon film is used. The temperature of the silicon film is raised to a high temperature (at least a melting point of silicon) by the laser crystallization step though it is for a short time and then the silicon film is cooled rapidly. Thus, the silicon film and the peripheral member have a lot of residual stress, and when bending stress is further added later, electrical characteristics and the like are deteriorated and the reliability is lowered.

It is easy for the display apparatus of one embodiment of the present invention to satisfy R1>R2, and the display apparatus can be folded in a small size without lowering the reliability. Because the bending resistance differs depending on the radius of curvature, the number of times of bending, and the like, a Si transistor may be used in a pixel circuit under some circumstances.

As a semiconductor material used for an OS transistor, a metal oxide whose energy gap is greater than or equal to 2 eV, preferably greater than or equal to 2.5 eV, further preferably greater than or equal to 3 eV can be used. A typical example is an oxide semiconductor containing indium, and a CAAC-OS or a CAC-OS described later can be used, for example. A CAAC-OS has a crystal structure including stable atoms and is suitable for a transistor that is required to have high reliability, and the like. A CAC-OS has high mobility and is suitable for a transistor that operates at high speed, and the like.

In the OS transistor, the semiconductor layer has a large energy gap, and thus the OS transistor can have an extremely low off-state current of several yA/μm (current per micrometer of a channel width). An OS transistor has features such that impact ionization, an avalanche breakdown, a short-channel effect, or the like does not occur, which are different from those of a S1 transistor. Thus, the use of an OS transistor enables formation of a highly reliable circuit. Moreover, variations in electrical characteristics due to crystallinity unevenness, which are caused in S1 transistors, are less likely to occur in OS transistors.

The semiconductor layer included in the OS transistor can be, for example, a film represented by an In—M—Zn-based oxide that contains indium, zinc, and M (a metal such as aluminum, titanium, gallium, germanium, yttrium, zirconium, lanthanum, cerium, tin, neodymium, or hafnium). Besides the above In—M—Zn oxide, an In oxide, an In—Ga oxide, or an In—Zn oxide may be used for the semiconductor layer included in the OS transistor. Note that when a semiconductor layer having high proportion of indium is used, the on-state current, the field-effect mobility, or the like of the OS transistor can be increased. The In—M—Zn-based oxide can be formed by, for example, a sputtering method, an ALD (Atomic layer deposition) method, an MOCVD (Metal organic chemical vapor deposition) method, or the like.

In the case of forming a film of In—M—Zn oxide by a sputtering method, it is preferable that the atomic ratio of metal elements in a sputtering target satisfy In≥M and Zn≥M. The atomic ratio of metal elements in such a sputtering target is preferably, for example, In:M:Zn=1:1:1, In:M:Zn=1:1:1.2, In:M:Zn=3:1:2, In:M:Zn=4:2:3, In:M:Zn=4:2:4.1, In:M:Zn=5:1:3, In:M:Zn=5:1:6, or In:M:Zn=5:1:7, In:M:Zn=5:1:8, or In:M:Zn=10:1:3. In the case where the oxide semiconductor contained in the semiconductor layer is an In—Zn oxide, it is preferable that the atomic ratio of metal elements in a sputtering target used for forming a film of the In—Zn oxide satisfy In≥Zn. As the atomic ratio of metal elements in such a sputtering target, In:Zn=1:1, In:Zn=2:1, In:Zn=5:1, In:Zn=5:3, In:Zn=10:1, In:Zn=10:3, and the like are preferable.

An oxide semiconductor with low carrier concentration is used for the semiconductor layer. For example, an oxide semiconductor which has a carrier concentration lower than or equal to 1×10¹⁷/cm³, preferably lower than or equal to 1×10¹⁵/cm³, further preferably lower than or equal to 1×10¹³/cm³, still further preferably lower than or equal to 1×10¹¹/cm³, yet further preferably lower than 1×10¹⁰/cm³, and higher than or equal to 1×10⁻⁹/cm³ can be used for the semiconductor layer. Such an oxide semiconductor is referred to as a highly purified intrinsic or substantially highly purified intrinsic oxide semiconductor. The oxide semiconductor has a low density of defect states and can thus be regarded as an oxide semiconductor having stable characteristics.

Note that, without limitation to these, a material with an appropriate composition may be used in accordance with required semiconductor characteristics and electrical characteristics (e.g., field-effect mobility and threshold voltage) of the transistor. To obtain the required semiconductor characteristics of the transistor, it is preferable that the carrier concentration, the impurity concentration, the defect density, the atomic ratio between a metal element and oxygen, the interatomic distance, the density, and the like of the semiconductor layer be set to appropriate values.

Note that the hinges 103a and 103b are abstractly illustrated and there is no particular limitation on the structure. Although specific examples of the hinges 103a and 103b are described later, an elastic body such as rubber, columnar bodies connected in series, a gear, or the like can be used. Note that although FIG. 1A and FIG. 1B illustrate that the housings and the hinges are different components, the housings and the hinges are integrated without clear boundary in some cases. In some cases, the display panel 101 is not in contact with the hinges.

### Modification Example 1 of Display Apparatus

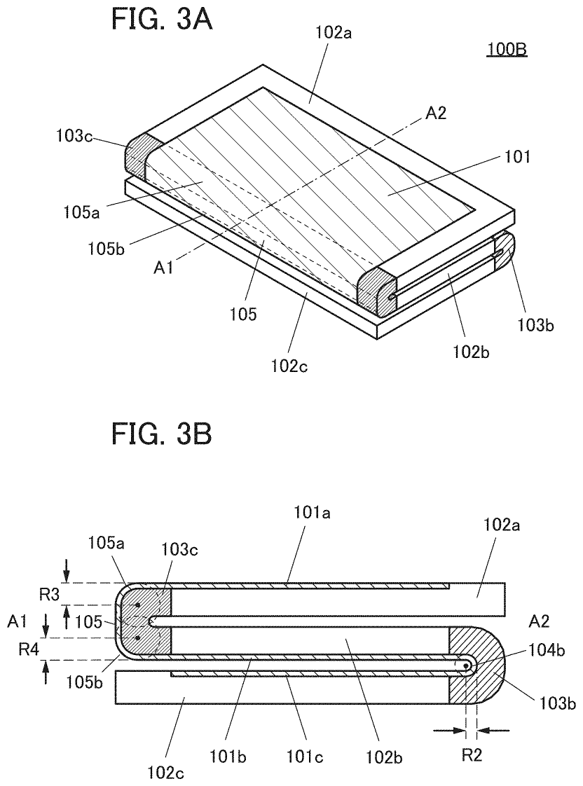

One embodiment of the present invention may also have the structure illustrated in FIG. 3A. A display apparatus 100B illustrated in FIG. 3A has a structure in which the hinge 103a included in the display apparatus 100A is replaced with the hinge 103c.

The hinge 103c included in the display apparatus 100B has a function of forming a curved surface 105a with a convex shape on the display surface, a plane surface 105, and a curved surface 105b with a convex shape on the display surface in this order across the region 101a and the region 101b when the display apparatus 100B is bent. Note that the curved surface 105a is a region formed using part of the region 101a, the plane surface 105 is formed using part of the region 101a and part of the region 101b, and the curved surface 105b is formed using part of the region 101c.

As illustrated in the cross-sectional view in FIG. 3B, when the radius of curvature of the curved surface 105a and the radius of curvature of the curved surface 105b at the time when the display apparatus 100B is folded in a minimum size, is R3 and R4, respectively, it is preferable that R3>R2 and R4>R2 be satisfied. By setting R3>R2 and R4>R2, the entire thickness can be reduced as in the display apparatus 100A. R3 and R4 are preferably equal to or substantially equal to each other. By setting R3 and R4 equal to each other, the display apparatus 100B can be folded with good symmetry, whereby the reliability of hinge mechanism can be improved. When R3 and R4 are largely different, at the time when the display apparatus 100B is folded or opened, one of the region where the curved surface 105a is formed and the region where the curved surface 105b is formed is easily bent compared to the other; which reduces the reliability in some cases.

In the display apparatus 100B in FIG. 3A and FIG. 3B, the plane surface 105 is formed by the hinge 103c when the display apparatus 100B is bent. Thus, the proportion of the plane surface is large at a bend portion, whereby the visibility of an image can be increased.

### <Hinge>

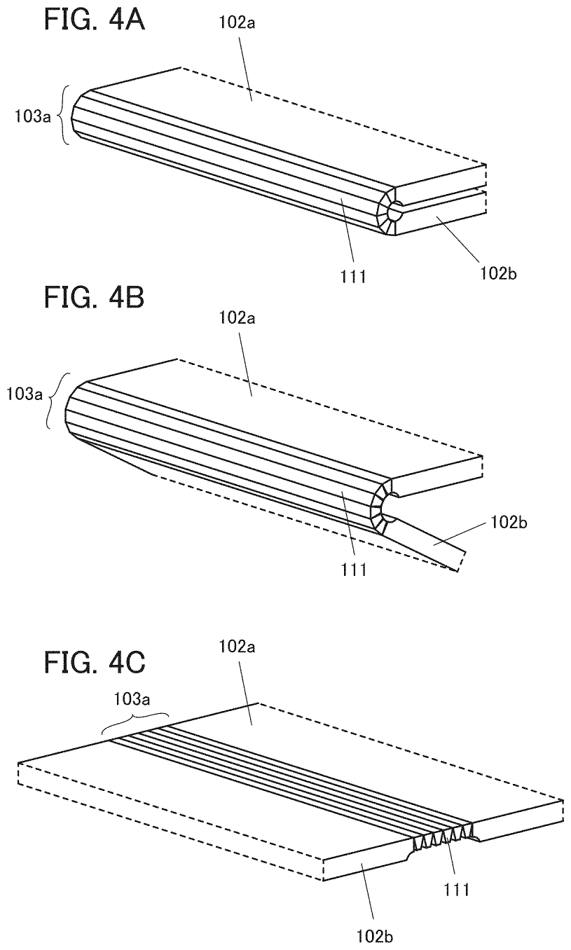

FIG. 4A to FIG. 4C illustrate an example of the hinge 103a that can be used for the display apparatus 100A illustrated in FIG. 1A.

The hinge 103a includes a plurality of columnar bodies 111 each of which has a trapezoidal or substantially trapezoidal cross section in the short-axis direction. The columnar bodies 111 are connected so that bottom surfaces (corresponding to the lower bases of trapeziums) are continuous. The bottom surface of the columnar body 111 at one end portion of the hinge 103a is continuously connected to the first surface of the housing 102a. Further, the bottom surface of the columnar body 111 at the other end portion of the hinge 103a is continuously connected to the first surface of the housing 102b. Note that the shape of the top surface (corresponding to the upper base of trapezium) of each of the columnar bodies 111 is freely determined within the scope not to interfere with the other columnar bodies and the housings.

As illustrated in FIG. 4A, the display apparatus is changed in shape such that side surfaces of adjacent columnar bodies 111 (corresponding to legs of trapezoids) are in contact with each other, so that a folded state can be obtained. At this time, the bottom surfaces of the plurality of columnar bodies 111 extend with a constant angle, so that a region where the whole cross section has a substantially circular arc shape is formed. Therefore, the display panel having flexibility can form a curved surface in a portion overlapping with this region.

When operation of change in shape (opening operation) is performed from the state of FIG. 4A, the side surfaces of the columnar bodies 111 move in the direction away from one another, and the radius of curvature of a substantially circular arc shape is changed so as to be large, as illustrated in FIG. 4B. At this time, the radius of curvature of the curved portion of the display panel is also changed so as to be large.

When operation of change in shape is further performed from the state of FIG. 4B, the first surface of the housing 102a, the bottom surfaces of the columnar bodies 111, and the first surface of the housing 102b extend to be flat as illustrated in FIG. 4C. At this time, the curved surface portion of the display panel is also changed to be flat, so that the whole becomes a flat opened state. When the operation of change in shape is performed in the reverse order, the display apparatus 100A can be folded.

Although the cross section of the columnar body 111 has a trapezoidal shape, it may be a triangular shape. There is no particular limitation on the structure for connecting the columnar bodies and the housings. Furthermore, a stopper may be provided so as not to cause bending in the direction opposite to the desired direction. Furthermore, a spacer for maintaining a gap between the housings when the display panel is folded may be provided. The housing or the hinge may be changed in shape as appropriate to be suitable for mounting of the display panel. These can be also applied to the hinge 103c described next.

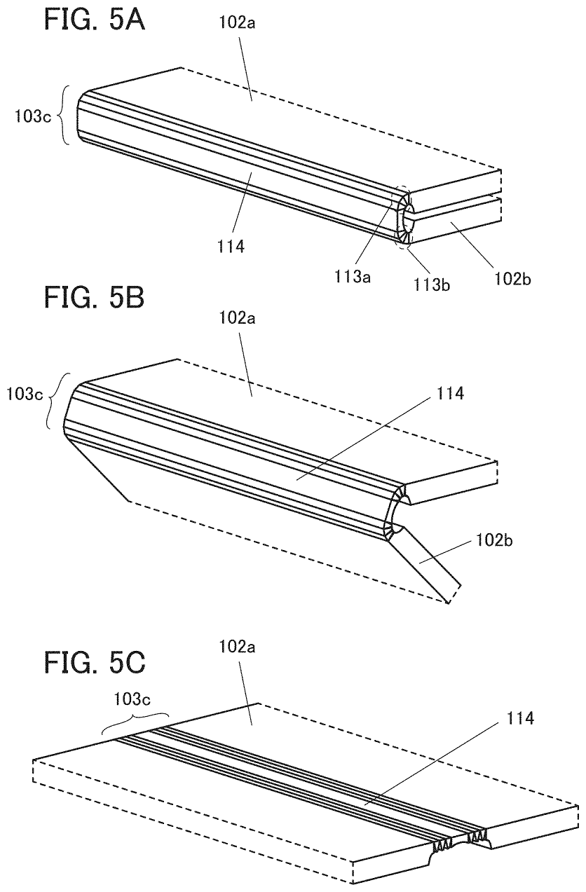

FIG. 5A to FIG. 5C illustrate an example of the hinge 103c that can be used in the display apparatus 100B in FIG. 3A.

The hinge 103c includes units 113a and 113b that have substantially the same components as the hinge 103a. Note that the number of columnar bodies in the units 113a and 113b may be different from that in the hinge 103a. Between the unit 113a and the unit 113b, a columnar body 114 having a flat bottom surface and a side surface perpendicular to the bottom surface is provided. The top surface shape of the columnar body 114 is freely determined within the scope not to interfere with the other columnar bodies and the housings.

As illustrated in FIG. 5A, the display apparatus 100B is changed in shape such that the side surfaces of the columnar bodies included in the unit 113a, the side surface of the columnar body 114, and the side surfaces of the columnar bodies included in the 113b are in contact with one another, so that a folded state can be obtained. At this time, the bottom surfaces of the columnar bodies included in the unit 113a extend with a certain angle, so that a region where a cross section has a substantially circular arc shape is formed. The same applies to the unit 113b. Therefore, the display panel having flexibility can form a curved surface, a plane surface, and a curved surface in a portion overlapping with this region.

The columnar bodies included in the units 113a, the columnar body 114, and the columnar bodies included in the unit 113b are connected such that the bottom surfaces are continuous. The bottom surface of the columnar body at one end portion of the unit 113a is continuously connected to the first surface of the housing 102a. The bottom surface of the columnar body at one end portion of the unit 113b is continuously connected to the first surface of the housing 102b.

When operation of change in shape (opening operation) is performed from the state of FIG. 5A, the side surfaces of the columnar bodies included in the units 113a and 113b move in the direction away from one another, and the radius of curvature of a substantially circular arc shape is changed so as to be large, as illustrated in FIG. 5B. At this time, the radius of curvature of the curved portion of the display panel is also changed so as to be large.

When operation of change in shape is further performed from the state of FIG. 5B, as illustrated in FIG. 5C, the first surface of the housing 102a, the bottom surfaces of the columnar bodies of the unit 113a, the bottom surface of the columnar body 114, the bottom surfaces of the columnar bodies of the unit 113b, and the first surface of the housing 102b extend to be flat. At this time, the curved surface portion of the display panel is also changed to be flat, so that the whole becomes a flat opened state. When the operation of the change in shape is performed in the reverse order, the display apparatus can be folded.

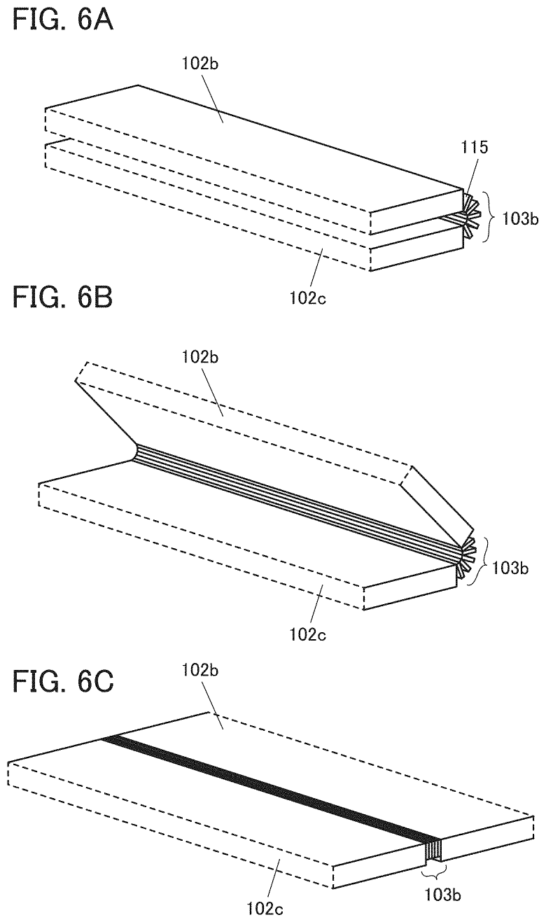

FIG. 6A to FIG. 6C illustrate an example of the hinge 103b that can be used for the display apparatus 100A in FIG. 1A or the display apparatus 100B in FIG. 3A.

The hinge 103b includes a plurality of columnar bodies 115 each have a rectangular cross section in the short-axis direction. The columnar bodies 115 are connected so that bottom surfaces are continuous. Further, the bottom surface of the columnar body 115 at one end portion of the hinge 103b is continuously connected to the first surface of the housing 102a. The bottom surface of the columnar body 115 at the other end portion of the hinge 103b is continuously connected to the first surface of the housing 102c. Note that the top surface shape of each of the columnar bodies 115 is freely determined within the scope not to interfere with the other columnar bodies and the housings.

As illustrated in FIG. 6A, when the display apparatus is changed in shape in a direction such that side surfaces of adjacent columnar bodies 115 are apart from one another, a folded state can be obtained. At this time, the bottom surfaces of the plurality of columnar bodies 115 extend with a certain angle, a region where the whole cross section has a substantially circular arc shape is formed. Therefore, the display panel having flexibility can form a curved surface in a portion overlapping with this region.

When operation of change in shape (opening operation) is performed from the state of FIG. 6A, the side surfaces of the columnar bodies 115 move to come close to one another as illustrated in FIG. 6B, and the radius of curvature of a substantially circular arc shape is changed to be large. At this time, the radius of curvature of the curved portion of the display panel is also changed so as to be large.

When operation of change is further performed from the state of FIG. 6B, as illustrated in FIG. 6C, the first surface of the housing 102b, the bottom surfaces of the columnar bodies 115, and the first surface of the housing 102c extend to be flat. At this time, the curved surface portion of the display panel is also changed to be flat, so that the whole becomes a flat opened state. When the operation of change in shape is performed in the reverse order, the display apparatus can be folded.

Note that the columnar bodies 115 each have a rectangular cross section; thus, the side surfaces of the columnar bodies 115 are in contact with one another when it is opened flat. Thus, the hinge 103b does not cause bending of the display panel in the opposite direction, and a stopper can be unnecessary. Note that a spacer for maintaining a gap between the housings when the display panel is folded may be provided. The housing or the hinge may be changed in shape as appropriate to be suitable for mounting of the display panel.

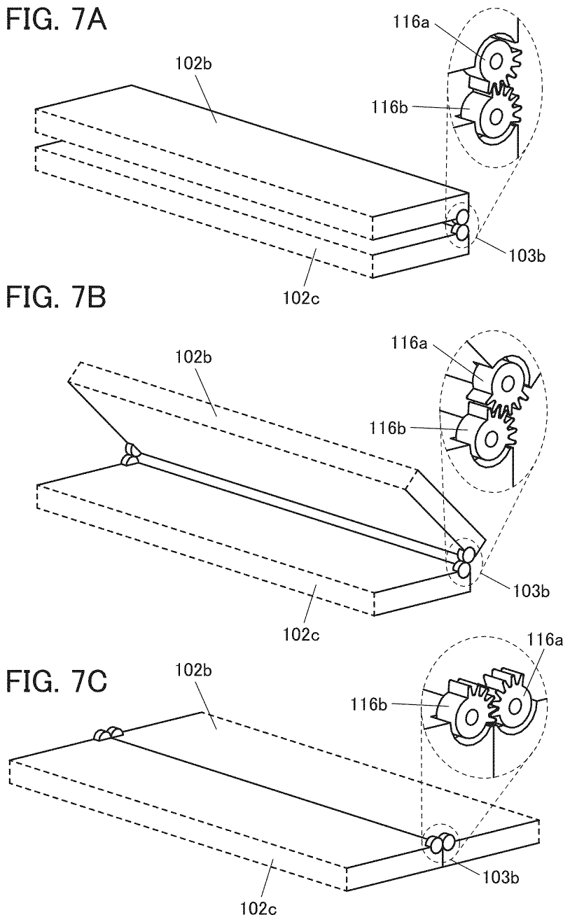

FIG. 7A to FIG. 7C illustrate another example of the hinge 103b.

The hinge 103b includes a gear 116a and a gear 116b. The gear 116a is fixed to the housing 102a. The gear 116b is fixed to the housing 102b. The center axis of the gear 116a preferably overlaps with the first surface of the housing 102a. The center axis of the gear 116b preferably overlaps with the first surface of the housing 102b.

As illustrated in FIG. 7A, the gear 116a is engaged with the gear 116b in a particular position in a folded state. At this time, the center axes of the two gears are each on the first surface of the housing, thereby generating a gap between the housings (between the display surfaces facing each other of the display panel). Therefore, the display panel having flexibility can form a curved surface whose radius of curvature corresponds approximately half of this gap.

When operation of change in shape (opening operation) is performed from the state of FIG. 7A, the housing 102b and the housing 102c are synchronized in accordance with engagement of the gear 116a and the gear 116b, and move to open with the hinge 103b as a pivot (see FIG. 7B). At this time, the radius of curvature of the curved portion of the display panel is also changed to be large.

When the operation of change in shape is further performed from the state of FIG. 7B, as illustrated in FIG. 7C, the first surface of the housing 102b and the first surface of the housing 102c extend to be flat. At this time, the curved surface portion of the display panel is also changed to be flat, so that the whole becomes a flat opened state. When the operation of change in shape is performed in the reverse order, the display apparatus can be folded.

Note that a mechanism for holding the engagement of the gear 116a and the gear 116b may be provided. When the display panel is opened flat, the side surface of the housing 102c and the side surface of the housing 102c are in contact with each other. Thus, the hinge 103b does not cause bending of the display panel in the opposite direction, and thus a stopper can be unnecessary. Note that a spacer for maintaining a gap between the housings when the display panel is folded may be provided. Alternatively, a mechanism for maintaining the gap may be provided for the gear 116a and the gear 116b. Further alternatively, the housings or the hinge may be changed in shape as appropriate to be suitable for mounting of the display panel.

### Modification Example 2 of Display Apparatus

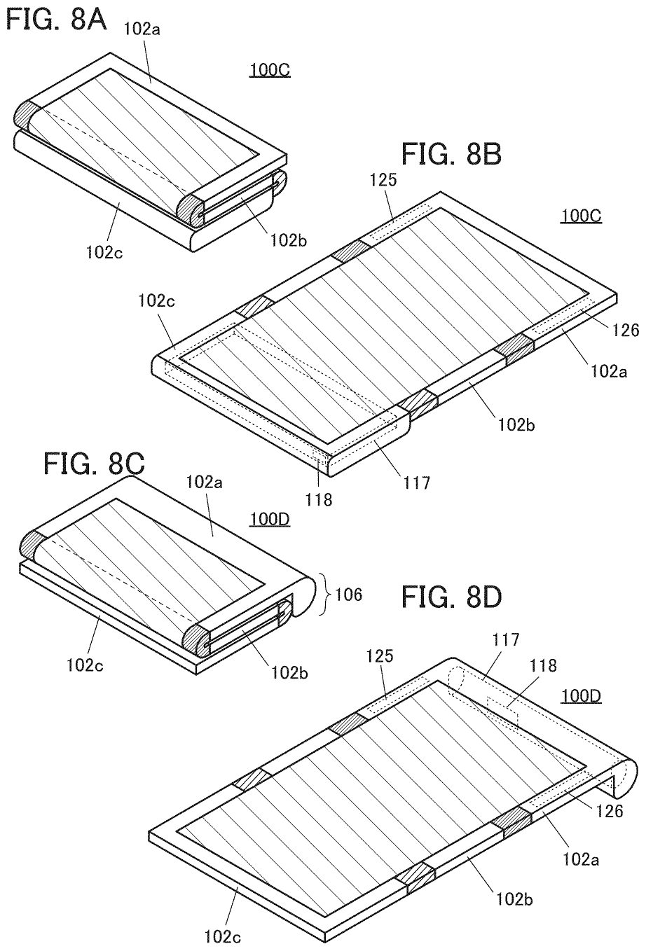

FIG. 8A illustrates a display apparatus 100C, which is a modification example of the display apparatus 100A. The display apparatus 100C is different from the display apparatus 100A in the shape of the housing 102c.

The housing 102c of the display apparatus 100C is formed to have larger thickness than the housing 102a and the housing 102b. When the housing 102c is formed thick as illustrated in FIG. 8B, a battery 117 with a relatively large size can be included, and the display apparatus can be operated for a long time. Furthermore, by including the battery 117 that is relatively heavy in the housing 102c, the gravity center of the display apparatus 100C can be positioned inside the housing 102c not only in the state of FIG. 8A but also in the state of FIG. 8B. The thick housing 102c and the gravity center positioned inside the housing 102c can enhance easy holding of the display apparatus when it is opened flat.

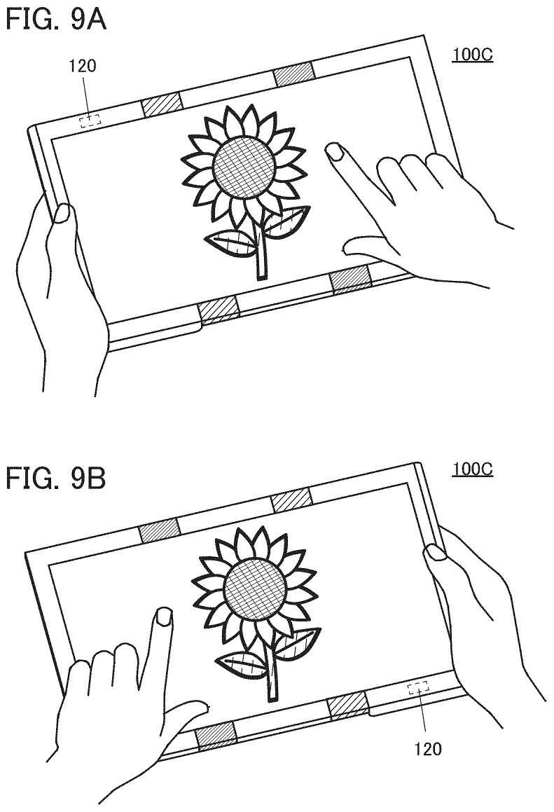

Furthermore, the display apparatus 100C has an easy-to-operate structure regardless of hand dominance. FIG. 9A shows the case where the housing 102c side of the display apparatus 100C is held with a left hand and screen touch operation is performed with a right hand. FIG. 9B shows the case where the housing 102c side of the display apparatus 100C is held with a right hand and screen touch operation is performed with a left hand. In either case, an image can be displayed so as to be easily viewed by a user.

This operation is performed such that inclination of the display apparatus 100C is sensed by a sensor 120 (such as acceleration sensor or a gyro sensor) included in the display apparatus 100C and orientation of image display is determined from the inclination. The sensor 120 can sense vibration of the display apparatus 100C from the change in inclination. There are individual differences in the vibration; thus, the artificial intelligence (AI) is made to learn vibration information to judge a user. Personal authentication can be also performed by utilizing this function. The sensor 120 can be also provided in another display apparatus described in this embodiment.

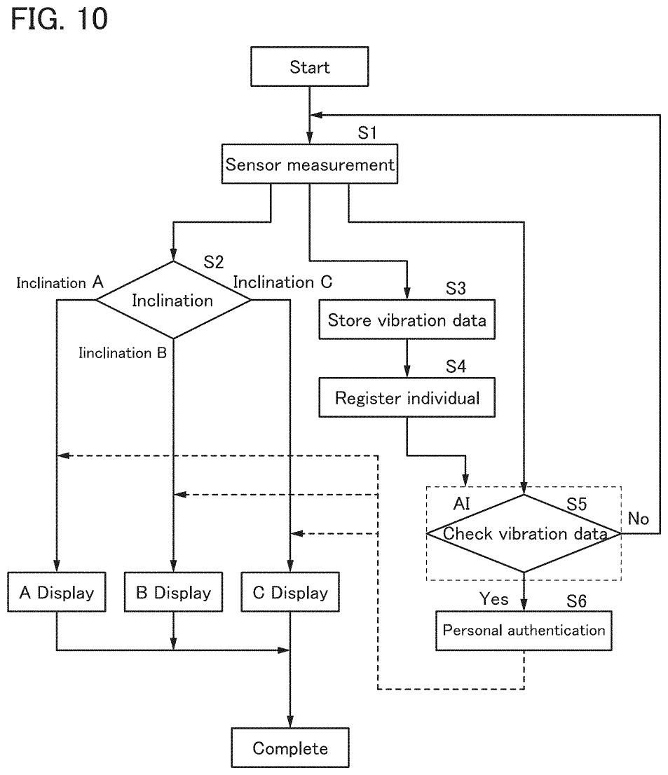

FIG. 10 is a flow chart for performing operation of determining the orientation of display image and for performing personal authentication, using the sensor 120.

The path from S1 to S2 is operation of determining the orientation of image display by utilizing a sensing result of inclination by the sensor. Note that inclination occurs in a plurality of directions, and inclination A, inclination B, and inclination C include inclination conditions in the plurality of directions. Here, inclination A is set in the range including inclination of the display apparatus 100C shown in FIG. 9A, inclination C is set in the range including inclination of the display apparatus 100C shown in FIG. 9B, and inclination B is set in the range including inclination in which the long-axis direction of the display apparatus 100C is the vertical direction. Note that inclination B has two ways, upside-down orientation and right-side-up orientation, determination may be performed in the range including four types of inclination.

When it is judged to be inclination A, “A display” is performed. “A display” is a mode in which an image is displayed in the direction shown in FIG. 9A. When it is judged to be inclination C, “C display” is performed. “C display” is a mode in which an image is displayed in the direction shown in FIG. 9B. When it is judged to be inclination B, “B display” is performed. “B display” is a display mode in which the image of the display apparatus 100C shown in FIG. 9A is rotated by about 90 degrees. In this manner, by the use of the sensor 120, display can be performed while the orientation of the image is changed so that the image is easily viewed.

The path through S1, S3, and S4 is operation to store data on vibration that is sensed by the sensor 120 and to register the data and an individual. The data registered here becomes data to identify an individual. Note that the data can be updated every time when the display apparatus is used.

The path through S1, S5, and S6 is operation to check up the above data with data corresponding to vibration output from the sensor 120 in real time to perform personal authentication. For the checking, artificial intelligence (AI) where deep learning of the accumulated individual data on vibration has done can be used. This operation can be performed after individual information is stored in the above database. In this manner, personal authentication can be performed using the sensor 120.

If an individual is identified, the orientation of the display apparatus 100C which the person prefers to use can be known, so that default display orientation can be set in advance. When the angle of the display apparatus 100C is judged by the sensor 120 alone, the sensor 120 reacts sensitively to slight vibration of the display apparatus 100C in some cases. In this situation, it might take time to view the image normally due to a frequent occurrence of rotation of the image, and the like. Furthermore, wasted power is also consumed. Setting of the display orientation by default can shorten the time required for viewing and reduce power consumption.

For example, when an individual often holds the display apparatus 100C as illustrated in FIG. 9A, “A display” can be used as default. To the contrary, when an individual often hold the display apparatus 100C as illustrated in FIG. 9B, “C display” can be used as default. Note that only operation using the sensor 120 may be performed without utilizing such a function.

FIG. 8C and FIG. 8D illustrate a display apparatus 100D in which a battery is included in the housing 102a. The display apparatus 100D includes a grip portion 106 at an end portion of the housing 102a, and the battery 117 is included in the grip portion 106. The gravity center of the display apparatus 100D is positioned in the grip portion 106 including the battery 117 with a relatively large weight, easy holding can be enhanced. Furthermore, as illustrated in FIG. 8D, the display apparatus can be utilized in a stable mode on a desk with the grip portion serving as a leg when it is opened flat. Because the display surface is slanted, the visibility can be improved.

Furthermore, it is preferable that the protection circuit 118 be provided in the battery 117 as illustrated in FIG. 8B and FIG. 8D. Although a lithium ion battery whose capacity can be increased is preferably used as the battery 117, a firing accident occurs due to an abnormality (a micro-short circuit) inside the battery in rare cases.

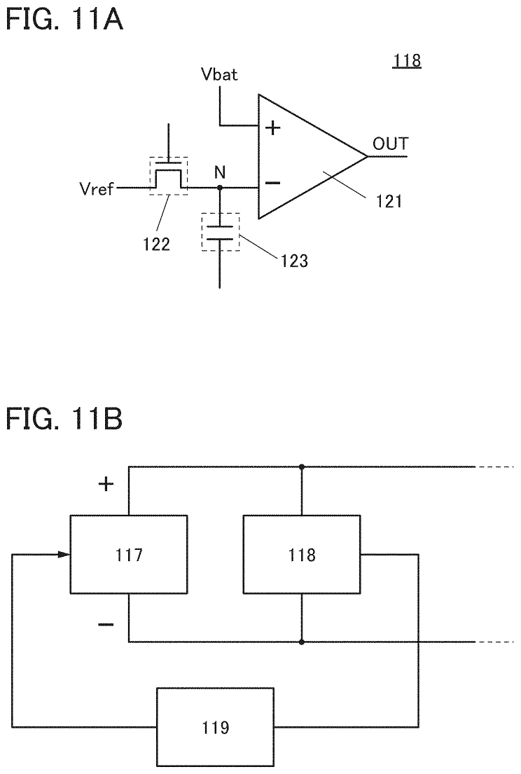

The protection circuit 118 can have a structure of including a comparator 121, a transistor 122, and a capacitor 123, as illustrated in FIG. 11A. The comparator 121 compares a voltage (V_{bat}) of the battery 117 and a reference potential (V_{ref}) which is the lower limit of the normal value, and inverts a logic value to be output from an output terminal (OUT) when V_{bat} is lower than V_{ref}. V_{ref} is written to a node N to which the transistor 122, the capacitor 123, and one of input terminals of the comparator 121 are connected, and can be held.

Since the potential written to the node N can be held by the use of the transistor 122 and the capacitor 123, a circuit in which the transistor 122 and the capacitor 123 are combined can be referred to as a memory circuit or a DOSRAM (Dynamic Oxide Semiconductor Random Access Memory). A DOSRAM can be formed using one transistor and one capacitor, so that high density of a memory can be achieved. With the use of an OS transistor, a data retention period can be extended.

Rewriting of Vref is performed in every certain period in accordance with a change in voltage due to charge and discharge of the battery 117. In the protection circuit 118, an OS transistor is preferably used as the transistor 122. An OS transistor has a low off-state current and a potential written to the node N can be retained in a state of substantially no change.

In the case where an OS transistor is used as the transistor 122, the protection circuit 118 including the above-described memory circuit is referred to as BTOS (Battery operating system or Battery oxide semiconductor) in some cases.

As illustrated in FIG. 11B, the battery 117 is electrically connected to the protection circuit 118, and the output of the protection circuit 118 is connected to the control circuit 119. When sensing a sudden voltage drop or the like of the battery 117, the protection circuit 118 inverts a logic value of a signal to be output to the control circuit 119. At this time, the control circuit 119 performs control such that charging and discharging of the battery 117 is stopped, whereby security of a user is ensured.

Furthermore, as illustrated in FIG. 8B and FIG. 8D, an antenna 125 and an antenna 126 are preferably provided in the housing 102a. The antenna 125 is an antenna for a fourth-generation mobile communication system (4G), and the antenna 126 is a fifth-generation mobile communication system (5G). The 5G communication can provide high-speed communication of 10 to 20 times faster than the 4G communication.

Although FIG. 8B and FIG. 8D each illustrate a structure in which the antenna 125 and the antenna 126 are both provided, one embodiment of the present invention is not limited thereto. For example, a structure in which only the antenna 125 is provided in the housing 102a or a structure in which only the antenna 126 is provided in the housing 102a may be employed. Although FIG. 8B and FIG. 8D each illustrate a structure in which one antenna 125 and one antenna 126 are provided, one embodiment of the present invention is not limited thereto. For example, a structure in which a plurality of antennas 125 is provided or a structure in which a plurality of antennas 126 is provided may be employed.

Provision of both antenna 125 and antenna 126 in the housing 102a enables favorable communication to be performed easily. Since a user mostly uses in the way that the user can easily view the display (the way of placing, the way of holding) also when the display apparatus is folded, the housing 102a is usually turned in the direction where a radio wave proceeds (the upper and outer side direction), so that the radio wave is easily received.

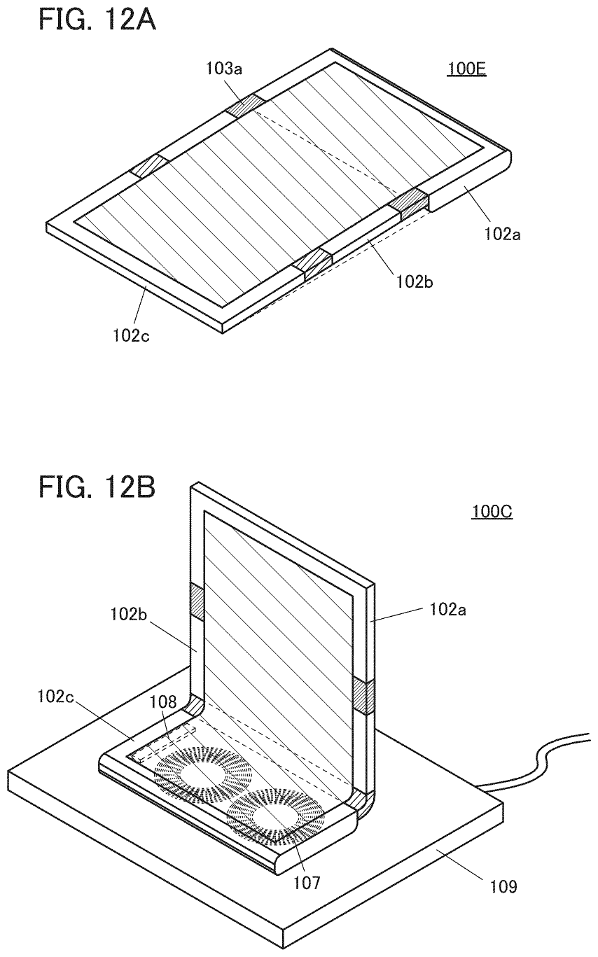

Although an example is illustrated in FIG. 8A and FIG. 8B, where the shape of the housing 102c is made thicker than the other housings so as to include a battery and the like, the shape of the housing 102a may be made thicker than the other housings like a display apparatus 100E as illustrated in FIG. 12A. In that case, the hinge 103a corresponding to external bending is bent as appropriate, so that the display apparatus can be placed on a desk or the like in a balanced manner.

Furthermore, because a plane portion of the display surface can be divided into two with the hinge 103a as a boundary, in case of displaying a plurality of images, an appropriate image can be allocated to each plane portion, thereby improving visibility. Furthermore, power saving operation can be also performed by setting one of the plane portions in a non-display state.

In the housing 102c of the display apparatus 100C, as illustrated in FIG. 12B, a power receiving coil 107, a power receiving circuit 108, and the like may be provided. Wireless charging can be performed by overlapping the power receiving coil 107 and a transmitting coil included in a charger 109.

A magnetic flux is generated when current is made to flow into the transmitting coil included in the charger 109, and current is generated in the power receiving coil 107 by electromagnetic induction. Current is rectified by the power receiving circuit 108 and used in charging of a battery connected to the power receiving circuit 108.

The display apparatus 100C can be installed such that the housing 102c having the gravity center is on and in contact with the charger 109. As illustrated in FIG. 12B, the display apparatus 100C can be stably put on the charger 109 even when it is not folded. Furthermore, even in charging, the display apparatus 100C can be utilized without lowering the visibility. Note that the power receiving coil 107 can be provided for all of, any two of, or any one of the housings 102a, 102b, and 102c.

### Display Operation Example 1

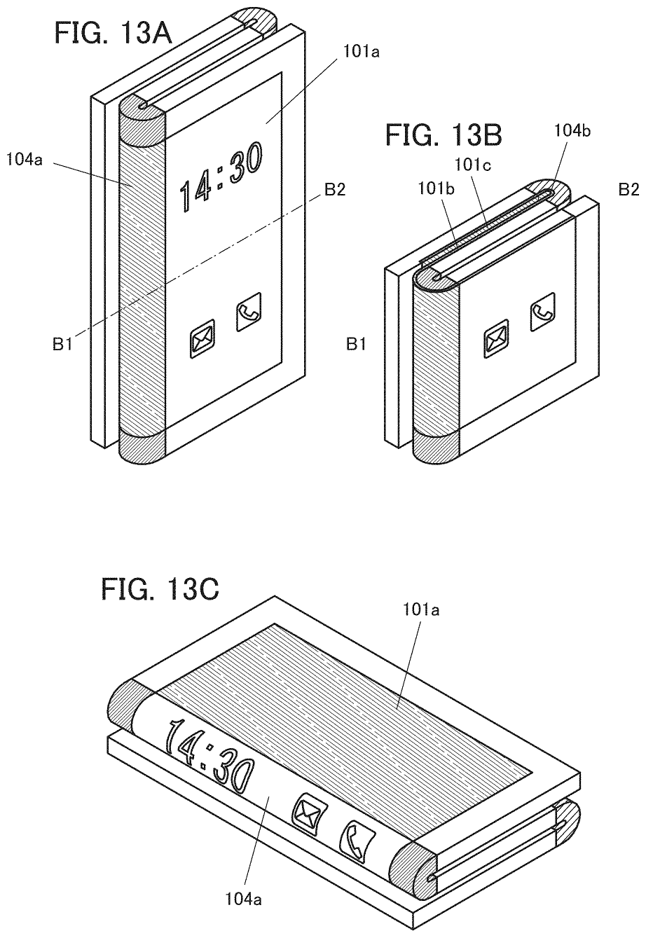

FIG. 13A to FIG. 13C illustrate operation examples which are common to the display apparatuses 100A to 100E of embodiments of the present invention. Note that in FIG. 13A to 13C, typically, the case where the display apparatus 100A is used is shown. FIG. 13A shows operation in a folded state, in which the plane surface portion of the region 101a is in a display state and the curved surface 104a is in a non-display state. In that case, as illustrated in a cross-sectional view along line B1-B2 in FIG. 13B, a region which can not be seen (the region 101b and the region 101c which include the curved surface 104b) in the folded state is preferably put in a non-display state.

Alternatively, as illustrated in FIG. 13C, when the plane surface portion of the region 101a is in a non-display state, the curved surface 104a may be in a display state. Similarly to the above, the region which can not be seen in the folded state is preferably put in a non-display state. In such a manner, when the display is in a folded state, only a part of region is put in a display state, so that power saving operation can be performed.

### Display Operation Example 2

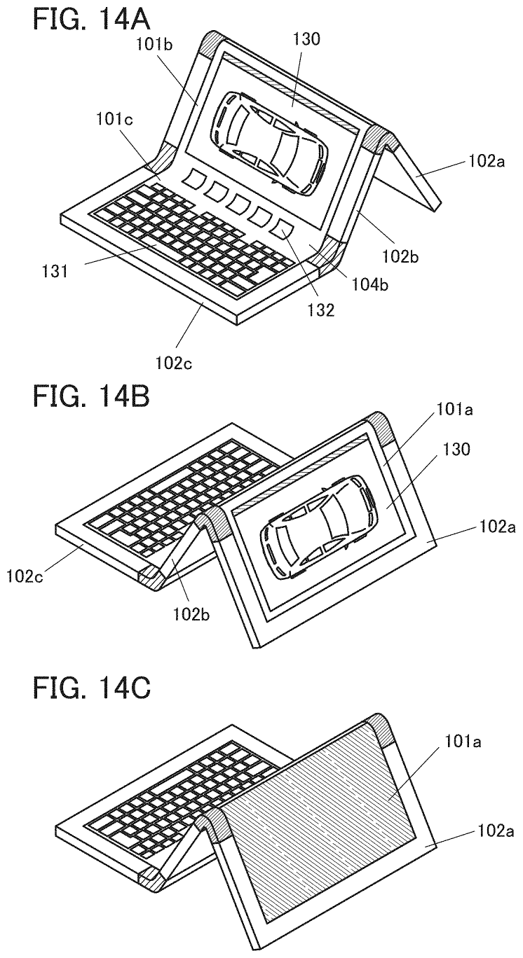

FIG. 14A to FIG. 14C illustrate examples where the display portions of the display apparatuses 100A to 100D of embodiments of the present invention are each divided into three planes to be used.

FIG. 14A illustrates an example in which the display apparatus is placed on a desk in a balanced manner by setting the angle between the housing 102c and the housing 102b at an obtuse angle and the angle between the housing 102b and the housing 102a at an acute angle. Using the housing 102a as a leg allows the display apparatus to be utilized like a lap top computer. Operation can be performed by touching the screen with a keyboard 131, icons 132, and an image 130 of application soft displayed on the region 101c, the curved surface 104b, and the region 101b, respectively.

At this time, as illustrated in FIG. 14B, when a mode is adopted in which the same image as the image 130 on the region 101b is also displayed on the region 101a, the same image can be seen with high visibility by a person in the opposite side. Further alternatively, as illustrated in FIG. 14C, operation may be performed in a power saving mode with the region 101a in a non-display state.

### Display Operation Example 3

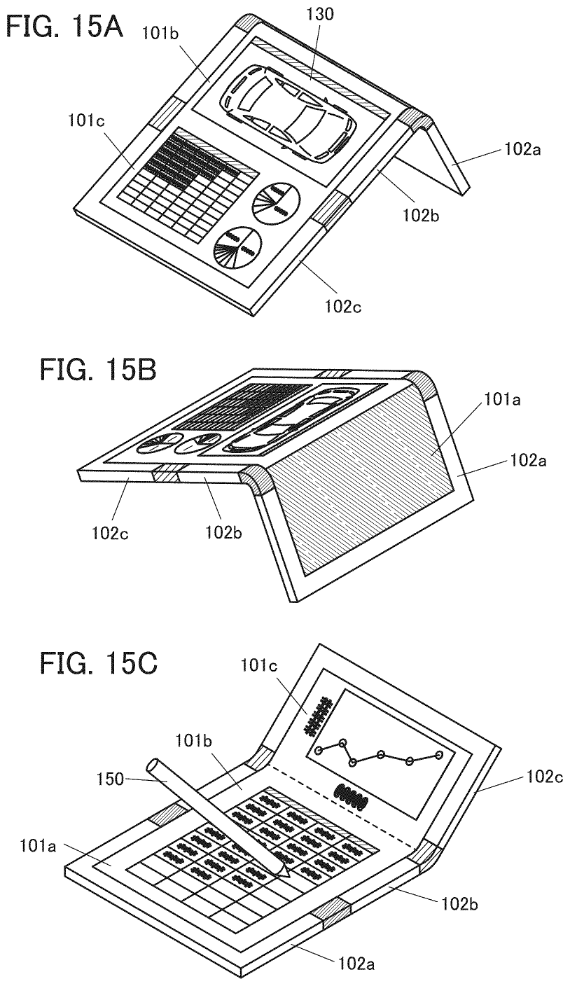

FIG. 15A to FIG. 15C are diagrams which illustrate examples of the case where the display portions of the display apparatuses 100A to 100E of embodiments of the present invention are each divided into two planes to be used.

FIG. 15A is a diagram illustrating an example in which the display apparatus is placed on a desk in a balanced manner by setting the angle between the housing 102a and the housing 102b at substantially greater than or equal to 60° and less than 180° (e.g., about 90°) and the angle between the housing 102b and the housing 102c at substantially 180°. An increase in the screen size with the region 101b and the region 101c as a continuous plane surface and an inclination of the display surface (the region 101b and the region 101c) using the housing 102a as a leg can enhance the visibility.

At this time, as illustrated in FIG. 15B, operation may be performed in a power saving mode with the region 101a in a non-display state.

FIG. 15C is a diagram illustrating an example in which the display apparatus is placed on a desk in a balanced manner by setting the angle between the housing 102c and the housing 102b at substantially less than 180° and greater than or equal to 90° (e.g., about 135°) and setting the angle between the housing 102b and the housing 102a at substantially 180°. The housing 102a and the housing 102b are placed parallel to a plane surface such as a desk, whereby input with a stylus 150 or the like can be easily performed. Furthermore, an inclination of the region 101c can enhance the visibility.

### Application Example 1

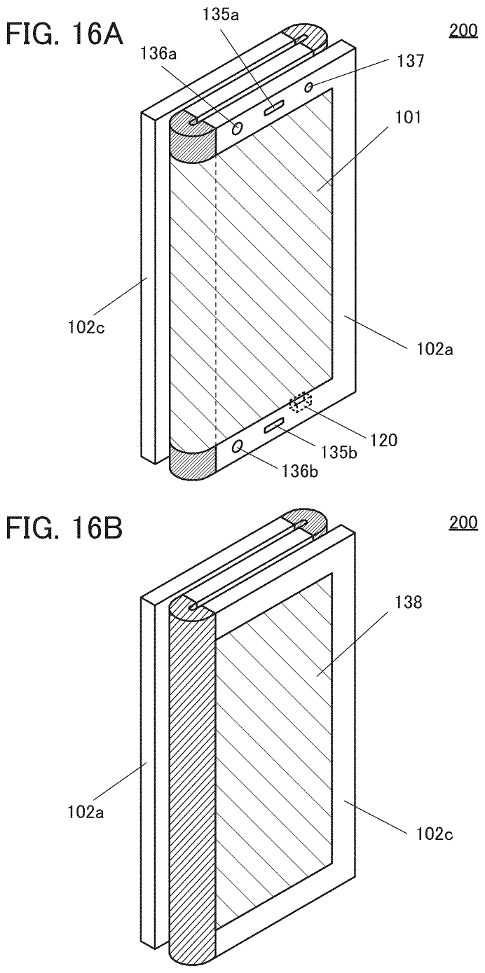

FIG. 16A and FIG. 16B are diagrams each illustrating an application example in which the display apparatus described in this embodiment is used as an information terminal such as a smartphone. Note that components common to those in the above-described display apparatuses are denoted by the same reference numeral. A display apparatus 200 includes sound input/output units 135a and 135b, cameras 136a and 136b, a sensor 137, and a sensor 120.

When one of the sound input/output units 135a and 135b functions as a microphone, the other can function as a speaker. Thus, when a telephone function is utilized, for example, conversation can be made without inconvenience regardless of the side of the display a user holds. The microphone function and the speaker function can be switched by the sensor 120 which senses inclination. Similarly, either of the cameras 136a and 136b can preferentially function by the sensor 120.

The input/output units 135a and 135b may have both of a device functioning as a microphone and a device functioning as a speaker, or may have a device having both of the functions.

Alternatively, the input/output units 135a and 135b both can function as microphones and can record stereo sound. Further alternatively, the input/output units 135a and 135b both can function as speakers and can reproduce stereo sound.

Both of the camera 136a and the camera 136b are allowed to function so that 3D image can be taken. The sensor 137 is an optical sensor, which can adjust luminance of display in accordance with ambient illuminance so as to be easily viewed.

As illustrated in FIG. 16B, a display panel 138 may be provided on a back surface opposite to the front surface where the display panel 101 of the display apparatus 200 is provided. The display panel 138 can display the same image as that on the display panel 101 and can also be utilized as a sub-display which displays simple information, a picture, a pattern, a photograph, and the like, lighting, or the like. Other than a display panel using a light-emitting device or a liquid crystal device, low-power consumption electronic paper, or the like can be used for the display panel 138. For the display panel 138, a display panel using a rigid substrate as a support can be used.

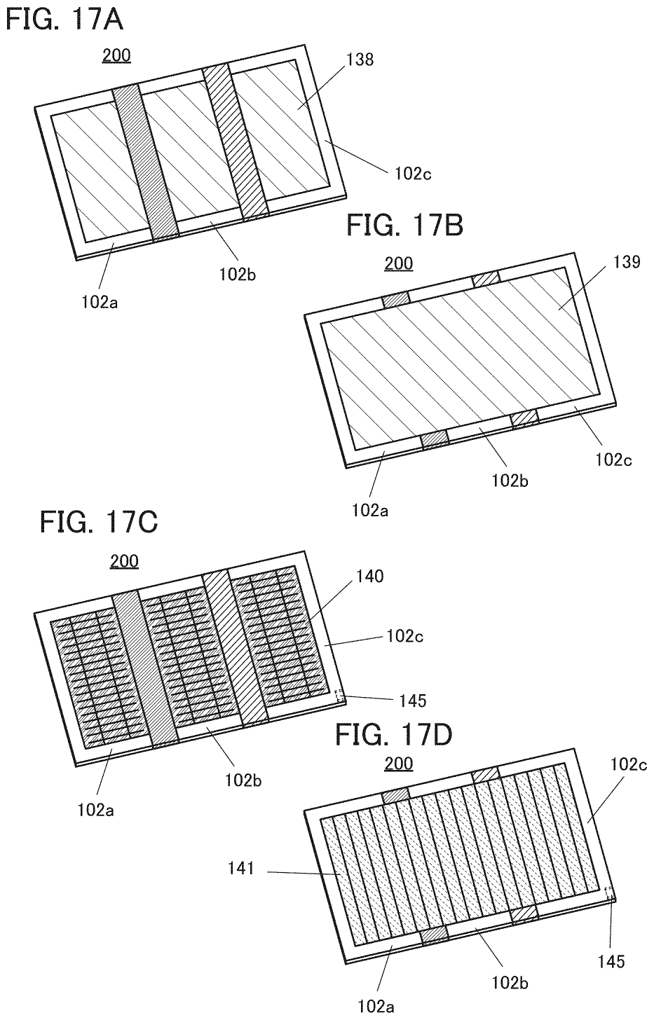

Note that the display panel 138 can be provided for each of the housings 102a to 102c as illustrated in FIG. 17A. Alternatively, as illustrated in FIG. 17B, a display panel 139 having flexibility may be provided on the back surface of the display apparatus 200. In this case, the display panel 139 can be bent, so that the display panel 139 can be provided across the housings 102a to 102c as in the display panel 101 provided on the front surface.

As illustrated in FIG. 17C, a solar cell 140 may be provided on the back surface of the display apparatus 200. A battery in the display apparatus 200 can be charged with electric power generated by the solar cell 140, and the electric power can be supplied to the outside through an external interface 145.

Note that FIG. 17C illustrates an example of a solar cell including a rigid support. As the solar cell, for example, a silicon solar cell in which crystal silicon is used for a photoelectric conversion layer, a solar cell in which a tandem structure of a silicon solar cell and a perovskite type solar cell is used, or the like can be used.

Alternatively, as illustrated in FIG. 17D, a solar cell in which a flexible substrate is used as a support may be used. As the solar cell, for example, a thin film solar cell 141 such as an amorphous silicon solar cell, CIGS(Cu—In—Ga—Se) type solar cell, an organic solar cell, or a perovskite type solar cell can be used. The solar cell in which a flexible substrate is used as a support can be provided across the housings 102a to 102c as in the display panel 139.

### Application Example 2

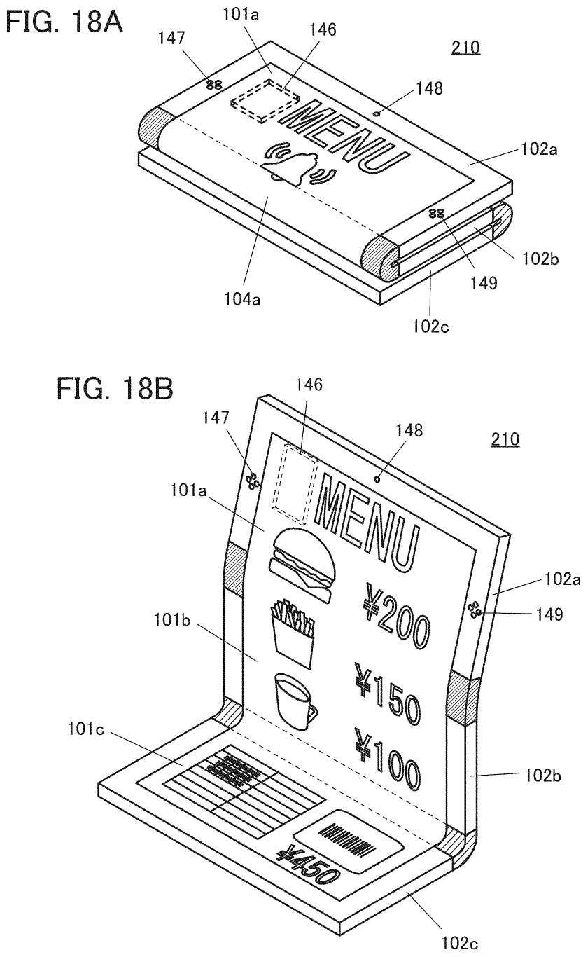

FIG. 18A and FIG. 18B illustrate usage examples of the case where the display portions of the display apparatuses 100A to 100D of embodiments of the present invention are selected depending on the purpose and the usage.

FIG. 18A and FIG. 18B are diagrams illustrating an example in which the display apparatus described in this embodiment is used as an order terminal at an restaurant or the like. Note that components common to those in the above-described display apparatuses are denoted by the same reference numeral. The display apparatus 210 includes a transmitting and receiving unit 146, a speaker 147, a camera 148, a microphone 149, and the like. Note that the display apparatus 210 may have a function of a general tablet type computer as well as the function of one embodiment of the present invention.

In the normal condition, the display apparatus can be in a folded state as illustrated in FIG. 18A, and a clerk-calling function and an interphone function can be utilized. A menu is displayed when the display apparatus is opened, and an order can be made. The ordered item can be transmitted through the transmitting and receiving unit 146. In addition, the total sum of the order can be displayed and payment with a barcode taken by the camera 148 can be performed.

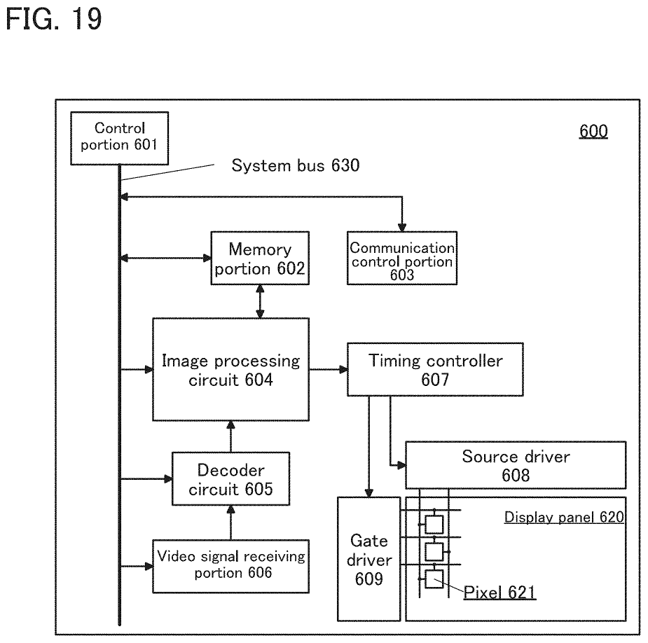

FIG. 19 is a block diagram illustrating an example in which the display apparatus of one embodiment of the present invention is used as a television device.

Although in FIG. 19, components are classified by their functions and illustrated as independent blocks, it is difficult to completely divide actual components according to their functions and one component can relate to a plurality of functions.

A television device 600 includes a control portion 601, a memory portion 602, a communication control portion 603, an image processing circuit 604, a decoder circuit 605, a video signal receiving portion 606, a timing controller 607, a source driver 608, a gate driver 609, a display panel 620, and the like.

The display panel 620 corresponds to the display panel 101 described in Embodiment 1, and the other components can exist in any of the housing 102a to the housing 102c. Note that some components such as the source driver 608 and the gate driver 609 may be components of the display panel 101.

The control portion 601 can function as, for example, a central processing unit (CPU). For example, the control portion 601 has a function of controlling components such as the memory portion 602, the communication control portion 603, the image processing circuit 604, the decoder circuit 605, and the video signal receiving portion 606 via a system bus 630.

Signals are transmitted between the control portion 601 and the components via the system bus 630. The control portion 601 has a function of processing signals input from the components which are connected via the system bus 630, a function of generating signals to be output to the components, and the like, so that the components connected to the system bus 630 can be controlled comprehensively.

The memory portion 602 functions as a register, a cache memory, a main memory, a secondary memory, or the like that can be accessed by the control portion 601 and the image processing circuit 604.

As a memory device that can be used as a secondary memory, a memory device including a rewritable nonvolatile memory can be used, for example. For example, a flash memory, an MRAM (Magnetroresistive Random Access Memory), a PRAM (Phase change RAM), a ReRAM (Resistive RAM), or an FeRAM (Ferroelectric RAM) can be used.

As a memory device that can be used as a temporary memory such as a register, a cache memory, or a main memory, a volatile memory such as a DRAM (Dynamic RAM) or an SRAM (Static Random Access Memory) may be used.

For example, a DRAM is used as a RAM provided in the main memory, in which case a memory space is virtually allocated and used as a workspace of the control portion 601. An operating system, an application program, a program module, program data, and the like which are stored in the memory portion 602 are loaded into the RAM for execution. The data, program, and program module which are loaded into the RAM are directly accessed and operated by the control portion 601.

In the ROM, a BIOS (Basic Input/Output System), firmware, and the like for which rewriting is not needed can be stored. As the ROM, a mask ROM, a OTPROM (One-Time Programmable Read Only Memory), an EPROM (Erasable Programmable Read Only Memory), or the like can be used. As an EPROM, an UV-EPROM (Ultra-Violet Erasable Programmable Read Only Memory) which can erase stored data by irradiation with ultraviolet rays, an EEPROM (Electrically Erasable Programmable Read Only Memory), a flash memory, and the like can be given.

A configuration may be employed in which besides the memory portion 602, a detachable memory device can be connected. For example, it is preferable to provide a terminal connected to a storage media drive functioning as a storage device such as a hard disk drive (HDD) or a solid state drive (SSD) or a storage medium such as a flash memory, a Blu-ray Disc, or a DVD. With such a structure, an image can be stored.

The communication control portion 603 has a function of controlling communication performed via a computer network. That is, lot (Internet of Things) technology is used in the television device 600.

For example, the communication control portion 603 controls a control signal for connection to a computer network in response to instructions from the control portion 601 and transmits the signal to the computer network. Accordingly, communication can be performed by connecting to a computer network such as the Internet, which is an infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network).

The communication control portion 603 may have a function of communicating with a computer network or another electronic device with a communication standard such as Wi-Fi (registered trademark), Bluetooth (registered trademark), or ZigBee (registered trademark).

The communication control portion 603 may have a function of wireless communication. For example, an antenna and a high frequency circuit (an RF circuit) are provided to receive and transmit an RF signal. The high frequency circuit is a circuit which converts an electromagnetic signal into an electric signal in a frequency band in accordance with respective national laws and transmits the electromagnetic signal wirelessly to another communication device. Several tens of kilohertz to several tens of gigahertz are a practical frequency band which is generally used. The high frequency circuit connected to an antenna includes a high frequency circuit portion compatible with a plurality of frequency bands; the high frequency circuit portion can include an amplifier, a mixer, a filter, a DSP, an RF transceiver, or the like.

The video signal receiving portion 606 includes, for example, an antenna, a demodulation circuit, and analog-digital conversion circuit (AD converter circuit), and the like. The demodulation circuit has a function of demodulating a signal input from the antenna. The AD converter circuit has a function of converting the demodulated analog signal into a digital signal. The signal processed in the video signal receiving portion 606 is transmitted to the decoder circuit 605.

The decoder circuit 605 has a function of decoding video data included in a digital signal input from the video signal receiving portion 606, in accordance with the specifications of the broadcasting standard for transmitting the video data, and generating a signal transmitted to the image processing circuit. For example, as the broadcasting standard in 8K broadcasts, H.265 MPEG-H High Efficiency Video Coding (hereinafter referred to as HEVC) is given.

The antenna included in the video signal receiving portion 606 can receive airwaves such as a ground wave and a satellite wave. The antenna can receive airwaves for analog broadcasting, digital broadcasting, and the like, and image-sound-only broadcasting, sound-only broadcasting, and the like. For example, the antenna can receive airwaves transmitted in a certain frequency band, such as a UHF band (about 300 MHz to 3 GHz) or a VHF band (30 MHz to 300 MHz). When a plurality of pieces of data received in a plurality of frequency bands is used, the transfer rate can be increased and more information can thus be obtained. Accordingly, the display panel 620 can display a video with a resolution higher than the full high definition, such as 4K2K, 8K4K, 16K8K, or more.

Alternatively, a structure may be employed in which the video signal receiving portion 606 and the decoder circuit 605 generate a signal transmitted to the image processing circuit 604 using the broadcasting data transmitted with data transmission technology through a computer network. At this time, in the case where the received signal is a digital signal, the video signal receiving portion 606 does not necessarily include a demodulation circuit, an AD converter circuit, and the like.

The image processing circuit 604 has a function of generating a video signal output to the timing controller 607, on the basis of a video signal input from the decoder circuit 605.

The timing controller 607 has a function of generating a signal (e.g., a clock signal or a start pulse signal) output to the gate driver 609 and the source driver 608 on the basis of a synchronization signal included in a video signal or the like on which the image processing circuit 604 performs processing. In addition, the timing controller 607 has a function of generating a video signal output to the source driver 608, as well as the above signal.

The display panel 620 includes a plurality of pixels 621. Each pixel 621 is driven by a signal supplied from the gate driver 609 and the source driver 608. Here, an example of a display panel whose number of pixels is 7680×4320, with the resolution corresponding to the standard of 8K4K, is shown. Note that the resolution of the display panel 620 is not limited thereto, and may have a resolution corresponding to the standard such as full high-definition (the number of pixels is 1920×1080) or 4K2K (the number of pixels is 3840×2160).

A structure in which, for example, a processor is included can be employed for the control portion 601 or the image processing circuit 604 illustrated in FIG. 19. For example, a processor functioning as a CPU can be used for the control portion 601. In addition, another processor such as a DSP (Digital Signal Processor) or a GPU (Graphics Processing Unit) can be used for the image processing circuit 604, for example. Furthermore, a structure in which the above processor is obtained with a PLD (Programmable Logic Device) such as an FPGA (Field Programmable Gate Array) or an FPAA (Field Programmable Analog Array) may be employed for the control portion 601 or the image processing circuit 604.

The processor interprets and executes instructions from various programs to process various kinds of data and control programs. The programs that might be executed by the processor may be stored in a memory region included in the processor or a memory device which is additionally provided.

Furthermore, two or more functions among the functions of the control portion 601, the memory portion 602, the communication control portion 603, the image processing circuit 604, the decoder circuit 605, the video signal receiving portion 606, and the timing controller 607 may be aggregated in one IC chip to form a system LSI. For example, a system LSI including a processor, a decoder circuit, a tuner circuit, an A-D converter circuit, a DRAM, an SRAM, and the like may be employed.

Note that a transistor that includes an oxide semiconductor in a channel formation region and that achieves an extremely low off-state current can be used in an IC or the like included in the control portion 601 or another component. The transistor has an extremely low off-state current; therefore, with the use of the transistor as a switch for holding electric charge (data) which flows into a capacitor functioning as a memory, a long data retention period can be ensured. Utilizing this characteristic for a register or a cache memory of the control portion 601 or the like enables normally-off computing where the control portion 601 operates only when needed and data on the previous processing is stored in the memory in the other case. Thus, power consumption of television device 600 can be reduced.

Note that the structure of the television device 600 in FIG. 19 is just an example, and all of the components are not necessarily included. It is acceptable as long as the television device 600 includes at least necessary components among the components illustrated in FIG. 19. Furthermore, the television device 600 may include a component other than the components illustrated in FIG. 19.

For example, the television device 600 may include an external interface, an audio output portion, a touch panel unit, a sensor unit, a camera unit, or the like besides the components illustrated in FIG. 19. For example, examples of the external interfaces include an external connection terminal such as a USB (Universal Serial Bus) terminal, a LAN (Local Area Network) connection terminal, a power receiving terminal, an audio output terminal, an audio input terminal, a video output terminal, and a video input terminal; a transceiver for optical communication using infrared rays, visible light, ultraviolet rays, or the like; and a physical button provided on a housing.

In addition, examples of the audio input/output portions include a sound controller, a microphone, and a speaker.

The image processing circuit 604 is described in detail below.

The image processing circuit 604 preferably has a function of executing image processing on the basis of a video signal input from the decoder circuit 605.

Examples of the image processing include noise removal processing, grayscale conversion processing, tone correction processing, and luminance correction processing. Examples of the tone correction processing or the luminance correction processing include gamma correction.

Furthermore, the image processing circuit 604 preferably has a function of executing processing such as pixel interpolation processing in accordance with up-conversion of the resolution or frame interpolation processing in accordance with up-conversion of the frame frequency.

As the noise removing processing, various noise such as mosquito noise which appears near outline of characters and the like, block noise which appears in high-speed moving images, random noise causing flicker, and dot noise caused by up-conversion of the resolution are removed, for example.

The grayscale conversion processing converts the grayscale of an image to a grayscale corresponding to output characteristics of the display panel 620. For example, in the case where the number of gray levels is increased, gray levels for pixels are interpolated to an image input with a small number of gray levels and assigned to the pixels, so that processing for smoothing a histogram can be executed. In addition, high-dynamic range (HDR) processing for increasing a dynamic range is also included in the grayscale conversion processing.

In addition, the pixel interpolation processing interpolates data that does not actually exist when resolution is up-converted. For example, with reference to pixels around the target pixel, data is interpolated so that an intermediate color of the pixels is displayed.

The tone correction processing corrects the tone of an image. The luminance correction processing corrects the brightness (luminance contrast) of an image. For example, a type, luminance, color purity, and the like of lighting in a space where the television device 600 is provided are detected, and luminance and tone of images displayed on the display panel 620 are corrected to be optimal in accordance with the detection. These processes can have a function of referring a displayed image to various images of various scenes in an image list stored in advance, and then correcting luminance and tone of the displayed image to be suitable to the images in the closest scene of the image.

In the case where the frame frequency of the displayed video is increased, the frame interpolation generates an image for a frame that does not exist originally (an interpolation frame). For example, an image for an interpolation frame that is interposed between certain two images is generated from a difference between the two images. Alternatively, images for a plurality of interpolation frames can be generated between the two images. For example, when the frame frequency of a video signal input from the decoder circuit 605 is 60 Hz, a plurality of interpolation frames are generated, and the frame frequency of a video signal output to the timing controller 607 can be increased twofold (120 Hz), fourfold (240 Hz), or eightfold (480 Hz), for example.

At least part of the structure examples, the drawings corresponding thereto, and the like exemplified in this embodiment can be implemented in combination with the other structure examples, the other drawings, and the like as appropriate.

At least part of this embodiment can be implemented in combination with the other embodiments described in this specification as appropriate.

### Embodiment 2

In this embodiment, a structure example of a display panel which can be applied to the display apparatus of one embodiment of the present invention is described.

### Structure Example

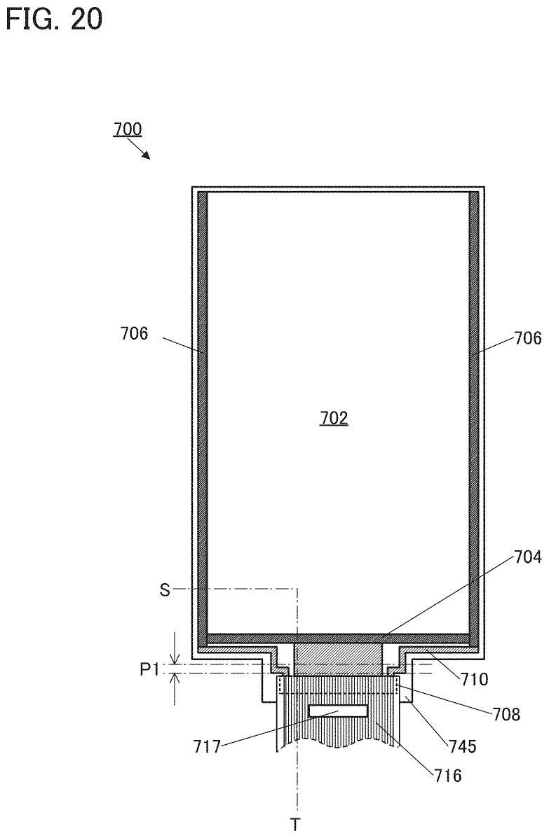

FIG. 20 shows a top view of a display panel 700. The display panel 700 is a display panel that employs a support substrate 745 having flexibility and can be used as a flexible display. The display panel 700 includes a pixel portion 702 provided over the support substrate 745 having flexibility. Over the support substrate 745, a source driver circuit portion 704, a pair of gate driver circuit portions 706, a wiring 710, and the like are provided. A plurality of display devices are provided in the pixel portion 702.

Part of the support substrate 745 is provided with an FPC terminal portion 708, to which an FPC 716 (FPC: Flexible printed circuit) is connected. The pixel portion 702, the source driver circuit portion 704, and the gate driver circuit portions 706 are each supplied with a variety of signals and the like from the FPC 716 through the FPC terminal portion 708 and the wiring 710.

The pair of gate driver circuit portions 706 is provided on opposite sides with the pixel portion 702 interposed therebetween. Note that the gate driver circuit portions 706 and the source driver circuit portion 704 may be formed separately on semiconductor substrates or the like to form packaged IC chips. The IC chip can be mounted on the support substrate 745 by a COF (Chip On Film) technique or the like.

An OS transistor is preferably applied to the transistors included in the pixel portion 702, the source driver circuit portion 704, and the gate driver circuit portions 706.

A light-emitting device or the like can be used as the display device included in the pixel portion 702. Examples of the light-emitting device include a self-luminous light-emitting device such as an LED (Light Emitting Diode), an OLED (Organic LED), a QLED (Quantum-dot LED), and a semiconductor laser. As the display device, a liquid crystal device such as transmissive liquid crystal devices, a reflective liquid crystal device, or a transreflective liquid crystal device can also be used. Alternatively, a MEMS (Micro Electro Mechanical Systems) shutter device, an optical interference type MEMS device, or a display device using a microcapsule method, an electrophoretic method, an electrowetting method, an Electronic Liquid Powder (registered trademark) method, or the like can also be used, for example.

FIG. 20 shows an example where the FPC terminal portion 708 is provided in the portion of the support substrate 745 which has a protrusive shape. In a region P1 in FIG. 20, part of the support substrate 745 that includes the FPC terminal portion 708 can be bent backward. Bending the part of the support substrate 745 backward enables the FPC 716 to be placed in a state overlapping with the rear side of the pixel portion 702 when the display panel 700 is mounted on an electronic device or the like, whereby the electronic device or the like can be space-saving or small-sized.

An IC 717 is mounted on the FPC 716 connected to the display panel 700. The IC 717 has a function of a source driver circuit, for example. In this case, a structure can be employed in which the source driver circuit portion 704 in the display panel 700 includes at least one of a protection circuit, a buffer circuit, a demultiplexer circuit, and the like.

### <Cross-Sectional Structure Example>

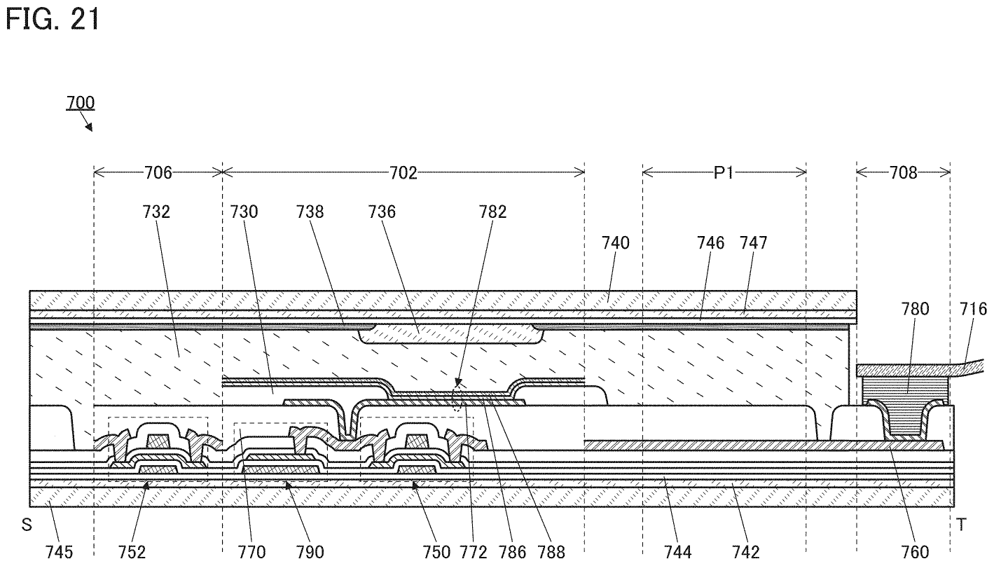

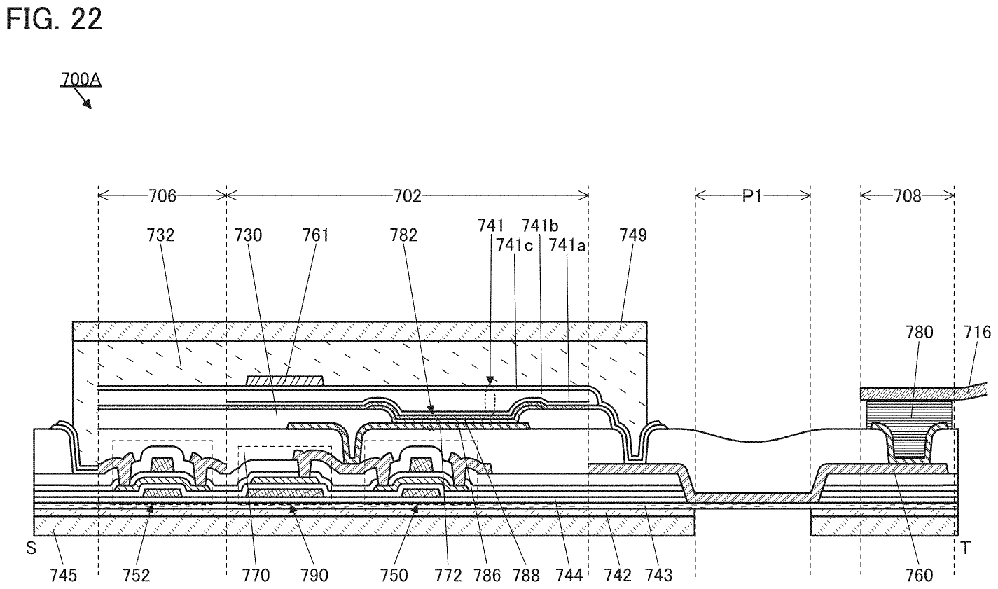

Structures using organic EL as the display device are described below with reference to FIG. 21 and FIG. 22. FIG. 21 and FIG. 22 are each a schematic cross-sectional view of the display panel 700 illustrated in FIG. 20 along the dash-dot line S-T.

First, portions common to the display panels illustrated in FIG. 21 and FIG. 22 are described.

FIG. 21 and FIG. 22 illustrate cross sections including the pixel portion 702, the gate driver circuit portion 706, and the FPC terminal portion 708. The pixel portion 702 includes a transistor 750 and a capacitor 790. The gate driver circuit portion 706 includes a transistor 752.

The transistor 750 and the transistor 752 are each a transistor using an oxide semiconductor for a semiconductor layer in which a channel is formed. Note that the transistors are not limited thereto, and a transistor using silicon (amorphous silicon, polycrystalline silicon, or single-crystal silicon) or a transistor using an organic semiconductor for the semiconductor layer can be used.

The transistor used in this embodiment includes a highly purified oxide semiconductor film in which formation of oxygen vacancies is inhibited. The off-state current of the transistors can be reduced significantly. Accordingly, in the pixel employing such a transistor, the retention time of an electrical signal such as an image signal can be extended, and the interval between writes of an image signal or the like can also be set longer. Accordingly, the frequency of refresh operations can be reduced, so that power consumption can be reduced.

The transistor used in this embodiment can have relatively high field-effect mobility and thus is capable of high-speed operation. For example, with such a transistor capable of high-speed operation used for the display panel, a switching transistor in a pixel portion and a driver transistor used in a driver circuit portion can be formed over one substrate. That is, a structure in which a driver circuit formed using a silicon wafer or the like is not used is possible, in which case the number of components of the display apparatus can be reduced. Moreover, the use of the transistor capable of high-speed operation also in the pixel portion can provide a high-quality image.

The capacitor 790 includes a lower electrode formed by processing the same film as a film used for the first gate electrode of the transistor 750 and an upper electrode formed by processing the same metal oxide film as a film used for the semiconductor layer. The upper electrode has reduced resistance like a source region and a drain region of the transistor 750. Part of an insulating film functioning as a first gate insulating layer of the transistor 750 is provided between the lower electrode and the upper electrode. That is, the capacitor 790 has a stacked-layer structure in which an insulating film functioning as a dielectric film is positioned between a pair of electrodes. A wiring obtained by processing the same film as a film used for a source electrode and a drain electrode of the transistor 750 is connected to the upper electrode.

An insulating layer 770 that functions as a planarization film is provided over the transistor 750, the transistor 752, and the capacitor 790.

The transistor 750 included in the pixel portion 702 and the transistor 752 included in the gate driver circuit portion 706 may have different structures. For example, a top-gate transistor may be used as one of the transistors 750 and 752, and a bottom-gate transistor may be used as the other. Note that the same applies to the driver circuit portion 704, as in the gate driver circuit portion 706.

The FPC terminal portion 708 includes a wiring 760 part of which functions as a connection electrode, an anisotropic conductive film 780, and the FPC 716. The wiring 760 is electrically connected to a terminal included in the FPC 716 through the anisotropic conductive film 780. Here, the wiring 760 is formed using the same conductive film as the source electrode and the drain electrode of the transistor 750 and the like.

Next, the display panel 700 illustrated in FIG. 21 is described.

The display panel 700 illustrated in FIG. 21 includes the support substrate 745 and a support substrate 740. As the support substrate 745 and the support substrate 740, a glass substrate or a substrate having flexibility such as a plastic substrate can be used, for example.

The transistor 750, the transistor 752, the capacitor 790, and the like are provided over the insulating layer 744. The support substrate 745 and the insulating layer 744 are bonded to each other with the adhesive layer 742.

The display panel 700 includes a light-emitting device 782, a coloring layer 736, a light-blocking layer 738, and the like.

The light-emitting device 782 includes a conductive layer 772, an EL layer 786, and a conductive layer 788. The conductive layer 772 is electrically connected to the source electrode or the drain electrode included in the transistor 750. The conductive layer 772 is provided over the insulating layer 770 and functions as a pixel electrode. An insulating layer 730 is provided to cover an end portion of the conductive layer 772. Over the insulating layer 730 and the conductive layer 772, the EL layer 786 and the conductive layer 788 are stacked.

For the conductive layer 772, a material having a property of reflecting visible light can be used. For example, a material including aluminum, silver, or the like can be used. For the conductive layer 788, a material that transmits visible light can be used. For example, an oxide material including indium, zinc, tin, or the like is preferably used. Thus, the light-emitting device 782 is a top-emission light-emitting device, which emits light to the side opposite the formation surface (the support substrate 740 side).

The EL layer 786 includes an organic compound or an inorganic compound such as quantum dots. The EL layer 786 includes a light-emitting material that exhibits blue light when current flows.

As the light-emitting material, a fluorescent material, a phosphorescent material, a thermally activated delayed fluorescence (TADF) material, an inorganic compound (e.g., a quantum dot material), or the like can be used. Examples of materials that can be used for quantum dots include a colloidal quantum dot material, an alloyed quantum dot material, a core-shell quantum dot material, and a core quantum dot material.

The light-blocking layer 738 and the coloring layer 736 are provided on one surface of an insulating layer 746. The coloring layer 736 is provided in a position overlapping with the light-emitting device 782. The light-blocking layer 738 is provided in a region not overlapping with the light-emitting device 782 in the pixel portion 702. The light-blocking layer 738 may also be provided to overlap with the gate driver circuit portion 706 or the like.

The support substrate 740 is bonded to the other surface of the insulating layer 746 with an adhesive layer 747. The support substrate 740 and the support substrate 745 are bonded to each other with a sealing layer 732.

Here, for the EL layer 786 included in the light-emitting device 782, a light-emitting material that exhibits white light emission is used. White light emission by the light-emitting device 782 is colored by the coloring layer 736 to be emitted to the outside. The EL layer 786 is provided for the whole pixels that exhibit different colors. The pixels provided with the coloring layer 736 transmitting any of red light (R), green light (G), and blue light (B) are arranged in a matrix in the pixel portion, whereby the display panel 700 can perform full-color display.

A conductive film having a semi-transmissive property and a semi-reflective property may be used for the conductive layer 788. In this case, a microcavity structure is achieved between the conductive layer 772 and the conductive layer 788 such that light of a specific wavelength can be intensified to be emitted. Also in this case, an optical adjustment layer for adjusting an optical distance may be placed between the conductive layer 772 and the conductive layer 788 such that the thickness of the optical adjustment layer differs between pixels of different colors and accordingly the color purity of light emitted from each pixel can be increased.

Note that a structure in which the coloring layer 736 or the above optical adjustment layer is not provided may be employed when the EL layer 786 is formed into an island shape for each pixel or into a stripe shape for each pixel column, i.e., the EL layer 786 is formed by separate coloring.

Here, an inorganic insulating film which functions as a barrier film having low permeability is preferably used for each of the insulating layer 744 and the insulating layer 746. With such a structure in which the light-emitting device 782, the transistor 750, and the like are interposed between the insulating layer 744 and the insulating layer 746, deterioration of them can be inhibited and a highly reliable display panel can be achieved.

In a display panel 700A illustrated in FIG. 22, a resin layer 743 is provided between the adhesive layer 742 and the insulating layer 744 illustrated in FIG. 21. A protection layer 749 is provided instead of the support substrate 740.

The resin layer 743 is a layer including an organic resin such as polyimide or acrylic. The insulating layer 744 includes an inorganic insulating film of silicon oxide, silicon oxynitride, silicon nitride, or the like. The resin layer 743 and the support substrate 745 are attached to each other with the bonding layer 742. The resin layer 743 is preferably thinner than the support substrate 745.

The protection layer 749 is attached to the sealing layer 732. A glass substrate, a resin film, or the like can be used as the protection layer 749. As the protection layer 749, an optical member such as a polarizing plate (including a circularly polarizing plate) or a scattering plate, an input device such as a touch sensor panel, or a structure in which two or more of the above are stacked may be employed.

The EL layer 786 included in the light-emitting device 782 is provided over the insulating layer 730 and the conductive layer 772 in an island shape. The EL layers 786 are formed separately so that respective subpixels emit light of different colors, whereby color display can be performed without use of the coloring layer 736.

A protection layer 741 is provided to cover the light-emitting device 782. The protection layer 741 has a function of preventing diffusion of impurities such as water into the light-emitting device 782. The protection layer 741 has a stacked-layer structure in which an insulating layer 741a, an insulating layer 741b, and an insulating layer 741c are stacked in this order from the conductive layer 788 side. In that case, it is preferable that inorganic insulating films with a high barrier property against impurities such as water be used as the insulating layer 741a and the insulating layer 741c, and an organic insulating film which functions as a planarization film be used as the insulating layer 741b. The protection layer 741 is preferably provided to extend also to the gate driver circuit portion 706.

An organic insulating film covering the transistor 750, the transistor 752, and the like is preferably formed in an island shape inward from the sealing layer 732. In other words, an end portion of the organic insulating film is preferably inward from the sealing layer 732 or in a region overlapping with an end portion of the sealing layer 732. FIG. 22 shows an example in which the insulating layer 770, the insulating layer 730, and the insulating layer 741b are processed into island shapes. The insulating layer 741c and the insulating layer 741a are provided in contact with each other in a portion overlapping with the sealing layer 732, for example. Thus, a surface of the organic insulating film covering the transistor 750 and the transistor 752 is not exposed to the outside of the sealing layer 732, whereby diffusion of water or hydrogen from the outside to the transistor 750 and the transistor 752 through the organic insulating film can be favorably prevented. This can reduce variations in electrical characteristics of the transistors, so that a display apparatus with extremely high reliability can be achieved.

In FIG. 22, the region P1 that can be bent includes a portion where the support substrate 745, the bonding layer 742, and the inorganic insulating film such as the insulating layer 744 are not provided. The region P1 has a structure in which the insulating layer 770 including an organic material covers the wiring 760 not to expose the wiring 760. When an inorganic insulating film is not provided in the region P1 that can be bent and only a conductive layer including a metal or an alloy and a layer including an organic material are stacked, generation of cracks at the time of bending can be prevented. When the support substrate 745 is not provided in the region P1, part of the display panel 700A can be bent with an extremely small radius of curvature.

In FIG. 22, a conductive layer 761 is provided over the protection layer 741. The conductive layer 761 can be used as a wiring or an electrode.

In the case where a touch sensor is provided so as to overlap with the display panel 700A, the conductive layer 761 can function as an electrostatic shielding film for preventing transmission of electrical noise to the touch sensor during pixel driving. In this case, the structure in which a predetermined constant potential is applied to the conductive layer 761 can be employed.

Alternatively, the conductive layer 761 can be used as an electrode of the touch sensor, for example. This enables the display panel 700A to function as a touch panel. For example, the conductive layer 761 can be used as an electrode or a wiring of a capacitive touch sensor. In this case, the conductive layer 761 can be used as a wiring or an electrode to which a sensor circuit is connected or a wiring or an electrode to which a sensor signal is input. When the touch sensor is formed over the light-emitting device 782 in this manner, the number of components can be reduced, and manufacturing cost of an electronic device or the like can be reduced.

The conductive layer 761 is preferably provided in a portion not overlapping with the light-emitting device 782. The conductive layer 761 can be provided in a position overlapping with the insulating layer 730, for example. Thus, a transparent conductive film with a relatively low conductivity is not necessarily used for the conductive layer 761, and a metal or an alloy having high conductivity or the like can be used, so that the sensitivity of the sensor can be increased.

As the type of the touch sensor that can be formed of the conductive layer 761, a variety of types such as a capacitive type, a resistive type, a surface acoustic wave type, an infrared type, an optical type, and a pressure-sensitive type can be used, without limitation to a capacitive type.

Alternatively, two or more of these types may be combined and used.

### <Components>

Components such as a transistor that can be used in the display apparatus will be described below.

### [Transistor]

The transistors each include a conductive layer functioning as a gate electrode, a semiconductor layer, a conductive layer functioning as a source electrode, a conductive layer functioning as a drain electrode, and an insulating layer functioning as a gate insulating layer.

Note that there is no particular limitation on the structure of the transistor included in the display apparatus of one embodiment of the present invention. For example, a planar transistor, a staggered transistor, or an inverted staggered transistor may be used. A top-gate or bottom-gate transistor structure may be employed. Gate electrodes may be provided above and below a channel.

There is no particular limitation on the crystallinity of a semiconductor material used for the transistors, and an amorphous semiconductor or a semiconductor having crystallinity (a microcrystalline semiconductor, a polycrystalline semiconductor, a single-crystal semiconductor, or a semiconductor partly including crystal regions) may be used. A semiconductor having crystallinity is preferably used, in which case deterioration of the transistor characteristics can be suppressed.

### <Conductive Layer>

Examples of materials that can be used for conductive layers of a variety of wirings and electrodes and the like included in the display apparatus in addition to a gate, a source, and a drain of a transistor include metals such as aluminum, titanium, chromium, nickel, copper, yttrium, zirconium, molybdenum, silver, tantalum, and tungsten and an alloy containing such a metal as its main component. A single-layer structure or stacked-layer structure including a film containing any of these materials can be used. For example, a single-layer structure of an aluminum film containing silicon, a two-layer structure in which an aluminum film is stacked over a titanium film, a two-layer structure in which an aluminum film is stacked over a tungsten film, a two-layer structure in which a copper film is stacked over a copper-magnesium-aluminum alloy film, a two-layer structure in which a copper film is stacked over a titanium film, a two-layer structure in which a copper film is stacked over a tungsten film, a three-layer structure in which an aluminum film or a copper film is stacked over a titanium film or a titanium nitride film and a titanium film or a titanium nitride film is formed thereover, a three-layer structure in which an aluminum film or a copper film is stacked over a molybdenum film or a molybdenum nitride film and a molybdenum film or a molybdenum nitride film is formed thereover, and the like can be given. Note that an oxide such as indium oxide, tin oxide, or zinc oxide may be used. Copper containing manganese is preferably used because it increases controllability of a shape by etching.

### <Insulating Layer>

Examples of an insulating material that can be used for the insulating layers include, in addition to a resin such as acrylic or epoxy and a resin having a siloxane bond, an inorganic insulating material such as silicon oxide, silicon oxynitride, silicon nitride oxide, silicon nitride, or aluminum oxide.

The light-emitting device is preferably provided between a pair of insulating films with low water permeability. In that case, impurities such as water can be inhibited from entering the light-emitting device, and thus a decrease in the reliability of the device can be inhibited.

Examples of the insulating film with low water permeability include a film containing nitrogen and silicon, such as a silicon nitride film and a silicon nitride oxide film, and a film containing nitrogen and aluminum, such as an aluminum nitride film. Alternatively, a silicon oxide film, a silicon oxynitride film, an aluminum oxide film, or the like may be used.

For example, the moisture vapor transmission rate of the insulating film with low water permeability is lower than or equal to 1×10⁻⁵ [g/(m²·day)], preferably lower than or equal to 1×10⁻⁶ [g/(m²·day)], further preferably lower than or equal to 1×10⁻⁷ [g/(m²·day)], still further preferably lower than or equal to 1×10⁻⁸ [g/(m²·day)].

The above is the description of the components.

At least part of the structure examples, the drawings corresponding thereto, and the like exemplified in this embodiment can be implemented in combination with the other structure examples, the other drawings, and the like as appropriate.

At least part of this embodiment can be implemented in combination with the other embodiments described in this specification as appropriate.

### Embodiment 3

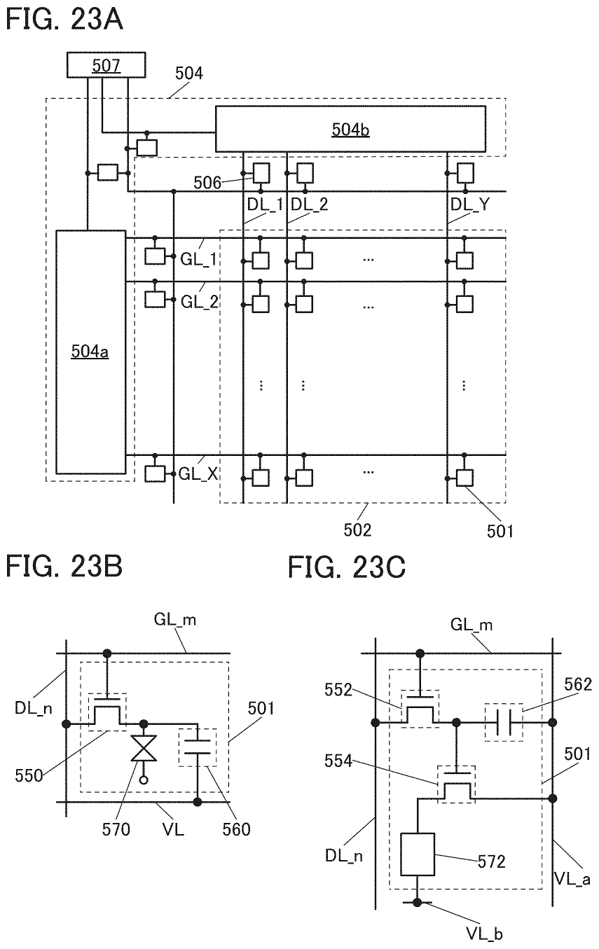

In this embodiment, configuration examples of a display apparatus will be described with reference to FIG. 23A, FIG. 23B, and FIG. 23C.

The display apparatus illustrated in FIG. 23A includes a pixel portion 502, a driver circuit portion 504, protection circuits 506, and a terminal portion 507. Note that a configuration in which the protection circuits 506 are not provided may be employed.

The pixel portion 502 includes a plurality of pixel circuits 501 that drive a plurality of display devices arranged in X rows and Y columns (X and Y each independently represent a natural number of 2 or more).

The driver circuit portion 504 includes driver circuits such as a gate driver 504a that outputs a scanning signal to gate lines GL_1 to GL_X and a source driver 504b that supplies a data signal to data lines DL_1 to DL Y. The gate driver 504a includes at least a shift register. The source driver 504b is formed using a plurality of analog switches, for example. Alternatively, the source driver 504b may be formed using a shift register or the like.

The terminal portion 507 refers to a portion provided with terminals for inputting power, control signals, image signals, and the like to the display apparatus from external circuits.

The protection circuit 506 is a circuit that, when a potential out of a certain range is applied to a wiring to which the protection circuit 506 is connected, establishes continuity between the wiring and another wiring. The protection circuit 506 illustrated in FIG. 23A is connected to a variety of wirings such as the gate lines GL that are wirings between the gate driver 504a and the pixel circuits 501 and the data lines DL that are wirings between the source driver 504b and the pixel circuits 501, for example.

The gate driver 504a and the source driver 504b may be provided over a substrate over which the pixel portion 502 is provided, or a substrate where a gate driver circuit or a source driver circuit is separately formed (e.g., a driver circuit board formed using a single crystal semiconductor film or a polycrystalline semiconductor film) may be mounted on the substrate by COF, TCP (Tape Carrier Package), COG (Chip On Glass), or the like.

The plurality of pixel circuits 501 illustrated in FIG. 23A can have the configuration illustrated in FIG. 23B or FIG. 23C, for example.

The pixel circuit 501 illustrated in FIG. 23B includes a liquid crystal device 570, a transistor 550, and a capacitor 560. A data line DL_n, a gate line GL_m, a potential supply line VL, and the like are connected to the pixel circuit 501.

The potential of one of a pair of electrodes of the liquid crystal device 570 is set appropriately in accordance with the specifications of the pixel circuit 501. The alignment state of the liquid crystal device 570 is set depending on written data. Note that a common potential may be supplied to one of the pair of electrodes of the liquid crystal device 570 included in each of the plurality of pixel circuits 501. Moreover, a different potential may be supplied to one of the pair of electrodes of the liquid crystal device 570 of the pixel circuit 501 in each row.

The pixel circuit 501 illustrated in FIG. 23C includes transistors 552 and 554, a capacitor 562, and a light-emitting device 572. The data line DL_n, the gate line GL_m, a potential supply line VL_a, a potential supply line VL_b, and the like are connected to the pixel circuit 501.

Note that a high-power supply potential VDD is supplied to one of the potential supply line VL_a and the potential supply line VL_b, and a low-power supply potential VSS is supplied to the other. Current flowing through the light-emitting element 572 is controlled in accordance with a potential applied to a gate of the transistor 554, whereby the luminance of light emitted from the light-emitting device 572 is controlled.

At least part of the configuration examples, the drawings corresponding thereto, and the like exemplified in this embodiment can be implemented in combination with the other configuration examples, the other drawings, and the like as appropriate.

At least part of this embodiment can be implemented in combination with the other embodiments described in this specification as appropriate.

### Embodiment 4

A pixel circuit including a memory for correcting gray levels displayed by pixels and a display apparatus including the pixel circuit are described below.

### <Circuit Configuration>

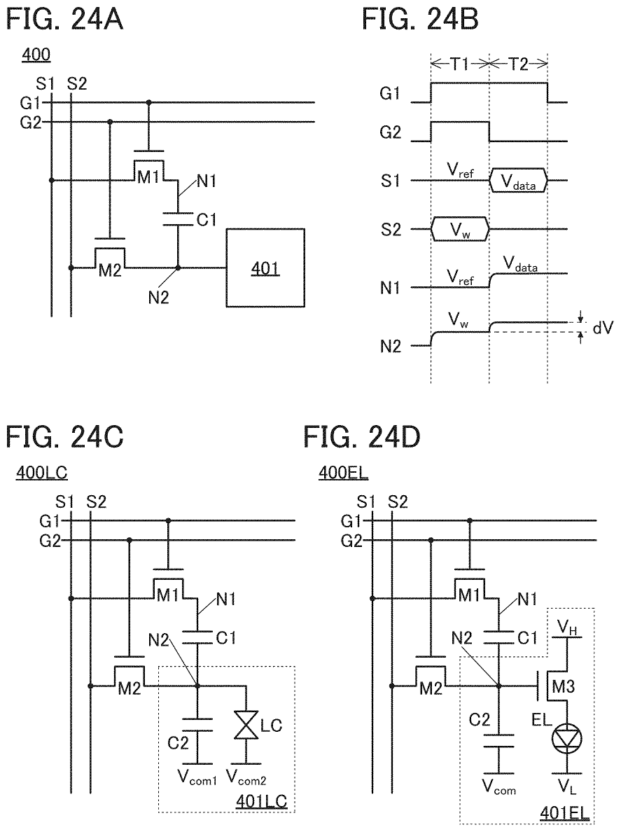

FIG. 24A is a circuit diagram of a pixel circuit 400. The pixel circuit 400 includes a transistor M1, a transistor M2, a capacitor C1, and a circuit 401. A wiring S1, a wiring S2, a wiring G1, and a wiring G2 are connected to the pixel circuit 400.

In the transistor M1, a gate is connected to the wiring G1, one of a source and a drain is connected to the wiring S1, and the other is connected to one electrode of the capacitor C1. In the transistor M2, a gate is connected to the wiring G2, one of a source and a drain is connected to the wiring S2, and the other is connected to the other electrode of the capacitor C1 and the circuit 401.

The circuit 401 is a circuit including at least one display device. Any of a variety of devices can be used as the display device, and typically, a light-emitting device such as an organic EL device or an LED device, a liquid crystal device, a MEMS (Micro Electro Mechanical Systems) device, or the like can be used.

A node connecting the transistor M1 and the capacitor C1 is denoted as a node N1, and a node connecting the transistor M2 and the circuit 401 is denoted as a node N2.

In the pixel circuit 400, the potential of the node N1 can be retained when the transistor M1 is turned off. The potential of the node N2 can be retained when the transistor M2 is turned off When a predetermined potential is written to the node N1 through the transistor M1 with the transistor M2 being in an off state, the potential of the node N2 can be changed in accordance with displacement of the potential of the node N1 owing to capacitive coupling through the capacitor C1.

Here, the transistor using an oxide semiconductor, which is described in Embodiment 1, can be used as one or both of the transistor M1 and the transistor M2. Accordingly, owing to an extremely low off-state current, the potentials of the node N1 and the node N2 can be retained for a long time. Note that in the case where the period in which the potential of each node is retained is short (specifically, the case where the frame frequency is higher than or equal to 30 Hz, for example), a transistor using a semiconductor such as silicon may be used.

### <Driving Method Example>

Next, an example of a method for operating the pixel circuit 400 is described with reference to FIG. 24B. FIG. 24B is a timing chart of the operation of the pixel circuit 400. Note that for simplification of description, the influence of various kinds of resistance such as wiring resistance, parasitic capacitance of a transistor, a wiring, or the like, the threshold voltage of the transistor, and the like is not taken into account here.

In the operation shown in FIG. 24B, one frame period is divided into a period T1 and a period T2. The period T1 is a period in which a potential is written to the node N2, and the period T2 is a period in which a potential is written to the node N1.

In the period T1, a potential for turning on the transistor is supplied to both the wiring G1 and the wiring G2. In addition, a potential V_{ref} that is a fixed potential is supplied to the wiring S1, and a first data potential V_{w} is supplied to the wiring S2.

The potential V_{ref} is supplied from the wiring S1 to the node N1 through the transistor M1. The first data potential V_{w} is supplied from the wiring S2 to the node N2 through the transistor M2. Accordingly, a potential difference V_{w}-V_{ref} is retained in the capacitor C1.

Next, in the period T2, a potential for turning on the transistor M1 is supplied to the wiring G1, and a potential for turning off the transistor M2 is supplied to the wiring G2. A second data potential V_{data} is supplied to the wiring S1. The wiring S2 may be supplied with a predetermined constant potential or brought into a floating state.

The second data potential V_{data} is supplied from the wiring S1 to the node N1 through the transistor M1. At this time, capacitive coupling due to the capacitor C1 changes the potential of the node N2 in accordance with the second data potential V_{data} by a potential dV. That is, a potential that is the sum of the first data potential V_{w} and the potential dV is input to the circuit 401. Note that although dV is shown as a positive value in FIG. 24B, dV may be a negative value. That is, the second data potential V_{data} may be lower than the potential V_{ref}.

Here, the potential dV is roughly determined from the capacitance value of the capacitor C1 and the capacitance value of the circuit 401. When the capacitance value of the capacitor C1 is sufficiently larger than the capacitance value of the circuit 401, the potential dV is a potential close to the second data potential V_{data}.

In the above manner, the pixel circuit 400 can generate a potential to be supplied to the circuit 401 including the display device, by combining two kinds of data signals; hence, a gray level can be corrected in the pixel circuit 400.

The pixel circuit 400 can also generate a potential exceeding the maximum potential that can be supplied to the wiring S1 and the wiring S2. For example, in the case where a light-emitting device is used, high-dynamic range (HDR) display or the like can be performed. In the case where a liquid crystal device is used, overdriving or the like can be achieved.

### <Application Example>

### [Example Using Liquid Crystal Device]

A pixel circuit 400LC illustrated in FIG. 24C includes a circuit 401LC. The circuit 401LC includes a liquid crystal device LC and a capacitor C2.

In the liquid crystal device LC, one electrode is connected to the node N2 and one electrode of the capacitor C2, and the other electrode is connected to a wiring supplied with a potential V_{com2}. The other electrode of the capacitor C2 is connected to a wiring supplied with a potential V_{com1}.

The capacitor C2 functions as a storage capacitor. Note that the capacitor C2 can be omitted when not needed.

In the pixel circuit 400LC, a high voltage can be supplied to the liquid crystal device LC; thus, high-speed display can be performed by overdriving or a liquid crystal material with a high driving voltage can be employed, for example. Moreover, by supply of a correction signal to the wiring S1 or the wiring S2, a gray level can be corrected in accordance with the operating temperature, the deterioration state of the liquid crystal element LC, or the like.

### [Example Using Light-Emitting Device]

A pixel circuit 400EL illustrated in FIG. 24D includes a circuit 401EL. The circuit 401EL includes a light-emitting device EL, a transistor M3, and the capacitor C2.

In the transistor M3, a gate is connected to the node N2 and one electrode of the capacitor C2, one of a source and a drain is connected to a wiring supplied with a potential V_{H}, and the other is connected to one electrode of the light-emitting device EL. The other electrode of the capacitor C2 is connected to a wiring supplied with a potential V_{com}. The other electrode of the light-emitting device EL is connected to a wiring supplied with a potential V_{L}.

The transistor M3 has a function of controlling a current to be supplied to the light-emitting device EL. The capacitor C2 functions as a storage capacitor. The capacitor C2 can be omitted when not needed.

Note that although the structure in which the anode side of the light-emitting device EL is connected to the transistor M3 is described here, the transistor M3 may be connected to the cathode side. In that case, the values of the potential V_{H} and the potential V_{L} can be appropriately changed.

In the pixel circuit 400EL, a large amount of current can flow through the light-emitting device EL when a high potential is applied to the gate of the transistor M3, which enables HDR display, for example. Moreover, a variation in the electrical characteristics of the transistor M3 and the light-emitting device EL can be corrected by supply of a correction signal to the wiring S1 or the wiring S2.

Note that the configuration is not limited to the circuits shown in FIG. 24C and FIG. 24D, and a configuration to which a transistor, a capacitor, or the like is further added may be employed.

At least part of this embodiment can be implemented in combination with the other embodiments described in this specification as appropriate.

### Embodiment 5

In this embodiment, structure examples of the pixel of the display panel of one embodiment of the present invention are described below.

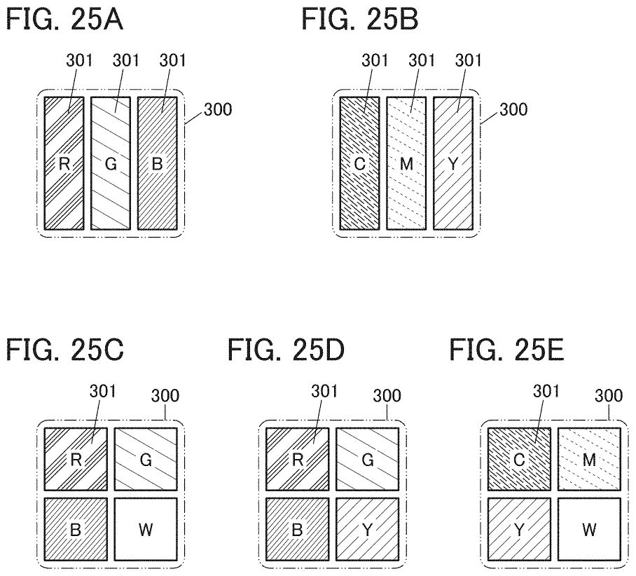

Structure examples of a pixel 300 are shown in FIG. 25A to FIG. 25E.

The pixel 300 includes a plurality of pixels 301. The plurality of pixels 301 each function as a subpixel. One pixel 300 is formed of the plurality of pixels 301 exhibiting different colors, and thus full-color display can be achieved in a display portion.

The pixels 300 illustrated in FIG. 25A and FIG. 25B each include three subpixels. The combination of colors exhibited by the pixels 301 included in the pixel 300 illustrated in FIG. 25A is red (R), green (G), and blue (B). The combination of colors exhibited by the pixels 301 included in the pixel 300 illustrated in FIG. 25B is cyan (C), magenta (M), and yellow (Y).

The pixels 300 illustrated in FIG. 25C to FIG. 25E each include four subpixels. The combination of colors exhibited by the pixels 301 included in the pixel 300 illustrated in FIG. 25C is red (R), green (G), blue (B), and white (W). The use of the subpixel that exhibits white can increase the luminance of the display portion. The combination of colors exhibited by the pixels 301 included in the pixel 300 illustrated in FIG. 25D is red (R), green (G), blue (B), and yellow (Y). The combination of colors exhibited by the pixels 301 included in the pixel 300 illustrated in FIG. 25E is cyan (C), magenta (M), yellow (Y), and white (W).

When subpixels that exhibit red, green, blue, cyan, magenta, yellow, and the like are combined as appropriate with more subpixels functioning as one pixel, the reproducibility of halftones can be increased. Thus, the display quality can be improved.

The display apparatus of one embodiment of the present invention can reproduce the color gamut of various standards. For example, the display apparatus of one embodiment of the present invention can reproduce the color gamut of the following standards: the PAL (Phase Alternating Line) or NTSC (National Television System Committee) standard used for TV broadcasting; the sRGB (standard RGB) or Adobe RGB standard used widely for display apparatuses in electronic devices such as personal computers, digital cameras, and printers; the ITU-R BT.709 (International Telecommunication Union Radiocommunication Sector Broadcasting Service (Television) 709) standard used for HDTV (High Definition Televisions, also referred to Hi-Vision); the DCI-P3 (Digital Cinema Initiatives P3) standard used for digital cinema projection; and the ITU-R BT.2020 (REC.2020 (Recommendation 2020)) standard used for UHDTV (Ultra High Definition Television, also referred to as Super Hi-Vision); and the like.

Using the pixels 300 arranged in a matrix of 1920×1080, a display apparatus that can achieve full color display with a resolution of what is called full high definition (also referred to as “2K resolution”, “2K1K”, “2K”, or the like) can be obtained. For example, using the pixels 300 arranged in a matrix of 3840×2160, a display apparatus that can achieve full color display with a resolution of what is called ultra high definition (also referred to as “4K resolution”, “4K2K”, “4K”, or the like) can be obtained. For example, using the pixels 300 arranged in a matrix of 7680×4320, a display apparatus that can achieve full color display with a resolution of what is called super high definition (also referred to as “8K resolution”, “8K4K”, “8K”, or the like) can be obtained. By increasing the number of pixels 300, a display apparatus that can achieve full color display with 16K or 32K resolution can be achieved.

At least part of this embodiment can be implemented in combination with the other embodiments described in this specification as appropriate.

### Embodiment 6

In this embodiment, a CAC-OS (Cloud-Aligned Composite Oxide Semiconductor) and a CAAC-OS (c-axis Aligned Crystalline Oxide Semiconductor), which are metal oxides that can be used in the OS transistor described in the other embodiments, will be described.

### <Composition of Metal Oxide>

A CAC-OS or a CAC-metal oxide has a conducting function in part of the material and has an insulating function in another part of the material; as a whole, the CAC-OS or the CAC-metal oxide has a function of a semiconductor. In the case where the CAC-OS or the CAC-metal oxide is used in an active layer of a transistor, the conducting function is a function of allowing electrons (or holes) serving as carriers to flow, and the insulating function is a function of not allowing electrons serving as carriers to flow. By the complementary action of the conducting function and the insulating function, a switching function (On/Off function) can be given to the CAC-OS or the CAC-metal oxide. In the CAC-OS or the CAC-metal oxide, separation of the functions can maximize each function.

The CAC-OS or the CAC-metal oxide includes conductive regions and insulating regions. The conductive regions have the above-described conducting function, and the insulating regions have the above-described insulating function. Furthermore, in some cases, the conductive regions and the insulating regions in the material are separated at the nanoparticle level. Furthermore, in some cases, the conductive regions and the insulating regions are unevenly distributed in the material. Furthermore, in some cases, the conductive regions are observed to be coupled in a cloud-like manner with their boundaries blurred.

In the CAC-OS or the CAC-metal oxide, the conductive regions and the insulating regions each have a size greater than or equal to 0.5 nm and less than or equal to 10 nm, preferably greater than or equal to 0.5 nm and less than or equal to 3 nm and are dispersed in the material in some cases.

The CAC-OS or the CAC-metal oxide includes components having different band gaps. For example, the CAC-OS or the CAC-metal oxide includes a component having a wide gap due to the insulating region and a component having a narrow gap due to the conductive region. In the case of this structure, when carriers flow, carriers mainly flow in the component having a narrow gap. Furthermore, the component having a narrow gap complements the component having a wide gap, and carriers also flow in the component having a wide gap in conjunction with the component having a narrow gap. Therefore, in the case where the above-described CAC-OS or CAC-metal oxide is used in a channel formation region of a transistor, high current driving capability in the on state of the transistor, that is, a high on-state current and high field-effect mobility can be obtained.

In other words, the CAC-OS or the CAC-metal oxide can also be referred to as a matrix composite or a metal matrix composite.

### <Structure of Metal Oxide>

Oxide semiconductors can be classified into a single crystal oxide semiconductor and a non-single-crystal oxide semiconductor. Examples of a non-single-crystal oxide semiconductor include a CAAC-OS, a polycrystalline oxide semiconductor, an nc-OS (nanocrystalline oxide semiconductor), an amorphous-like oxide semiconductor (a-like OS), and an amorphous oxide semiconductor.

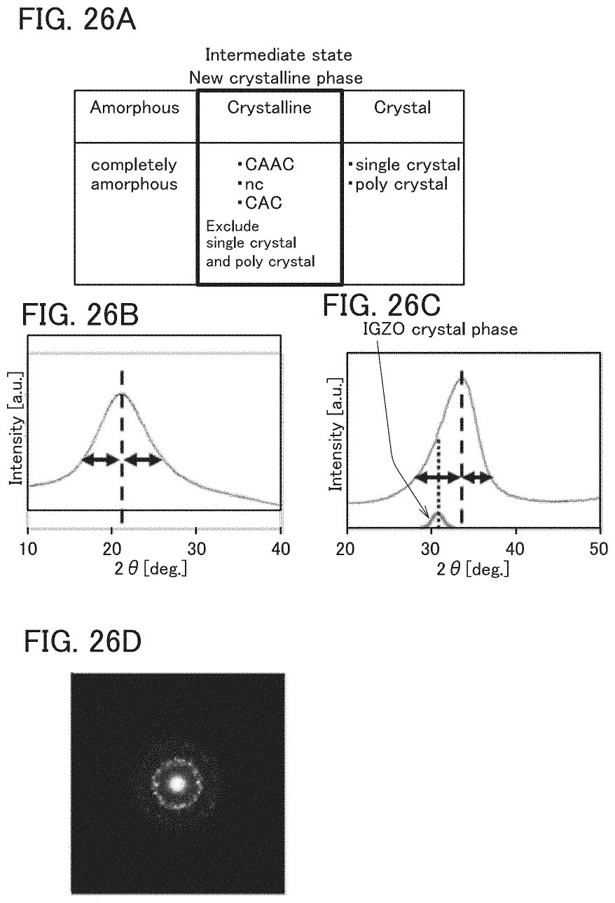

Oxide semiconductors might be classified in a manner different from the above-described one when classified in terms of the crystal structure. The classification of the crystal structures of oxide semiconductor will be explained with FIG. 26A. FIG. 26A is a diagram showing the classification of crystal structures of an oxide semiconductor, typically IGZO (a metal oxide containing In, Ga, and Zn).

As shown in FIG. 26A, IGZO is roughly classified into “Amorphous”, “Crystalline”, and “Crystal”. Amorphous includes completely amorphous. Crystalline includes CAAC (c-axis-aligned crystalline), nc (nanocrystalline), and CAC (Cloud-Aligned Composite). Note that in classification of Crystalline, single crystal, poly crystal, and completely amorphous are excluded. Crystal includes single crystal and poly crystal.

Note that the structure in the thick frame in FIG. 26A is in an intermediate state between “Amorphous” and “Crystal”, and belongs to a new crystalline phase. This structure is positioned in a boundary region between Amorphous and Crystal. In other words, the structure is completely different from “Amorphous”, which is energetically unstable, and “Crystal”.

A crystal structure of a film or a substrate can be analyzed with X-ray diffraction (XRD) images. Here, XRD spectra of quartz glass and IGZO, which has a crystal structure classified into crystalline (also referred to as crystalline IGZO), are shown in FIG. 26B and FIG. 26C. FIG. 26B shows an XRD spectrum of quartz glass and FIG. 26C shows an XRD spectrum of crystalline IGZO. Note that the crystalline IGZO film shown in FIG. 26C has a composition in vicinity of In:Ga:Zn=4:2:3 [atomic ratio]. Furthermore, the crystalline IGZO film shown in FIG. 26C has a thickness of 500 nm.

As indicated by arrows in FIG. 26B, the XRD spectrum of the quartz glass substrate shows a peak with a substantially bilaterally symmetrical shape. In contrast, as indicated by arrows in FIG. 26C, the XRD spectrum of the crystalline IGZO film shows a peak with an asymmetrical shape. The bilaterally asymmetrical peak of the XRD spectrum clearly shows the existence of crystal. In other words, the structure cannot be regarded as Amorphous unless it has a bilaterally symmetrical peak in the XRD spectrum. Note that in FIG. 26C, a crystal phase (IGZO crystal phase) is explicitly denoted at 2 θ of 31° or in the vicinity thereof. The asymmetrical shape of the peak of the XRD spectrum is presumably attributed to the crystal phase (microcrystal).

Specifically, in the XRD spectrum of the crystalline IGZO shown in FIG. 26C, there is a peak at 2 θ=34° or in the vicinity thereof. The microcrystal has a peak at 2 θ=31° or in the vicinity thereof. When an oxide semiconductor film is evaluated using an X-ray diffraction pattern, the spectrum becomes wide in the lower degree side than the peak at 2 θ=34° or in the vicinity thereof as shown in FIG. 26C. This indicates that the oxide semiconductor film includes a microcrystal having a peak at 2 θ=31° or in the vicinity thereof

A crystal structure of a film can also be evaluated with a diffraction pattern obtained by a nanobeam electron diffraction (NBED) method (also referred to as nanobeam electron diffraction pattern). FIG. 26D shows a diffraction pattern of an IGZO film which is formed at room temperature as substrate temperature. Note that the IGZO film in FIG. 26D is formed with a sputtering method using an In—Ga—Zn oxide target with In:Ga:Zn=1:1:1 [atomic ratio]. In the nanobeam electron diffraction method, electron diffraction is performed with a probe diameter of 1 nm.

As shown in FIG. 26D, not a halo pattern but a spot-like pattern is observed in the diffraction pattern of the IGZO film formed at room temperature. Thus, it is presumed that the IGZO film formed at room temperature is in an intermediate state, which is neither a crystal state nor an amorphous state, and it cannot be concluded that the IGZO film is in an amorphous state.

The CAAC-OS has c-axis alignment, a plurality of nanocrystals are connected in the a-b plane direction, and its crystal structure has distortion. Note that the distortion refers to a portion where the direction of a lattice arrangement changes between a region with a regular lattice arrangement and another region with a regular lattice arrangement in a region where the plurality of nanocrystals are connected.

The nanocrystal is basically a hexagon but is not always a regular hexagon and is a non-regular hexagon in some cases. Furthermore, a pentagonal or heptagonal lattice arrangement, for example, is included in the distortion in some cases. Note that a clear crystal grain boundary (also referred to as grain boundary) cannot be observed even in the vicinity of distortion in the CAAC-OS. That is, formation of a crystal grain boundary is inhibited due to the distortion of lattice arrangement. This is probably because the CAAC-OS can tolerate distortion owing to the low density of arrangement of oxygen atoms in the a-b plane direction, a change in interatomic bond distance by substitution of a metal element, and the like.

A crystal structure in which a clear crystal grain boundary (grain boundary) is observed is what is called a polycrystal structure. It is highly probable that the crystal grain boundary becomes a recombination center and traps carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, an In—Zn oxide and an In—Ga—Zn oxide are suitable because they can inhibit generation of a crystal grain boundary as compared with an In oxide.

Furthermore, the CAAC-OS tends to have a layered crystal structure (also referred to as a layered structure) in which a layer containing indium and oxygen (hereinafter, In layer) and a layer containing the element M, zinc, and oxygen (hereinafter, (M, Zn) layer) are stacked. Note that indium and the element M can be replaced with each other, and when the element M in the (M, Zn) layer is replaced with indium, the layer can also be referred to as an (In, M, Zn) layer. Furthermore, when indium in the In layer is replaced with the element M, the layer can be referred to as an (In, M) layer.

The CAAC-OS is an oxide semiconductor with high crystallinity. By contrast, in the CAAC-OS, it can be said that a reduction in electron mobility due to the crystal grain boundary is less likely to occur because a clear crystal grain boundary cannot be observed. Moreover, since the crystallinity of an oxide semiconductor might be decreased by entry of impurities, formation of defects, or the like, the CAAC-OS can be regarded as an oxide semiconductor that has small amounts of impurities and defects (oxygen vacancies or the like). Thus, an oxide semiconductor including a CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend a degree of freedom of the manufacturing process.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods.

The a-like OS is an oxide semiconductor having a structure between those of the nc-OS and the amorphous oxide semiconductor. The a-like OS contains a void or a low-density region. That is, the a-like OS has low crystallinity as compared with the nc-OS and the CAAC-OS.

An oxide semiconductor has various structures with different properties. Two or more of the amorphous oxide semiconductor, the polycrystalline oxide semiconductor, the a-like OS, the nc-OS, and the CAAC-OS may be included in an oxide semiconductor of one embodiment of the present invention.

### <Transistor Including Oxide Semiconductor>

Next, the case where the above oxide semiconductor is used for a transistor will be described.

When the above oxide semiconductor is used for a transistor, a transistor with high field-effect mobility can be achieved. In addition, a transistor having high reliability can be achieved.

An oxide semiconductor with a low carrier concentration is preferably used for a transistor. In the case where the carrier concentration of an oxide semiconductor film is lowered, the impurity concentration in the oxide semiconductor film is lowered to decrease the density of defect states. In this specification and the like, a state with a low impurity concentration and a low density of defect states is referred to as a highly purified intrinsic or substantially highly purified intrinsic state.

A highly purified intrinsic or substantially highly purified intrinsic oxide semiconductor film has a low density of defect states and thus has a low density of trap states in some cases.

Charges trapped by the trap states in the oxide semiconductor take a long time to be released and may behave like fixed charges. Thus, a transistor whose channel formation region is formed in an oxide semiconductor having a high density of trap states has unstable electrical characteristics in some cases.

Accordingly, in order to stabilize the electrical characteristics of the transistor, reducing the impurity concentration in the oxide semiconductor is effective. In addition, in order to reduce the concentration of impurities in the oxide semiconductor, the impurity concentration in an adjacent film is also preferably reduced. Examples of impurities include hydrogen, nitrogen, an alkali metal, an alkaline earth metal, iron, nickel, and silicon.

### <Impurity>

Here, the influence of each impurity in the oxide semiconductor will be described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are set lower than or equal to 2×10¹⁸ atoms/cm³, preferably lower than or equal to 2×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Accordingly, it is preferable to reduce the concentration of an alkali metal or an alkaline earth metal in the oxide semiconductor. Specifically, the concentration of an alkali metal or an alkaline earth metal in the oxide semiconductor that is obtained by SIMS is set lower than or equal to 1×10¹⁸ atoms/cm³, preferably lower than or equal to 2×10¹⁶ atoms/cm³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. Hence, nitrogen in the oxide semiconductor is preferably reduced as much as possible; the nitrogen concentration in the oxide semiconductor that is obtained by SIMS is set, for example, lower than 5×10¹⁹ atoms/cm³, preferably lower than or equal to 5×10¹⁸ atoms/cm³, further preferably lower than or equal to 1 x 10¹⁸ atoms/cm³, still further preferably lower than or equal to 5×10¹⁷ atoms/cm³.

Furthermore, hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, in some cases, bonding of part of hydrogen to oxygen bonded to a metal atom causes generation of an electron serving as a carrier. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor obtained by SIMS is lower than 1×10²⁰ atoms/cm³, preferably lower than 1×10¹⁹ atoms/cm³, further preferably lower than 5×10¹⁸ atoms/cm³, still further preferably lower than 1×10¹⁸ atoms/cm³.

When an oxide semiconductor with sufficiently reduced impurities is used for the channel formation region of the transistor, stable electrical characteristics can be given.

At least part of this embodiment can be implemented in combination with the other embodiments described in this specification as appropriate.

### Embodiment 7

In this embodiment, light-emitting devices that can be applied to display apparatuses of embodiments of the present invention and light-emitting models of the light-emitting devices will be described.

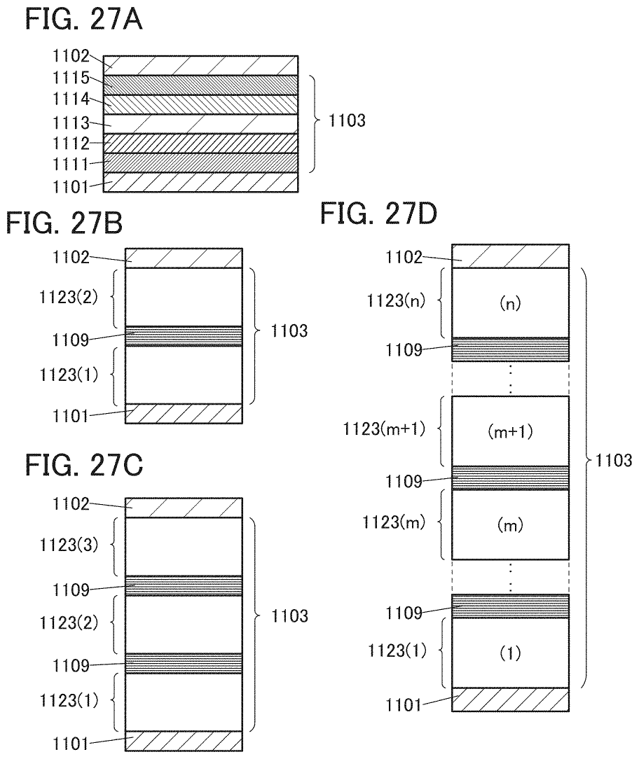

FIG. 27A to FIG. 27D are cross-sectional views illustrating structures of light-emitting devices. FIG. 27A is a cross-sectional view of a light-emitting device with a single structure, and FIG. 27B to FIG. 27D are cross-sectional views of light-emitting devices each with a tandem structure.

<Light-Emitting Device with Single Structure>

First, the light-emitting device with a single structure illustrated in FIG. 27A is described.

The light-emitting device illustrated in FIG. 27A includes an EL layer 1103 between a first electrode 1101 and a second electrode 1102. The EL layer 1103 includes a hole-injection layer 1111, a hole-transport layer 1112, a light-emitting layer 1113, an electron-transport layer 1114, and an electron-injection layer 1115.

Materials that can be used for the light-emitting devices of embodiments of the present invention will be described below.

### <First Electrode and Second Electrode>

The first electrode 1101 functions as either one of an anode and a cathode. The second electrode 1102 functions as either one of the anode and the cathode. Note that in this embodiment, description is given assuming that the first electrode 1101 and the electrode 1102 function as an anode and a cathode, respectively. In this embodiment, the first electrode 1101 has a visible-light-reflective property, and the second electrode 1102 has a visible-light-transmitting property. Note that one embodiment of the present invention is not limited thereto, and the second electrode 1102 may have a visible-light-reflective property and a visible-light-transmitting property. For example, in the case where a light-emitting device having a microcavity structure is formed, an electrode having a visible-light-reflective property and an electrode having both of a visible-light-reflective property and a visible-light-transmitting property can be favorably used.

For each of the first electrode 1101 and the second electrode 1102, a metal, an alloy, an electrically conductive compound, a mixture thereof, and the like can be used as appropriate. Specifically, an In—Sn oxide (also referred to as ITO), an In—Si—Sn oxide (also referred to as ITSO), an In—Zn oxide, or an In—W—Zn oxide can be used. In addition, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use an element belonging to Group 1 or Group 2 in the periodic table, which is not listed above as an example (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The first electrode 1101 and the second electrode 1102 can be formed by a sputtering method or a vacuum evaporation method.

### <Hole-Injection Layer>

The hole-injection layer 1111 preferably includes a first organic compound and a second organic compound. The first organic compound is a material that exhibits an electron-accepting property with respect to the second organic compound. The second organic compound is a material that has a relatively deep Highest Occupied Molecular Orbital (HOMO) level of higher than or equal to ˜5.7 eV and lower than or equal to ˜5.4 eV. The second organic compound with a relatively deep HOMO level allows easy hole injection into the hole-transport layer 1112.

As the first organic compound, an organic compound having an electron-withdrawing group (in particular, a cyano group or a halogen group such as a fluoro group) can be used, for example. A material that exhibits an electron-accepting property with respect to the second organic compound is selected as appropriate from such materials. Examples of such an organic compound include 7,7,8,8-tetracyano-2,3,5,6-tetrafluoroquinodimethane (abbreviation: F₄-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), and 2-(7-dicyanomethylene-1,3,4,5,6,8,9,10-octafluoro-7H-pyrene-2-ylidene)malononitrile. A compound in which electron-withdrawing groups are bonded to a condensed aromatic ring having a plurality of heteroatoms, such as HAT-CN, is preferred because it is thermally stable. A radialene derivative having an electron-withdrawing group (in particular, a cyano group or a halogen group such as a fluoro group) has a very high electron-accepting property and thus is preferred. Specific examples include α,α′,α″-1,2,3-cyclopropanetriylidenetris [4-cyano-2,3,5,6-tetrafluorobenzeneacetonitrile], α,α′,α″-1,2,3 -cyclopropanetriylidenetris [2,6-dichloro-3,5-difluoro-4-(trifluoromethyl)benzeneacetonitrile], and α,α′,α″-1,2,3-cyclopropanetriylidenetris [2,3,4,5 ,6-pentafluorobenzeneacetonitrile].

The second organic compound is preferably an organic compound having a hole-transport property and preferably includes at least one of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used.

Note that the second organic compound is preferably a material having an N,N-bis(4-biphenyl)amino group because a light-emitting device with a favorable lifetime can be fabricated.

<Hole-Transport layer>

The hole-transport layer 1112 preferably has a stacked-layer structure of two or more layers. For example, it is preferable that the hole-transport layer 1112 include a first layer and a second layer over the first layer, the first layer include a third organic compound, and the second layer include a fourth organic compound.

The third organic compound and the fourth organic compound are preferably organic compounds each having a hole-transport property. For the third organic compound and the fourth organic compound, a material similar to that of the organic compound that can be used as the second organic compound, can be used.

It is preferable that materials of the second organic compound and the third organic compound be selected so that the HOMO level of the third organic compound is deeper than that of the second organic compound and a difference between the HOMO levels is less than or equal to 0.2 eV. It is more preferable that the second organic compound and the third organic compound be the same material.

In addition, the HOMO level of the fourth organic compound is preferably deeper than the HOMO level of the third organic compound. It is preferable that materials be selected so that a difference between the HOMO levels is less than or equal to 0.2 eV. Owing to the above-described relation between the HOMO levels of the second organic compound to the fourth organic compound, holes are injected into each layer smoothly, which prevents an increase in driving voltage and deficiency of holes in the light-emitting layer.

The second organic compound to the fourth organic compound each preferably have a hole-transport skeleton. A carbazole skeleton, a dibenzofuran skeleton, a dibenzothiophene skeleton, and an anthracene skeleton, with which the HOMO levels of the organic compounds do not become too shallow, are preferably used as the hole-transport skeleton. Materials of adjacent layers (e.g., the second organic compound and the third organic compound or the third organic compound and the fourth organic compound) preferably have the same hole-transport skeleton, in which case holes can be injected smoothly. In particular, a dibenzofuran skeleton is preferably used as the hole-transport skeleton.

Furthermore, materials contained in adjacent layers (e.g., the second organic compound and the third organic compound or the third organic compound and the fourth organic compound) are preferably the same, in which case holes can be injected more smoothly. In particular, the second organic compound and the third organic compound are preferably the same material.

### <Light-Emitting Layer>

The light-emitting layer 1113 preferably contains a fifth organic compound and a sixth organic compound. The fifth organic compound is a material containing an emission center material (also referred to as a light-emitting material or a guest material), and the sixth organic compound is a host material for dispersing the fifth organic compound. Note that the sixth organic compound may be formed using one or more kinds of organic compounds (e.g., two kinds of organic compounds, a host material and an assist material). As the one or more kinds of organic compounds, one or both of the hole-transport material and the electron-transport material described in this embodiment can be used. As the one or more kinds of organic compounds, a bipolar material may be used.

The light-emitting layer 1113 can have either a single-layer structure or a stacked-layer structure including two or more layers. Note that in the case of the stacked-layer structure of two or more layers, different light-emitting materials may be contained in the plurality of layers.

The fifth organic compound is a light-emitting material, and the emission color of the light-emitting material may be, for example, blue, violet, blue violet, green, yellow green, yellow, orange, red, or the like. Note that in one embodiment of the present invention, in the case where the light-emitting layer 1113 contains a fluorescent light-emitting material, it is particularly preferable that the emission color be blue.

There is no particular limitation on the light-emitting material that can be used for the light-emitting layer 1113, and it is possible to use a light-emitting material that converts singlet excitation energy into light in the visible-light region or the near-infrared region (a fluorescent light-emitting material), or a light-emitting material that converts triplet excitation energy into light in the visible-light region or the near-infrared region (a phosphorescent light-emitting material or thermally activated delayed fluorescence (TADF) material).

### <Fluorescent Light-Emitting Material>

Examples of the light-emitting material that converts singlet excitation energy into light are fluorescent light-emitting materials such as a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative. A pyrene derivative is particularly preferable because it has a high emission quantum yield. Specific examples of the pyrene derivative include N,N-bis(3-methylphenyl)-N,N′-bis[3-(9-phenyl-9H-fluoren-9-yl)phenyl]pyrene-1,6-diamine (abbreviation: 1,6mMemFLPAPrn), N,N′-diphenyl-N,N-bis [4-(9-phenyl-9H-fluoren-9-yl)phenyl]pyrene-1,6-diamine (abbreviation: 1,6FLPAPrn), N,N-bis(dibenzofuran-2-yl)-N,N-diphenylpyrene-1,6-diamine (abbreviation: 1,6FrAPrn), N,N-bis(dibenzothiophen-2-yl)-N,N-diphenylpyrene-1,6-diamine (abbreviation: 1,6ThAPrn), N,N′-(pyrene-1,6-diyl)bis[(N-phenylbenzo[b]naphtho[1,2-d]furan)-6-amine] (abbreviation: 1,6BnfAPrn), N,N-(pyrene-1,6-diyl)bis[(N-phenylbenzo[b]naphtho[1,2-d]furan)-8-amine] (abbreviation: 1,6BnfAPrn-02), and N,N-(pyrene-1,6-diyl)bis[(6,N-diphenylbenzo[b]naphtho[1,2-d]furan)-8-amine] (abbreviation: 1,6BnfAPrn-03).

In addition, it is possible to use 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), 4-(10-phenyl-9-anthryl)-4′-(9-phenyl-9H-carbazol-3-yl)triphenylamine (abbreviation: PCBAPA), 4-[4-(10-phenyl-9-anthryl)phenyl]-4′-(9-phenyl-9H-carbazol-3-yl)triphenylamine (abbreviation: PCBAPBA), perylene, 2,5,8,11-tetra(tert-butyl)perylene (abbreviation: TBP), N,N″-(2-tert-butylanthracene-9,10-diyldi-4,1-phenylene)bis[N,N′,N-triphenyl-1,4-phenylenediamine] (abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N′-triphenyl-1,4-phenylenediamine (abbreviation: 2DPAPPA), and the like.

Examples of the light-emitting material that converts triplet excitation energy into light include a phosphorescent light-emitting material and a TADF material that exhibits thermally activated delayed fluorescence. Details of the TADF material will be described later.

### <Phosphorescent Light-Emitting Material>

Examples of the phosphorescent light-emitting material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

As examples of a phosphorescent light-emitting material which emits blue or green light and whose emission spectrum has a peak wavelength at greater than or equal to 450 nm and less than or equal to 570 nm, the following materials can be given.

The examples include organometallic complexes having a 4H-triazole skeleton, such as tris {2-[5-(2-methylpheny0-4-(2,6-dimethy1phenyl)-4H-1,2,4-triazol-3 -yl-κN²]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), tris [4-(3 -biphenyl)-54sopropyl-3-phenyl-4H-1,2,4-triazolato]iridium(III) (abbreviation: [Ir(iPrptz-3b)₃]), and tris [3-(5 -biphenyl)-5 -isopropyl-4-phenyl-4H-1,2,4-triazolato]iridium(III) (abbreviation: [Ir(iPr5btz)₃]); organometallic complexes having a 1H-triazole skeleton, such as tris[3-methyl-1-(2-methylphenyl)-5-phenyl-1H-1,2,4-triazolato]iridium(III) (abbreviation: [Ir(Mptzl-mp)₃]) and tris(1-methyl-5-phenyl-3-propyl-1H-1,2,4-triazolato)iridium(III) (abbreviation: [Ir(Prptzl-Me)₃]); organometallic complexes having an imidazole skeleton, such as fac-tris[1-(2,6-diisopropylphenyl)-2-phenyl-1H-imidazole]iridium(III) (abbreviation: [Ir(iPrpmi)₃]) and tris[3-(2,6-dimethylphenyl)-7-methylimidazo[1,2-f]phenanthridinato]iridium(III) (abbreviation: [Ir(dmpimpt-Me)₃]); and organometallic complexes having a phenylpyridine derivative including an electron-withdrawing group as a ligand, such as bis[2-(4′,6′-difluorophenyl)pyridinato-N,C²′]iridium(III) tetrakis(1-pyrazolyl)borate (abbreviation: FIr6), bis[2-(4′,6′-difluorophenyl)pyridinato-N,C²]iridium(III) picolinate (abbreviation: Flrpic), bis{2-[3′,5′-bis(trifluoromethyl)phenyl]pyridinato-N,C²′}iridium(III) picolinate (abbreviation: [Ir(CF3ppy)2(pic)]), and bis[2-(4′,6′-difluorophenyl)pyridinato-N,C²]iridium(III) acetylacetonate (abbreviation: FIr(acac)).

As examples of a phosphorescent light-emitting material which emits green or yellow light and whose emission spectrum has a peak wavelength at greater than or equal to 495 nm and less than or equal to 590 nm, the following materials can be given.

The examples include organometallic iridium complexes having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)2(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), (acetylacetonato)bis{4,6-dimethyl-2-[6-(2,6-dimethylphenyl)-4-pyrimidinyl-κN³]phenyl-κC}iridium(III) (abbreviation: [Ir(dmppm-dmp)₂(acac)]), and (acetylacetonato)bis(4,6-diphenylpyrimidinato)iridium(III) (abbreviation: [Ir(dppm)₂(acac)]); organometallic iridium complexes having a pyrazine skeleton, such as (acetylacetonato)bis(3,5-dimethyl-2-phenylpyrazinato)iridium(III) (abbreviation: [Ir(mppr-Me)₂(acac)]) and (acetylacetonato)bis(5 sopropyl-3-methyl-2-phenylpyrazinato)iridium(III) (abbreviation: [Ir(mppr-iPr)₂(acac)]); organometallic iridium complexes having a pyridine skeleton, such as tris(2-phenylpyridinato-N,C²′)iridium(III) (abbreviation: [Ir(ppy)₃]), bis(2-phenylpyridinato-N,C²′)iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C²′)iridium(III) (abbreviation: [Ir(pq)₃]), bis(2-phenylquinolinato-N,C²′)iridium(III) acetylacetonate (abbreviation: [Ir(pq)₂(acac)]), [2-4-phenyl-2-pyridinyl-κN)phenyl-κC]bis[2-(2-pyridinyl-κN)phenyl-κC]iridium(III) (abbreviation: [Ir(ppy)₂(4dppy)], and bis[2-(2-pyridinyl-κN)phenyl-κC][2-(4-methyl-5-phenyl-2-pyridinyl-κ,N)phenyl-KC]; organometallic complexes such as bis(2,4-diphenyl-1,3-oxazolato-N,C²′)iridium(III) acetylacetonate (abbreviation: [Ir(dpo)₂(acac)]), bis{2-[4′-(perfluorophenyl)phenyl]pyridinato-N,C²}iridium(III) acetylacetonate (abbreviation: [Ir(p-PF-ph)₂(acac)]), and bis(2-phenylbenzothiazolato-N,C²′)iridium(III) acetylacetonate (abbreviation: [Ir(bt)₂(acac)]); and rare earth metal complexes such as tris(acetylacetonato)(monophenanthroline)terbium(III) (abbreviation: [Tb(acac)3(Phen)]).

As examples of a phosphorescent light-emitting material which emits yellow or red light and whose emission spectrum has a peak wavelength at greater than or equal to 570 nm and less than or equal to 750 nm, the following materials can be given.

The examples include organometallic complexes having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), bis[4,6-di(naphthalen-1-yl)pyrimidinato](dipivaloylmethanato)iridium(III) (abbreviation: [Ir(dlnpm)₂(dpm)]), and tris(4-t-butyl-6-phenylpyrimidinato)iridium(III) (abbreviation: [Ir(tBuppm)₃]); organometallic complexes having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), bis{4,6-dimethyl-2-[3-(3,5-dimethylphenyl)-5-phenyl-2-pyrazinyl-κN]phenyl-κC}(2,6-dimethyl-3,5-heptanedionato-κ²O,O′)iridium(III) (abbreviation: [Ir(dmdppr-P)₂(dibm)]), bis{4,6-di methyl-2-[5-(4-cyano-2,6-dimethylphenyl)-3 -(3,5 - dimethylphenyl)-2-pyrazinyl-κN]phenyl-κC}(2,2,6,6-tetramethyl-3,5-heptanedionato-κ²O,O′)iridium(III) (abbreviation: [Ir(dmdppr-dmCP)₂(dpm)]), (acetylacetonato)bis[2-methyl-3-phenylquinoxalinato-N,C²′]iridium(III) (abbreviation: [Ir(mpq)₂(acac)]), (acetylacetonato)bis(2,3-diphenylquinoxalinato-N,C²′)iridium(III) (abbreviation: [Ir(dpq)₂(acac)]), (acetylacetonato)bis[2,3-bis(4-fluorophenyl)quinoxalinato]iridium(III) (abbreviation: [Ir(Fdpq)₂(acac)]), and bis{4,6-dimethyl-2-[5-(5-cyano-2-methylphenyl)-3-(3,5-dimethylphenyl)-2-pyrazinyl-κN]phenyl-κC}(2,2,6,6-tetramethyl-3,5-heptanedionato-κ²O,O′)iridium(III) (abbreviation: [Ir(dmdppr-m5CP)₂(dpm)]); organometallic complexes having a pyridine skeleton, such as tris(1-phenylisoquinolinato-N,C²′)iridium(III) (abbreviation: [Ir(piq)₃]), bis(1-pheny soquinolinato-N,C²′)iridium(III) acetylacetonate (abbreviation: [Ir(piq)₂(acac)]), and bis[4,6-dimethyl-2-(2-quinolinyl-κN)phenyl-κC](2,4-pentanedionato-K²O,O)iridium(III); platinum complexes such as 2,3,7,8,12,13,17,18-octaethyl-21H,23H-porphyrin platinum(II) (abbreviation: [PtOEP]); and rare earth metal complexes such as tris(1,3-diphenyl-1,3-propanedionato)(monophenanthroline)europium(III) (abbreviation: [Eu(DBM)3(Phen)]) and tris [1-(2-thenoyl)-3,3,3-trifluoroacetonato](monophenanthroline)europium(III) (abbreviation: [Eu(TTA)3(Phen)]).

As the organic compound (e.g., the host material or the assist material) used in the light-emitting layer, one or more kinds of materials having a larger energy gap than the light-emitting material can be used.

As an organic compound (host material) used in combination with a fluorescent light-emitting material, it is preferable to use an organic compound that has a high energy level in a singlet excited state and has a low energy level in a triplet excited state.

In terms of a preferable combination with the light-emitting material (a fluorescent light-emitting material or a phosphorescent light-emitting material), specific examples of the organic compound will be shown below though some of them overlap the specific examples shown above.

Examples of the organic compound that can be used in combination with a fluorescent light-emitting material include condensed polycyclic aromatic compounds such as an anthracene derivative, a tetracene derivative, a phenanthrene derivative, a pyrene derivative, a chrysene derivative, and a dibenzo[g,p]chrysene derivative.

Specific examples of the organic compound (the host materials) used in combination with a fluorescent light-emitting material include 9-phenyl-3-[4(10-phenyl-9-anthryl)phenyl]-9H-carbazole (abbreviation: PCzPA), 3,6-diphenyl-9-[4-(10-phenyl-9-anthryl)phenyl]-9H-carbazole (abbreviation: DPCzPA), 3-[4-(1-naphthyl)-phenyl]-9-phenyl-9H-carbazole (abbreviation: PCPN), 9,10-diphenylanthracene (abbreviation: DPAnth), N,N-diphenyl-9-[4-(10-phenyl-9-anthryl)phenyl]-9H-carbazol-3-amine (abbreviation: CzA1PA), 4-(10-phenyl-9-anthryl)triphenylamine (abbreviation: DPhPA), YGAPA, PCAPA, N,9-diphenyl-N-{4-[4-(10-phenyl-9-anthryl)phenyl]phenyl}-9H-carbazol-3-amine (abbreviation: PCAPBA), N-(9,10-diphenyl-2-anthryl)-N,9-diphenyl-9H-carbazol-3-amine (abbreviation: 2PCAPA), 6,12-dimethoxy-5,11-diphenylchrysene, N,N,N′,N′,N″,N″,N′″,N′″-octaphenyldibenzo[g,p]chrysene-2,7,10,15-tetraamine (abbreviation: DBC1), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]-benzo[b]naphtho [1,2-d]furan (abbreviation: 2mBnfPPA), 9-phenyl-10-{4-(9-phenyl-9H-fluoren-9-yl)-biphenyl-4′-yl}-anthracene (abbreviation: FLPPA), 9,10-bis(3,5-diphenylphenyl)anthracene (abbreviation: DPPA), 9,10-di(2-naphthyl)anthracene (abbreviation: DNA), 2-tent-butyl-9,10-di(2-naphthyl)anthracene (abbreviation: t-BuDNA), 9,9′-bianthryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 1,3,5-tri(1-pyrenyl)benzene (abbreviation: TPB3), and 5,12-diphenyltetracene, 5,12-bis(biphenyl-2-yl)tetracene.

As the organic compound used in combination with a phosphorescent light-emitting material, an organic compound having triplet excitation energy (an energy difference between a ground state and a triplet excited state) which is higher than that of the light-emitting material is selected.

When a plurality of organic compounds (e.g., a first host material and a second host material (or an assist material)) are used in combination with the light-emitting material so that an exciplex is formed, the plurality of organic compounds are preferably mixed with a phosphorescent light-emitting material (in particular, an organometallic complex).

With such a structure, light emission can be efficiently obtained by ExTET (Exciplex-Triplet Energy Transfer), which is energy transfer from an exciplex to a light-emitting material. Note that a combination of the plurality of organic compounds that easily forms an exciplex is preferably employed, and it is particularly preferable to combine a compound that easily accepts holes (a hole-transport material) and a compound that easily accepts electrons (an electron-transport material). When a combination of materials is selected so as to form an exciplex that exhibits light emission whose wavelength overlaps with the wavelength on a lowest-energy-side absorption band of the light-emitting material, energy can be transferred smoothly and light emission can be obtained efficiently. As the hole-transport material and the electron-transport material, specifically, any of the materials described in this embodiment can be used. With the above structure, high efficiency, low voltage, and a long lifetime of the light-emitting device can be achieved at the same time.

In a combination of materials for forming an exciplex, the HOMO level of the hole-transport material is preferably higher than or equal to that of the electron-transport material. In addition, the LUMO level (the lowest unoccupied molecular orbital level) of the hole-transport material is preferably higher than or equal to that of the electron-transport material. The LUMO levels and the HOMO levels of the materials can be derived from the electrochemical characteristics (the reduction potentials and the oxidation potentials) of the materials that are measured by cyclic voltammetry (CV).

The formation of an exciplex can be confirmed, for example, by a phenomenon in which the emission spectrum of a mixed film in which the hole-transport material and the electron-transport material are mixed is shifted to the longer wavelength side than the emission spectra of each of the materials (or has another peak on the longer wavelength side) observed by comparison of the emission spectra of the hole-transport material, the electron-transport material, and the mixed film of these materials. Alternatively, the formation of an exciplex can be confirmed by a difference in transient response, such as a phenomenon in which the transient photoluminescence (PL) lifetime of the mixed film has more long-lifetime components or has a larger proportion of delayed components than that of each of the materials, observed by comparison of transient PL of the hole-transport material, the electron-transport material, and the mixed film of these materials. The transient PL can be rephrased as transient electroluminescence (EL). That is, the formation of an exciplex can also be confirmed by a difference in transient response observed by comparison of the transient EL of the material having a hole-transport property, the transient EL of the material having an electron-transport property, and the transient EL of the mixed film of the materials.

Examples of the organic compound that can be used in combination with a phosphorescent light-emitting material include an aromatic amine (a compound having an aromatic amine skeleton), a carbazole derivative (a compound having a carbazole skeleton), a dibenzothiophene derivative (a thiophene derivative), a dibenzofuran derivative (a furan derivative), zinc- and aluminum-based metal complexes, an oxadiazole derivative, a triazole derivative, a benzimidazole derivative, a quinoxaline derivative, a dibenzoquinoxaline derivative, a pyrimidine derivative, a triazine derivative, a pyridine derivative, a bipyridine derivative, and a phenanthroline derivative.

Specific examples of the aromatic amine, the carbazole derivative, the dibenzothiophene derivative, and the dibenzofuran derivative, which are organic compounds having a high hole-transport property, are given below.

Examples of the carbazole derivative include a bicarbazole derivative (e.g., a 3,3′-bicarbazole derivative) and an aromatic amine having a carbazolyl group.

Specific examples of the bicarbazole derivative (e.g., a 3,3′-bicarbazole derivative) include 3,3′-bis(9-phenyl-9H-carbazole) (abbreviation: PCCP), 9,9′-bis(1,1′-biphenyl-4-yl)-3,3′-bi-9H-carbazole, 9,9′-bis(1,1′-biphenyl-3-yl)-3,3′-bi-9H-carbazole, 9-(1,1′-biphenyl-3-yl)-9′-(1,1′-biphenyl-4-yl)-9H, 9′H-3,3′-bicarbazole (abbreviation: mBPCCBP), 9-(2-naphthyl)-9′-phenyl-9H, 9′H-3,3′-bicarbazole (abbreviation: (3NCCP).

Specific examples of the aromatic amine having a carbazolyl group include PCBA1BP, N-(4-biphenyl)-N-(9,9-dimethyl-9H-fluoren-2-yl)-9-phenyl-9H-carbazol-3-amine (abbreviation: PCBiF), PCBBiF, PCBBi1BP, PCBANB, PCBNBB, 4-phenyldiphenyl-(9-phenyl-9H-carbazol-3-yl)amine (abbreviation: PCA1BP), N,N′-bis(9-phenylcarbazol-3-yl)-N,N-diphenylbenzene-1,3-diamine (abbreviation: PCA2B), N,N′,N″-triphenyl-N,N′,N″-tris(9-phenylcarbazol-3-yl)benzene-1,3,5-triamine (abbreviation: PCA3B), 9,9-dimethyl-N-phenyl-N-[4-(9-phenyl-9H-carbazol-3-yl)phenyl]fluoren-2-amine (abbreviation: PCBAF), PCBASF, 3-[N-(9-phenylcarbazol-3-yl)-N-phenylamino]-9-phenylcarbazole (abbreviation: PCzPCA1), 3,6-bis[N-(9-phenylcarbazol-3-yl)-N-phenylamino]-9-phenylcarbazole (abbreviation: PCzPCA2), 3-[N-(1-naphthyl)-N-(9-phenylcarbazol-3-yl)amino]-9-phenylcarbazole (abbreviation: PCzPCN1), 3-[N-(4-diphenylaminophenyl)-N-phenylamino]-9-phenylcarbazole (abbreviation: PCzDPA1), 3,6-bis[N-(4-diphenylaminophenyl)-N-phenylamino]-9-phenylcarbazole (abbreviation: PCzDPA2), 3,6-bis[N-(4-diphenylaminophenyl)-N-(1-naphthyl)amino]-9-phenylcarbazole (abbreviation: PCzTPN2), 2-[N-(9-phenylcarbazol-3-yl)-N-phenylamino1spiro-9,9′-bifluorene (abbreviation: PCASF), N-8 4-(9H-carbazol-9-yl)phenyl]-N-(4-phenyl)phenylaniline (abbreviation: YGA1BP), N,N′-bis[4-(carbazol-9-yl)phenyl]-N,N′-diphenyl-9,9-dimethylfluorene-2,7-diamine (abbreviation: YGA2F), and 4,4′,4″-tris(carbazol-9-yl)triphenylamine (abbreviation: TCTA).

Other examples of the carbazole derivative include 3-[4(9-phenanthryl)-phenyl]-9-phenyl-9H-carbazole (abbreviation: PCPPn), PCPN, 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 1,3,5-tris[4-(N-carbazolyl)phenyl]benzene (abbreviation: TCPB), and CzPA.

Specific examples of the thiophene derivative (a compound having a thiophene skeleton) and the furan derivative (a compound having a furan skeleton) include compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV), and 4-{3-[3-(9-phenyl-9H-fluoren-9-yl)phenyl]phenyl}dibenzofuran (abbreviation: mmDBFFLBi-II).

Specific examples of the aromatic amine include 4,4′-bis[N-(1-naphthyl)-N-phenylamino]biphenyl (abbreviation: NPB or α-NPD), N,N-bis(3-methylphenyl)-N,N-diphenyl-[1,1′-biphenyl]-4,4′-diamine (abbreviation: TPD), 4,4′-bis[N-(spiro-9,9′-bifluoren-2-yl)-N-phenylamino]biphenyl (abbreviation: BSPB), BPAFLP, mBPAFLP, N-(9,9-dimethyl-9H-fluoren-2-yl)-N-{9,9-dimethyl-2-[N-phenyl-N-(9,9-dimethyl-9H-fluoren-2-yl)amino]-9H-fluoren-7-yl}phenylamine (abbreviation: DFLADFL), N-(9,9-dimethyl-2-diphenylamino-9H-fluoren-7yl)diphenylamine (abbreviation: DPNF), 2-[N-(4-diphenylaminophenyl)-N-phenylamino]spiro-9,9′-bifluorene (abbreviation: DPASF), 2,7-bis[N-(4-diphenylaminophenyl)-N-phenylamino]-spiro-9,9′-bifluorene (abbreviation: DPA2SF), 4,4′,4″-tris [N-(1-naphthyl)-N-phenylamino]triphenylamine (abbreviation: 1′-TNATA), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), N,N′-di(p-tolyl)-N,N′-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), and 1,3,5 -tris [N-(4-diphenylaminophenyl)-N-phenylamino]benzene (abbreviation: DPA3B).

As the organic compound having a high hole-transport property, a high molecular compound such as poly(N-vinylcarbazole) (abbreviation: PVK), poly(-vinyltriphenylamine) (abbreviation: PVTPA), poly [N-(4-{N-[4-(4-diphenylamino)phenyl]phenyl-N-phenylamino}phenyl)methacrylamide](abbreviation: PTPDMA), or poly [N,N′-bis(4-butylphenyl)-N,N-bis(phenyl)benzidine](abbreviation: Poly-TPD) can also be used.

Specific examples of the zinc- and aluminum-based metal complexes, which are organic compounds having a high electron-transport property, include metal complexes having a quinoline skeleton or a benzoquinoline skeleton, such as tris(8-quinolinolato)aluminum(III) (abbreviation: Alq), tris(4-methyl-8-quinolinolato)aluminum(III) (abbreviation: Almq3), bis(10-hydroxybenzo [h]quinolinato)beryllium(II) (abbreviation: BeBq2), bis(2-methyl-8-quinolinolato)(4-phenylphenolato)aluminum(III) (abbreviation: BAlq), and bis(8-quinolinolato)zinc(II) (abbreviation: Znq).

Alternatively, a metal complex having an oxazole-based or thiazole-based ligand, such as bis[2-(2-benzoxazolyl)phenolato]zinc(II) (abbreviation: ZnPBO) or bis[2-(2-benzothiazolyl)phenolato]zinc(II) (abbreviation: ZnBTZ), can be used.

Specific examples of the oxadiazole derivative, the triazole derivative, the benzimidazole derivative, the quinoxaline derivative, the dibenzoquinoxaline derivative, and the phenanthroline derivative, which are organic compounds having a high electron-transport property, include 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 9-[4-(5-phenyl-1,3,4-xadiazol-2-yl)phenyl]-9H-carbazole (abbreviation: CO11), 3-(4-biphenylyl)-4-phenyl-5-(4-tert-butylphenyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), 4,4′-bis(5-methylbenzoxazol-2-yl)stilbene (abbreviation: BzOS, bathophenanthroline (abbreviation: Bphen), bathocuproine (abbreviation: BCP), 2,9-bis(naphthalen-2-yl)-4,7-diphenyl-1,10-phenanthroline (abbreviation: NBphen), 2-[3-(dibenzothiophen-4-yl)phenyl]dibenzo[f,]quinoxaline (abbreviation: 2mDBTPDBq-II), 2-[3′-(dibenzothiophen-4-yl)biphenyl-3-yl]dibenzo[f,h]quinoxaline (abbreviation: 2mDBTBPDBq-II), 243′-(9H-carbazol-9-yl)biphenyl-3-yl1dibenzo[f,h]quinoxaline (abbreviation: 2mCzBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[fh]quinoxaline (abbreviation: 7mDBTPDBq-II), and 6[3-(dibenzothiophen-4-yl)phenyl]dibenzo[f,h]quinoxaline (abbreviation: 6mDBTPDBq-II).

Specific examples of a heterocyclic compound having a diazine skeleton, a heterocyclic compound having a triazine skeleton, and a heterocyclic compound having a pyridine skeleton, which are organic compounds having a high electron-transport property, include 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 3,5-bis(3-(9H-carbazol-9-yl)phenyl)pyridine (abbreviation: 35DCzPPy), and 1,3,5-tri[3-(3-pyridyl)phenyl]benzene (abbreviation: TmPyPB).

As the organic compound having a high electron-transport property, a high molecular compound such as poly(2,5-pyridinediyl) (abbreviation: PPy), poly [(9,9-dihexylfluorene-2,7-diyl)-co-(pyridine-3,5-diyl)](abbreviation: PF-Py), or poly [(9,9-dioctylfluorene-2,7-diyl)-co-(2,2′-bipyridine-6,6′-diyl)](abbreviation: PF-BPy) can also be used.

### <TADF Material>

The TADF material has a small difference between the S₁ level (energy level in a singlet excited state) and the T₁ level (energy level in a triplet excited state) and has a function of converting triplet excitation energy into singlet excitation energy by reverse intersystem crossing. Thus, the TADF material can upconvert triplet excitation energy into singlet excitation energy (i.e., reverse intersystem crossing is possible) using a small amount of thermal energy and efficiently generate a singlet excited state. In addition, the triplet excitation energy can be converted into luminescence. Thermally activated delayed fluorescence is efficiently obtained under the condition where the energy difference between the S₁ level and the T₁ level is greater than or equal to 0 eV and less than or equal to 0.2 eV, preferably greater than or equal to 0 eV and less than or equal to 0.1 eV. Note that “delayed fluorescence” exhibited by the TADF material refers to light emission having the same spectrum as normal fluorescence and an extremely long lifetime. The lifetime is 1×10⁻⁶ seconds or longer, preferably 1×10⁻³ seconds or longer.

An exciplex whose excited state is formed of two kinds of materials has an extremely small difference between the S₁ level and the T₁ level and functions as a TADF material capable of converting triplet excitation energy into singlet excitation energy.

A phosphorescent spectrum observed at low temperatures (e.g., 77 K to 10 K) is used for an index of the T₁ level. When the level of energy with a wavelength of the line obtained by extrapolating a tangent to the fluorescent spectrum at a tail on the short wavelength side is the S₁ level and the level of energy with a wavelength of the line obtained by extrapolating a tangent to the phosphorescent spectrum at a tail on the short wavelength side is the T₁ level, the difference between the S₁ level and the T₁ level of the TADF material is preferably smaller than or equal to 0.3 eV, further preferably smaller than or equal to 0.2 eV.

Examples of the TADF material include fullerene, a derivative thereof, an acridine derivative such as proflavine, and eosin. Other examples include a metal-containing porphyrin such as a porphyrin containing magnesium (Mg), zinc (Zn), cadmium (Cd), tin (Sn), platinum (Pt), indium (In), or palladium (Pd). Examples of the metal-containing porphyrin include a protoporphyrin-tin fluoride complex (abbreviation: SnF₂(Proto IX)), a mesoporphyrin-tin fluoride complex (abbreviation: SnF₂(Meso IX)), a hematoporphyrin-tin fluoride complex (abbreviation: SnF₂(Hemato IX)), a coproporphyrin tetramethyl ester-tin fluoride complex (abbreviation: SnF₂(Copro III-4Me)), an octaethylporphyrin-tin fluoride complex (abbreviation: SnF₂(OEP)), an etioporphyrin-tin fluoride complex (abbreviation: SnF₂(Etio I)), and an octaethylporphyrin-platinum chloride complex (abbreviation: PtCl₂OEP).

It is also possible to use a heterocyclic compound having a π-electron rich heteroaromatic ring and a π-electron deficient heteroaromatic ring, such as 2-(biphenyl-4-yl)-4,6-bis(12-phenylindolo[2,3 -a]carbazol-11-yl)-1,3,5-triazine (abbreviation: PIC-TRZ), PCCzPTzn, 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5 -diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), 10-phenyl-10H,10′H-spiro[acridin-9,9′-anthracen]-10′-one (abbreviation: ACRSA), 4-(9′-phenyl-3,3′-bi-9H-carbozyl-9-yl)benzofuro [3,2-d]pyrimidine (abbreviation: 4PCCzBfpm), 4-[4-(9′-phenyl-3,3′-bi-9H-carbazol-9-yl)phenyl]benzofuro[3,2-d]pyrimidine (abbreviation: 4PCCzPBfpm), or 9-[3-(4,6-diphenyl-1,3,5-triazin-2-yl)phenyl]-9′-phenyl-2,3′-bi-9H-carbazole (abbreviation: mPCCzPTzn-02).

The heterocyclic compound is preferable because of having both a high electron-transport property and a high hole-transport property owing to a π-electron rich heteroaromatic ring and a π-electron deficient heteroaromatic ring. Among skeletons having the π-electron deficient heteroaromatic ring, a pyridine skeleton, a diazine skeleton (a pyrimidine skeleton, a pyrazine skeleton, and a pyridazine skeleton), and a triazine skeleton are preferred because of their high stability and reliability. In particular, a benzofuropyrimidine skeleton, a benzothienopyrimidine skeleton, a benzofuropyrazine skeleton, and a benzothienopyrazine skeleton are preferred because of their high electron-accepting properties and reliability.

Among skeletons having a π-electron rich heteroaromatic ring, an acridine skeleton, a phenoxazine skeleton, a phenothiazine skeleton, a furan skeleton, a thiophene skeleton, and a pyrrole skeleton have high stability and reliability; therefore, at least one of these skeletons is preferably included. Note that a dibenzofuran skeleton and a dibenzothiophene skeleton are preferable as the furan skeleton and the thiophene skeleton, respectively. As the pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable.

Note that a material in which a π-electron rich heteroaromatic ring and a π-electron deficient heteroaromatic ring are directly bonded to each other is particularly preferable because the electron-donating property of the π-electron rich heteroaromatic ring and the electron- accepting property of the π-electron deficient heteroaromatic ring are both increased and the energy difference between the S₁ level and the T₁ level becomes small, so that thermally activated delayed fluorescence can be obtained efficiently. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a boron-containing skeleton such as phenylborane or boranthrene, an aromatic ring or a heteroaromatic ring having a nitrile group or a cyano group, such as benzonitrile or cyanobenzene, a carbonyl skeleton such as benzophenone, a phosphine oxide skeleton, a sulfone skeleton, or the like can be used.

As described above, at least one of a π-electron deficient skeleton and a π-electron rich skeleton can be used instead of at least one of the π-electron deficient heteroaromatic ring and the π-electron rich heteroaromatic ring.

Note that the TADF material can also be used in combination with another organic compound. In particular, the TADF material can be used in combination with the host material, the hole-transport material, and the electron-transport material described above. When the TADF material is used, the S₁ level of the host material is preferably higher than that of the TADF material. In addition, the T₁ level of the host material is preferably higher than that of the TADF material.

Alternatively, a TADF material may be used as a host material, and a fluorescent light-emitting material may be used as a guest material. When the TADF material is used as the host material, triplet excitation energy generated in the TADF material is converted into singlet excitation energy by reverse intersystem crossing and transferred to the light-emitting material, whereby the emission efficiency of the light-emitting device can be increased. Here, the TADF material functions as an energy donor, and the light-emitting material functions as an energy acceptor. Therefore, the use of the TADF material as the host material is highly effective in the case where a fluorescent light-emitting material is used as the guest material. In that case, it is preferable that the S₁ level of the TADF material be higher than the S₁ level of the fluorescent light-emitting material in order that high emission efficiency be achieved. Furthermore, the T₁ level of the TADF material is preferably higher than the S₁ level of the fluorescent light-emitting material. Therefore, the T₁ level of the TADF material is preferably higher than the T₁ level of the fluorescent light-emitting material.

It is preferable to use a TADF material that emits light with a wavelength that overlaps the wavelength of the absorption band on the lowest energy side of the fluorescent light-emitting material, in which case the excitation energy is smoothly transferred from the TADF material to the fluorescent light-emitting material and light is emitted with high efficiency.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent light-emitting material. For that reason, the fluorescent light-emitting material preferably has a protective group around a luminophore (a skeleton that causes light emission) of the fluorescent light-emitting material. As the protective group, a substituent having no π bond and a saturated hydrocarbon are preferably used. Specific examples include an alkyl group having 3 to 10 carbon atoms, a substituted or unsubstituted cycloalkyl group having 3 to 10 carbon atoms, and a trialkylsilyl group having 3 to 10 carbon atoms. It is further preferable that the fluorescent light-emitting material have a plurality of protective groups. Since substituents having no π bond are poor in carrier transport performance, the TADF material and the luminophore of the fluorescent light-emitting material can be made away from each other with little influence on carrier transportation or carrier recombination. Here, the luminophore refers to an atomic group (skeleton) that causes light emission in a fluorescent light-emitting material. The luminophore is preferably a skeleton having a π bond, further preferably includes an aromatic ring, and still further preferably includes a condensed aromatic ring or a condensed heteroaromatic ring. Examples of the condensed aromatic ring and the condensed heteroaromatic ring include a phenanthrene skeleton, a stilbene skeleton, an acridone skeleton, a phenoxazine skeleton, and a phenothiazine skeleton. Specifically, a fluorescent light-emitting material having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferred because of its high fluorescence quantum yield.

Note that the above-mentioned TADF material may be used as a host material of the light-emitting layer.

### <Electron-Transport Layer>

The electron-transport layer 1114 is provided in contact with the light-emitting layer 1113. The electron-transport layer 1114 contains a seventh organic compound having an electron-transport property and a HOMO level of −6.0 eV or higher. The seventh organic compound preferably has an anthracene skeleton. The electron-transport layer 1114 may further contain an eighth organic compound in addition to the seventh organic compound. The eighth organic compound preferably contains an organic complex of an alkali metal or an alkaline earth metal. That is, examples of the structure of the electron-transport layer 1114 include a structure in which the seventh organic compound is used alone, a structure in which a plurality of organic compounds; specifically, the seventh organic compound and the eighth organic compound, is used, and the like.

Note that it is further preferable that the seventh organic compound have an anthracene skeleton and a heterocyclic skeleton. The heterocyclic skeleton is preferably a nitrogen-containing five-membered ring skeleton. More preferably, the nitrogen-containing five-membered ring skeleton includes two heteroatoms in a ring, like a pyrazol ring, an imidazole ring, an oxazole ring, or a thiazole ring.

Alternatively, for the material having an electron-transport property which can be used as the seventh organic compound, a material having an electron-transport property which can be used as the above host material, or a material which can be used as the host material of the above fluorescent light-emitting material, can be used.

The organic complex of an alkali metal or an alkaline earth metal is preferably an organic complex of lithium, and particularly preferably 8-quinolinolato-lithium (abbreviation: Liq).

Note that the electron mobility of the material included in the electron-transport layer 1114 in the case where the square root of the electric field strength [V/cm] is 600 is preferably higher than or equal to 1×10⁻⁷ cm²/Vs and lower than or equal to 5×10⁻⁵ cm²/Vs.

Furthermore, the electron mobility of the material included in the electron-transport layer 1114 in the case where the square root of the electric field strength [V/cm] is 600 is preferably lower than the electron mobility of the sixth organic compound or the material included in the light-emitting layer 1113 in the case where the square root of the electric field strength [V/cm] is 600. The amount of electrons injected into the light-emitting layer can be controlled by the reduction in the electron-transport property of the electron-transport layer, whereby the light-emitting layer can be prevented from having excess electrons.

### <Electron-Injection Layer>

The electron-injection layer 1115 increases the injection efficiency of electrons from the second electrode 1102. The difference between the work function of the material of the second electrode 1102 and the LUMO level of the material used for the electron-injection layer 1115 is preferably small (within 0.5 eV).

The electron-injection layer 1115 can be formed using an alkali metal, an alkaline earth metal, or a compound thereof, such as lithium, cesium, lithium fluoride (LiF), cesium fluoride (CsF), calcium fluoride (CaF₂), 8-(quinolinolato)lithium (abbreviation: Liq), 2-(2-pyridyl)phenolatolithium (abbreviation: LiPP), 2-(2-pyridyl)-3-pyridinolato lithium (abbreviation: LiPPy), 4-phenyl-2-(2-pyridyl)phenolato lithium (abbreviation: LiPPP), lithium oxide (LiOₓ) or cesium carbonate. A rare earth metal compound like erbium fluoride (ErF₃) can also be used. Electride may also be used for the electron-injection layer. An example of the electride includes a material in which electrons are added at high concentration to calcium oxide-aluminum oxide. Any of the above-described materials used for the electron-transport layer can also be used.

A composite material containing an electron-transport material and a donor material (an electron-donating material) may be used for the electron-injection layer 1115. Such a composite material is excellent in an electron-injection property and an electron-transport property because electrons are generated in the organic compound by the electron donor. The organic compound here is preferably a material excellent in transporting the generated electrons; specifically, any of the above electron-transport materials (e.g., the metal complexes and the heteroaromatic compounds) can be used, for example. As the electron donor, a substance showing an electron-donating property with respect to the organic compound is used. Specifically, an alkali metal, an alkaline earth metal, and a rare earth metal are preferable, and lithium, cesium, magnesium, calcium, erbium, ytterbium, and the like are given. In addition, an alkali metal oxide and an alkaline earth metal oxide are preferable, and lithium oxide, calcium oxide, barium oxide, and the like are given. Alternatively, a Lewis base such as magnesium oxide can be used. Further alternatively, an organic compound such as tetrathiafulvalene (abbreviation: TTF) can be used.

For manufacture of the light-emitting device of one embodiment of the present invention, a vacuum process such as an evaporation method or a solution process such as a spin coating method or an ink-jet method can be used. In the case of using an evaporation method, a physical vapor deposition method (PVD method) such as a sputtering method, an ion plating method, an ion beam evaporation method, a molecular beam evaporation method, or a vacuum evaporation method, a chemical vapor deposition method (CVD method), or the like can be used. Specifically, the functional layers (the hole-injection layer, the hole-transport layers, the light-emitting layer, the electron-transport layers, and the electron-injection layer) included in the EL layer can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, or a micro-contact printing method), or the like.

The materials of the functional layers included in the light-emitting device are not limited to the above-described materials. For example, as the materials of the functional layers, a high molecular compound (e.g., an oligomer, a dendrimer, and a polymer), a middle molecular compound (a compound between a low molecular compound and a high molecular compound with a molecular weight of 400 to 4000), or an inorganic compound (e.g., a quantum dot material) may be used. The quantum dot material may be a colloidal quantum dot material, an alloyed quantum dot material, a core-shell quantum dot material, a core quantum dot material, or the like.

Note that in the light-emitting device of one embodiment of the present invention, a functional layer other than the above-described layers may be included. As the functional layer, any of a variety of layers, such as a carrier-blocking layer and an exciton-blocking layer can be used, for example.

### <Light-Emitting Model of Light-Emitting Device>

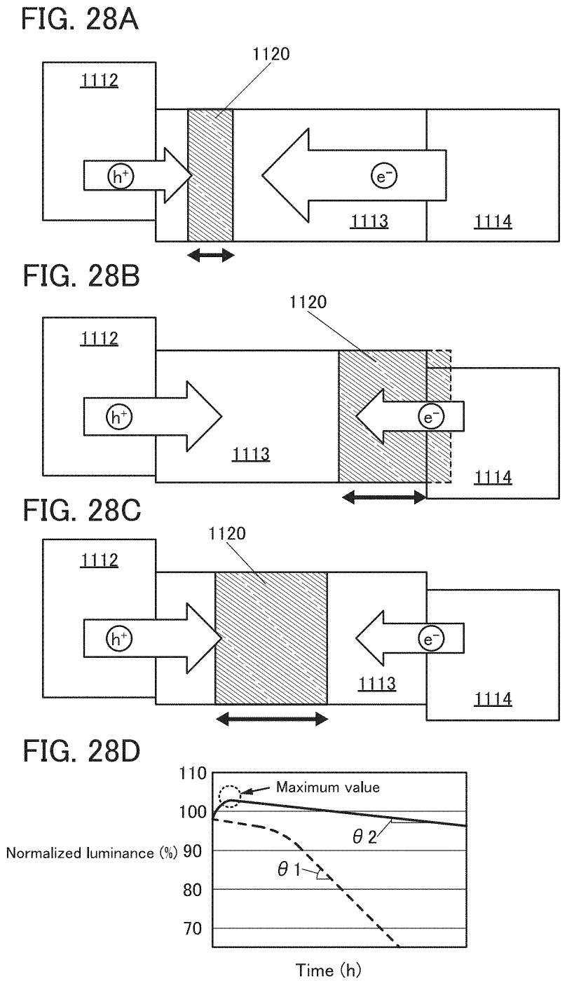

Next, a light-emitting model of a light-emitting device of one embodiment of the present invention will be described with reference to FIG. 28A to FIG. 28C.

FIG. 28A to FIG. 28C are schematic diagrams each illustrating a light-emitting model of a light-emitting device. Note that in FIG. 28A to FIG. 28C, a light-emitting region in the light-emitting device is represented by a light-emitting region 1120.

FIG. 28A is a light-emitting model showing the light-emitting region 1120 in a state where the light-emitting layer 1113 has excess electrons. FIG. 28B and FIG. 28C are light-emitting models each showing the light-emitting region 1120 of the light-emitting device of one embodiment of the present invention.

When the light-emitting layer 1113 has excess electrons, the light-emitting region 1120 is formed in a limited region of the light-emitting layer 1113, as illustrated in FIG. 28A. In other words, the width of the light-emitting region 1120 is small. Thus, electrons and holes are recombined intensively in the limited region of the light-emitting layer 1113, which accelerates degradation. In addition, the lifetime or emission efficiency may be reduced when electrons that have not been recombined in the light-emitting layer 1113 pass through the light-emitting layer 1113.

Meanwhile, in the light-emitting device of one embodiment of the present invention, the width of the light-emitting region 1120 in the light-emitting layer 1113 can be increased by lowering the electron-transport property of the electron-transport layer 1114, as illustrated in FIG. 28B and FIG. 28C. Increasing the width of the light-emitting region 1120 enables an electron-hole recombination region in the light-emitting layer 1113 to be dispersed. Accordingly, a light-emitting device with long lifetime and favorable emission efficiency can be provided.

The luminance decay curve of a light-emitting device of one embodiment of the present invention, which is obtained by a driving test at a constant current density, sometimes has the maximum value. In other words, the light-emitting device of one embodiment of the present invention sometimes shows a behavior such that the luminance increases with time. This behavior can cancel out rapid degradation at the initial stage of driving (i.e., initial decay). Thus, a light-emitting device with small initial degradation and a favorable driving lifetime can be provided.

Note that a differential value of the decay curve having the maximum value is 0 in a part. Therefore, a light-emitting device having a decay curve whose differential value is 0 in a part can be referred to as a light-emitting device of one embodiment of the present invention.

Here, normalized luminance over time of a light-emitting device of one embodiment of the present invention and that of a comparative light-emitting device will be described with reference to FIG. 28D.

In FIG. 28D, a thick solid line is a decay curve of normalized luminance of the light-emitting device of one embodiment of the present invention, and a thick dashed line is a decay curve of normalized luminance of the comparative light-emitting device.

As shown in FIG. 28D, the slope of the decay curve of normalized luminance is different between the light-emitting device of one embodiment of the present invention and the comparative light-emitting device. Specifically, a slope θ2 of the decay curve of the light-emitting device of one embodiment of the present invention is smaller than a slope θ1 of the decay curve of the comparative light-emitting device.

As illustrated in FIG. 28D, the luminance decay curve of the light-emitting device of one embodiment of the present invention, which is obtained by a driving test at a constant current density, sometimes has the maximum value. In other words, the decay curve of the light-emitting device of one embodiment of the present invention may have a portion where the luminance increases with time. The light-emitting device showing such a degradation behavior enables a rapid decay at the initial driving stage, which is called an initial decay, to be canceled out by the luminance increase. Thus, the light-emitting device can have an extremely long driving lifetime with a smaller initial decay.

At the initial stage of driving of the light-emitting device of one embodiment of the present invention, the light-emitting region 1120 formed in the light-emitting layer 1113 extends to the electron-transport layer 1114 side in some cases, as illustrated in FIG. 28B.

That is, in the light-emitting device of one embodiment of the present invention, a hole injection barrier is small at the initial stage of driving and the electron-transport property of the electron-transport layer 1114 is relatively low; accordingly, the light-emitting region 1120 (i.e., recombination region) is formed on the electron-transport layer 1114 side. Furthermore, since the HOMO level of the seventh organic compound included in the electron-transport layer 1114 is −6.0 eV or higher, which is relatively high, some holes even reach the electron-transport layer 1114 to cause recombination also in the electron-transport layer 1114; thus, a non-light-emitting recombination region is formed. This phenomenon sometimes occurs also when the difference between the HOMO levels of the sixth organic compound and the seventh organic compound is 0.2 eV or less.

In the light-emitting device of one embodiment of the present invention, carrier balance changes with the lapse of driving time, so that the light-emitting region 1120 (recombination region) moves toward the hole-transport layer 1112 side and is positioned within the light-emitting layer 1113, as illustrated in FIG. 28C

As illustrated in FIG. 28B and FIG. 28C, the light-emitting region 1120 of the light-emitting device of one embodiment of the present invention is moved in the light-emitting layer 1113 with the lapse of driving time, which allows energy of recombined carriers to effectively contribute to light emission, so that the luminance can increase as compared with that at the initial driving stage. This luminance increase cancels out the rapid luminance reduction that appears at the initial stage of driving of the light-emitting device, which is known as the initial decay. Thus, the light-emitting device can have a long driving lifetime with a small initial decay. Note that in this specification and the like, the structure of the above-described light-emitting device may be referred to as a Recombination-Site Tailoring Injection structure (ReSTI structure).

In the light-emitting device of one embodiment of the present invention, the electron-transport layer 1114 preferably includes a portion where the mixing ratio of the electron-transport material to the organometallic complex of an alkali metal or an alkaline earth metal differs in the thickness direction or a portion where the concentrations of the organometallic complex of an alkali metal or an alkaline earth metal differ in the thickness direction.

The concentration of the organometallic complex of an alkali metal or an alkaline earth metal in the electron-transport layer 1114 can be estimated from the amount of atoms and molecules detected by time-of-flight secondary ion mass spectrometry (ToF-SIMS).

The amount of organometallic complex in the electron-transport layer 1114 is preferably smaller on the second electrode 1102 side than on the first electrode 1101 side. In other words, the electron-transport layer 1114 is preferably formed so that the concentration of the organometallic complex increases from the second electrode 1102 side to the first electrode 1101 side. That is, in the electron-transport layer 1114, a portion where the amount of electron-transport material is small is closer to the light-emitting layer 1113 than a portion where the amount of electron-transport material is large is. In other words, in the electron-transport layer 1114, a portion where the amount of organometallic complex is large is closer to the light-emitting layer 1113 than a portion where the amount of organometallic complex is small is.

The electron mobility in the portion where the amount of electron-transport material is large (the portion where the amount of organometallic complex is small) is preferably higher than or equal to 1×10⁻⁷ cm²/Vs and lower than or equal to 5×10⁻⁵ cm²/Vs when the square root of the electric field strength [V/cm]is 600.

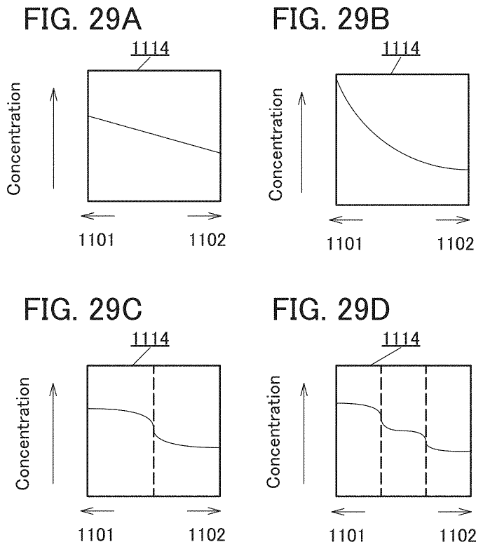

For example, the amount of organometallic complex contained in the electron-transport layer 1114, i.e., the concentration of the organometallic complex in the electron-transport layer 1114 can be those as illustrated in FIG. 29A to FIG. 29D. FIG. 29A and FIG. 29B show the case where no clear boundary exists in the electron-transport layer 1114, and FIG. 29C and FIG. 29D show the case where a clear boundary exists in the electron-transport layer 1114.

In the case where no clear boundary exists in the electron-transport layer 1114, the concentrations of the electron-transport material and the organometallic complex change continuously as shown in FIG. 29A and FIG. 29B. Meanwhile, in the case where a clear boundary exists in the electron-transport layer 1114, the concentrations of the electron-transport material and the organometallic complex change in a step-like manner as shown in FIG. 29C and FIG. 29D. Note that the change in a step-like manner indicates that the electron-transport layer 1114 includes a plurality of stacked layers. For example, FIG. 29C shows the case where the electron-transport layer 1114 has a two-layer-stack structure, and FIG. 29D shows the case where the electron-transport layer 1114 has a three-layer-stack structure. Note that in FIG. 29C and FIG. 29D, a dashed line indicates a boundary region between layers.

A change in the electron mobility of the electron-transport layer 1114 probably brings a change in carrier balance in the light-emitting device of one embodiment of the present invention. In the light-emitting device of one embodiment of the present invention, there is a concentration difference of the organometallic complex of an alkali metal or an alkaline earth metal in the electron-transport layer 1114. The electron-transport layer 1114 includes a region having a high concentration of the organometallic complex between the region having a low concentration of the organometallic complex and the light-emitting layer 1113. That is, the region with a low concentration of the organometallic complex is closer to the second electrode 1102 than the region with a high concentration of the organometallic complex is.

The light-emitting device of one embodiment of the present invention having the above structure has an extremely long lifetime. In particular, the time it takes for the luminance to decrease to 95% given that the initial luminance is 100% (the time can be referred to as LT95) can be extremely long.

<Light-Emitting Device with Tandem Structure>

Next, the light-emitting device with a tandem structure illustrated in FIG. 27B to FIG. 27D will be described.

Each of the light-emitting devices illustrated in FIG. 27B to FIG. 27D includes a plurality of light-emitting units between the first electrode 1101 and the second electrode 1102. A charge generation layer 1109 is preferably provided between two light-emitting units as illustrated in FIG. 27B to FIG. 27D.

Note that a light-emitting unit 1123(1) and a light-emitting unit 1123(2) each include the hole-injection layer 1111, the hole-transport layer 1112, the light-emitting layer 1113, the electron-transport layer 1114, the electron-injection layer 1115, and the like which are illustrated in FIG. 27A.

### <Charge Generation Layer>

The charge generation layer 1109 has a function of injecting electrons into one of the light-emitting unit 1123(1) and the light-emitting unit 1123(2) and injecting holes into the other when voltage is applied between the first electrode 1101 and the second electrode 1102. Thus, when voltage is applied in FIG. 27B such that the potential of the first electrode 1101 is higher than that of the second electrode 1102, the charge-generation layer 1109 injects electrons into the light-emitting unit 1123(1) and injects holes into the light-emitting unit 1123(2).

Note that in terms of light extraction efficiency, the charge generation layer 1109 preferably transmits visible light (specifically, the visible light transmittance of the charge generation layer 1109 is preferably 40% or higher). The charge generation layer 1109 functions even when it has lower conductivity than the first electrode 1101 or the second electrode 1102.

The EL layer 1103 illustrated in FIG. 27C includes the charge generation layer 1109 between the first light-emitting unit 1123(1) and the second light-emitting unit 1123(2) and the charge generation layer 1109 between the second light-emitting unit 1123(2) and a third light-emitting unit 1123(3). The light-emitting element illustrated in FIG. 27D includes m light-emitting units (m is a natural number of 2 or more) and n light-emitting units (n is a natural number greater than or equal to m), and includes the charge generation layer 1109 between the light-emitting units. The third light-emitting unit 1123(3), the light-emitting unit 1123(m), and the light-emitting unit 1123(n) each include the hole-injection layer 1111, the hole-transport layer 1112, the light-emitting layer 1113, the electron-transport layer 1114, the electron-injection layer 1115, and the like which are illustrated in FIG. 27A. Note that the light-emitting units may have the same structure or different structures.

Here, the behavior of electrons and holes in the charge generation layer 1109 provided between the light-emitting unit 1123(m) and a light-emitting unit 1123(m+1) is described. When a voltage higher than the threshold voltage of the light-emitting device is applied between the first electrode 1101 and the second electrode 1102, holes and electrons are generated in the charge generation layer 1109, holes move into the light-emitting unit 1123 (m+1) provided on the second electrode 1102 side, and electrons move into the light-emitting unit 1123(m) provided on the first electrode 1101 side. Holes injected to the light-emitting unit 1123 (m+1) and electrons injected from the second electrode 1102 side are recombined, so that a light-emitting material contained in the light-emitting unit 1123(m+1) emits light. Electrons injected to the light-emitting unit 1123(m) and holes injected from the first electrode 1101 side are recombined so that a light-emitting material included in the light-emitting unit 1123 (m) emits light. Thus, the holes and electrons generated in the charge generation layer 1109 emit light in the respective light-emitting units.

Note that the light-emitting units can be provided in contact with each other with no charge generation layer 1109 provided therebetween when the same structure as the charge generation layer 1109 is formed between the light-emitting units. For example, in the case where a charge generation region is formed on one surface of the light-emitting unit, another light-emitting unit can be provided to be in contact with the surface.

The light-emitting device with a tandem structure has higher current efficiency than the light-emitting device with a single structure, and needs a smaller amount of current when the devices emit light with the same luminance. Thus, the lifetime and the reliability of the light-emitting device can be increased.

Note that the plurality of light-emitting units may contain the same light-emitting material or different light-emitting materials. The light-emitting material of each light-emitting unit is not particularly limited. To improve reliability, a plurality of fluorescent light-emitting units is preferably stacked. For example, in the case where the same light-emitting material is used, a light-emitting device with high reliability can be provided by combination of a blue fluorescent light-emitting unit and a blue fluorescent light-emitting unit. Alternatively, one or more fluorescent light-emitting unit(s) and one or more phosphorescent light-emitting unit(s) may be stacked. For example, a light-emitting device capable of emitting white light can be provided by combination of a blue fluorescent light-emitting unit, a red phosphorescent light-emitting unit, and a green light-emitting unit. As the combination of light-emitting units with high reliability, fluorescent light-emitting units of each color of blue, red, and green may be employed.

In the case of a structure where blue fluorescent light-emitting units are combined as mentioned above, a device (e.g., quantum dot device) which has a function of converting blue light emitted from the light-emitting units into another color is preferably used in combination with the blue fluorescent light-emitting units.

At least part of this embodiment can be implemented in combination with the other embodiments described in this specification as appropriate.

### REFERENCE NUMERALS

100A: display apparatus, 100B: display apparatus, 100C: display apparatus, 100D: display apparatus, 100E: display apparatus, 101: display panel, 101a: region, 101b: region, 101c: region, 102a: housing, 102b: housing, 102c: housing, 103a: hinge, 103b: hinge, 103c: hinge, 104a: curved surface, 104b: curved surface, 105: plane surface, 105a: curved surface, 105b: curved surface, 106: grip portion, 107: power receiving coil, 108: power receiving circuit, 109: charger, 111: columnar body, 113a: unit, 113b: unit, 114: columnar body, 115: columnar body, 116a: gear, 116b: gear, 117: battery, 118: protection circuit, 119: control circuit, 120: sensor, 121: comparator, 122: transistor, 123: capacitor, 125: antenna, 126: antenna, 130: image, 131: keyboard, 132: icon, 135a: input/output unit, 135b: input/output unit, 136a: camera, 136b: camera, 137: sensor, 138: display panel, 139: display panel, 140: solar cell, 141: thin film solar cell, 145: external interface, 146: transmitting and receiving unit, 147: speaker, 148: camera, 149: microphone, 150: stylus, 200: display apparatus, 210: display apparatus, 300: pixel, 301: pixel, 400: pixel circuit, 400EL: pixel circuit, 400LC: pixel circuit, 401: circuit, 401EL: circuit, 401LC: circuit, 501: pixel circuit, 502: pixel portion, 504: driver circuit portion, 504a: gate driver, 504b: source driver, 506: protection circuit, 507: terminal portion, 550: transistor, 552: transistor, 554: transistor, 560: capacitor, 562: capacitor, 570: liquid crystal device, 572: light-emitting device, 600: television device, 601: control portion, 602: memory portion, 603: communication control portion, 604: image processing circuit, 605: decoder circuit, 606: video signal receiving portion, 607: timing controller, 608: source driver, 609: gate driver, 620: display panel, 621: pixel, 630: system bus, 700: display panel, 700A: display panel, 702: pixel portion, 704: source driver circuit portion, 706: gate driver circuit portion, 708: FPC terminal portion, 710: wiring, 716: FPC, 717: IC, 730: insulating layer, 732: sealing layer, 736: coloring layer, 738: light-blocking layer, 740: support substrate, 741: protection layer, 741a: insulating layer, 741b: insulating layer, 741c: insulating layer, 742: adhesive layer, 743: resin layer, 744: insulating layer, 745: support substrate, 746: insulating layer, 747: adhesive layer, 749: protection layer, 750: transistor, 752: transistor, 760: wiring, 761: conductive layer, 770: insulating layer, 772: conductive layer, 780: anisotropic conductive film, 782: light-emitting device, 786: EL layer, 788: conductive layer, 790: capacitor, 1101: electrode, 1102: electrode, 1103: EL layer, 1109: charge generation layer, 1111: hole-injection layer, 1112: hole-transport layer, 1113: light-emitting layer, 1114: electron-transport layer, 1115: electron-injection layer, 1120: light-emitting region, 1123: light-emitting unit

1. A display apparatus comprising a display panel having flexibility,
wherein the display panel comprises a first region, a second region, and a third region,
wherein the first region, the second region, and the third region are in parallel with one another to form a plane when the display apparatus is opened flat,
wherein the second region is between the first region and the third region,
wherein the display apparatus is capable of forming a first curved surface with a convex shape on a display surface side across the first region and the second region,
wherein the display apparatus is capable of forming a second curved surface with a concave shape on the display surface side across the second region and the third region, and
wherein a radius of curvature R1 of the first curved surface is larger than a radius of curvature R2 of the second curved surface when the display apparatus is folded.

2. (canceled)

3. The display apparatus according to claim 1, further comprising: a first housing; a second housing; a third housing; a first hinge; and a second hinge,
wherein at least part of the first region is fixed to the first housing,
wherein at least part of the second region is fixed to the second housing,
wherein at least part of the third region is fixed to the third housing,
wherein the first hinge is between the first housing and the second housing,
wherein the second hinge is between the second housing and the third housing,
wherein the first hinge is capable of forming the first curved surface,
wherein the second hinge is capable of forming the second curved surface, and
wherein when the display apparatus is opened flat, a gravity center of a whole is in the first housing or the third housing.

4. The display apparatus according to claim 3,
wherein a battery is in the first housing or the third housing.

5. The display apparatus according to claim 3,
wherein a power receiving coil for wireless charging is in the third housing.

6. The display apparatus according to claim 1,
wherein the display panel comprises a light-emitting device.

7. An operation method of a display apparatus, comprising the display apparatus according to claim 1,
wherein only a part of a region performs display.

8. The operation method of a display apparatus, according to claim 7,
wherein when the display panel is opened flat, orientation of an image is changed in accordance with inclination of the display panel.

9. A display apparatus comprising a display panel having flexibility,
wherein the display panel comprises a first region, a second region, and a third region,
wherein the first region, the second region, and the third region are in parallel with one another to form a plane when the display apparatus is opened flat,
wherein the second region is between the first region and the third region,
wherein the display apparatus is capable of successively forming a first curved surface with a convex shape on a display surface side, a plane surface, and a third curved surface with a convex shape on the display surface side in this order across the first region and the second region,
wherein the display apparatus is capable of forming a second curved surface with a concave shape on the display surface side across the second region and the third region, and
wherein when the display apparatus is folded, a radius of curvature R1 of the first curved surface is larger than a radius of curvature R2 of the second curved surface, a radius of curvature R3 of the third curved surface is larger than the radius of curvature R2, and the radius of curvature R1 is substantially equal to the radius of curvature R3.

10. The display apparatus according to claim 9, further comprising: a first housing; a second housing; a third housing; a first hinge; and a second hinge,
wherein at least part of the first region is fixed to the first housing,
wherein at least part of the second region is fixed to the second housing,
wherein at least part of the third region is fixed to the third housing,
wherein the first hinge is between the first housing and the second housing,
wherein the second hinge is between the second housing and the third housing,
wherein the first hinge is capable of forming the first curved surface,
wherein the second hinge is capable of forming the second curved surface, and
wherein when the display apparatus is opened flat, a gravity center of a whole is in the first housing or the third housing.

11. The display apparatus according to claim 10,
wherein a battery is in the first housing or the third housing.

12. The display apparatus according to claim 10,
wherein a power receiving coil for wireless charging is in the third housing.

13. The display apparatus according to claim 9,
wherein the display panel comprises a light-emitting device.

14. An operation method of a display apparatus, comprising the display apparatus according to claim 9,
wherein only a part of a region performs display.

15. The operation method of a display apparatus, according to claim 14,
wherein when the display panel is opened flat, orientation of an image is changed in accordance with inclination of the display panel.
